(19) United States
(12) Patent Application Publication
(10) Pub. No.: US 2025/0391794 A1
(43) Pub. Date: Dec. 25, 2025

(54) COMPOSITE HYBRID STRUCTURES

(71) Applicant: ADEIA SEMICONDUCTOR BONDING TECHNOLOGIES INC., San Jose, CA (US)

(72) Inventors: Cyprian Emeka Uzoh, San Jose, CA (US); Gaius Gillman Fountain, JR., Youngsville, NC (US); Thomas Workman, San Jose, CA (US); Guilian Gao, San Jose, CA (US)

(21) Appl. No.: 18/991,032

(22) Filed: Dec. 20, 2024

Related U.S. Application Data
(60) Provisional application No. 63/663,017, filed on Jun. 21, 2024.

(51) Int. Cl. H01L 23/00; H01L 25/065

(52) U.S. Cl. CPC H01L 24/08; H01L 24/03; H01L 24/05; H01L 25/0655; H01L 25/0657; H01L 2224/03003; H01L 2224/05084; H01L 2224/05087; H01L 2224/0519; H01L 2224/05287; H01L 2224/08148; H01L 2224/08188; H01L 2924/3512

(57) ABSTRACT

Methods for fabrication dielectric layers having conductive contact pads, and directly bonding the dielectric and conductive bonding surfaces of the dielectric layers. In some aspects, the method includes disposing a polish stop layer on dielectric bonding surfaces on top of a dielectric layer. A conductive layer is disposed on top of the polish stop layer and then polished to form conductive contact pads having polished conducting bonding surfaces. During the polishing process, the polish stop layer reduces rounding of dielectric edges and erosion of the dielectric bonding surfaces between closely spaced conductive bonding surfaces. The resulting polished dielectric and conductive bonding surfaces are directly bonded to dielectric and conductive bonding surfaces of another dielectric layer to form conductive interconnects.

### CROSS-REFERENCE TO RELATED APPLICATIONS

This application claims priority to U.S. Provisional Patent Application No. 63/663,017, filed on Jun. 21, 2024, the entire contents of which are incorporated by reference herein in their entirety and for all purposes.

### BACKGROUND

### Field

The field relates to structures having hybrid bonding surfaces including dielectric and conductive regions and methods for forming the same.

### Description of the Related Art

Semiconductor elements, such as integrated device dies or chips, may be mounted or stacked on other elements. For example, a semiconductor element can be stacked on top of another semiconductor element and the bonded elements can electrically communicate with one another through contact pads included in the hybrid bonding surfaces. For example, hybrid bonding surfaces of a first and second integrated device dies can be bonded on to hybrid bonding surfaces of a semiconductor substrate and the first and second integrated device dies can electrically communicate via contact pads of the respective hybrid binding surfaces. It can be challenging to integrate semiconductor elements of different types or material sets, on a substrate or in a package due to, for example, mismatches in coefficient of thermal expansion (CTE). Further, it can be challenging to provide communication between stacks of semiconductor elements and to maintain a low profile for the package or device.

### BRIEF DESCRIPTION OF THE DRAWINGS

The detailed description is set forth with reference to the accompanying figures. The use of the same numbers in different figures indicates similar or identical items. For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure.

FIG. 1A schematically illustrates an example composite flexible hybrid bonded structure including a flexible hybrid bonding layer and two dies directly bonded to two separate regions of a hybrid bonding surface of the hybrid flexible layer.

FIG. 1B schematically illustrates another example composite flexible hybrid bonded structure that includes a stack of flexible hybrid bonding layers and two dies directly bonded to two separate regions of a hybrid bonding surface of a top hybrid flexible layer.

FIG. 1C schematically illustrates another example composite flexible hybrid bonded structure that includes a double-sided flexible hybrid bonding substrate and two dies directly bonded to hybrid bonding surfaces on opposite sides of the double-sided flexible hybrid bonding substrate.

FIG. 1D schematically illustrates an example flexible hybrid bonding substrate including the double-sided flexible hybrid bonding layer shown in FIG. 1C directly bonded to hybrid bonding surface of a thick dielectric layer disposed on a carrier substrate.

FIG. 1E schematically illustrates an example double-sided flexible hybrid bonding layer including two double-sided flexible hybrid bonding layers directly bonded to hybrid bonding surfaces on the opposite sides of a double-sided hybrid dielectric layer.

FIG. 2A schematically illustrates a flexible hybrid bonding layer including a flexible layer, a dielectric layer, a plurality of contact pads each separated from the flexible and dielectric layers by a barrier layer, and a hybrid bonding surface including surface regions of the dielectric layer and the contact pads.

FIG. 2B schematically illustrates another flexible hybrid bonding layer including a flexible layer, a dielectric layer, a plurality of contact pads each separated from the flexible and dielectric layers by a barrier layer, the contact pads extending from a hybrid bonding surface to an opposite surface of the flexible hybrid bonding layer.

FIG. 2C schematically illustrates another flexible hybrid bonding layer including a flexible layer a hybrid bonding surface, a plurality of contact pads, and a conductive line at least partially embedded in flexible layer, the conductive line electrically connecting some of the contact pads.

FIG. 2D schematically illustrates another flexible hybrid bonding layer including a flexible layer having an intermediate layer therein, a dielectric layer, a plurality of contact pads each separated from the flexible and dielectric layers, by a barrier layer, the plurality of contact pads extending from the intermediate layer to a hybrid bonding surface of the flexible hybrid bonding layer.

FIG. 2E schematically illustrates another flexible hybrid bonding layer comprising a flexible layer, a thick dielectric layer disposed on the flexible layer, a hybrid bonding surface formed on the thick dielectric layer, and a plurality of contact pads extending from the hybrid bonding surface into the flexible layer.

FIG. 2F schematically illustrates another flexible hybrid bonding layer comprising a flexible layer, a thick dielectric layer disposed on the flexible layer, a hybrid bonding surface formed on the thick dielectric layer, and a plurality of contact pads extending from the hybrid bonding surface into the flexible layer.

FIG. 2G schematically illustrates a double-sided flexible hybrid bonding layer having two opposing hybrid bonding surfaces, two directly bonded double-sided flexible hybrid sub-layers, and a plurality of contact pads within each double-sided bonded flexible hybrid sub-layer.

FIGS. 3A-3H schematically illustrate selected steps of an example process for fabricating the flexible hybrid bonding layer shown in FIG. 2A having dielectric barrier layers.

FIGS. 4A-4F schematically illustrate selected steps of a process for dicing a composite flexible hybrid bonded structure formed on a carrier substrate, to separate one or more portions of the composite flexible hybrid bonded structure.

FIG. 5A schematically illustrates an example composite flexible hybrid bonded structure including a single die directly bonded to a flexible hybrid bonding substrate.

FIG. 5B schematically illustrates an example composite flexible hybrid bonded structure including two dies having the same number of layers, directly bonded to a flexible hybrid bonding substrate.

FIG. 5C schematically illustrates an example composite flexible hybrid bonded structure including two dies having different number of layers, directly bonded to a flexible hybrid bonding substrate.

FIG. 5D schematically illustrates a composite flexible hybrid bonded structure including a die directly bonded to a first hybrid bonding surface of a flexible hybrid bonding substrate and electrically connected to a conductive region of a second hybrid bonding surface if the flexible hybrid bonding substrate away from the die.

FIGS. 6A-6D schematically illustrate selected steps of an example process for fabricating the flexible hybrid bonding layer shown in FIG. 2A having conductive dielectric barrier layers.

FIG. 7A schematically illustrates an example composite flexible hybrid bonded structure including a die directly bonded to a flexible hybrid bonding substrate.

FIG. 7B schematically illustrates an example composite flexible hybrid bonded structure including two dies having the same number of layers, directly bonded to a flexible hybrid bonding substrate where a conductive barrier layers separates contact pads and the flexible layer of the flexible hybrid bonding substrate.

FIG. 7C schematically illustrates an example composite flexible hybrid bonded structure including two dies having different number of layers, directly bonded to a flexible hybrid bonding substrate where a conductive barrier layer separates contact pads and the flexible layer of the hybrid bonding substrate.

FIG. 7D schematically illustrates a hybrid composite structure including a component directly bonded to a hybrid bonding surface of a flexible hybrid bonding substrate and electrically connected to a conductive region of the bonding surface away from the component where a barrier layer separates the contact pads and a flexible layer of the hybrid bonding substrate.

FIGS. 8A-8E schematically illustrate selected steps of an example process for fabricating the flexible hybrid bonding layer shown in FIG. 2C.

FIGS. 9A-9B schematically illustrate hybrid composite structures including a component directly bonded to a hybrid bonding surface of the flexible hybrid bonding layer shown in FIG. 2C and electrically connected to a conductive region of the bonding surface away from the component when the flexible hybrid bonding layer is on a carrier substrate (9A), and when the flexible hybrid bonding layer is separated from the carrier substrate (9B).

FIGS. 10A-10J schematically illustrate selected steps of an example process for fabricating the flexible hybrid bonding layer shown in FIG. 2G.

FIGS. 11A-11G schematically illustrate selected steps of an example process for fabricating a composite hybrid bonded structure comprising a multilayer flexible hybrid bonded structure and multiple dies directly bonded to a hybrid surface of the multilayer flexible hybrid bonded structure.

FIGS. 12A-12J schematically illustrate selected steps of an example process for fabricating the flexible hybrid bonding layer shown in FIG. 2B.

FIGS. 13A-13E schematically illustrate selected steps of an example process for fabricating the flexible hybrid bonding layer shown in FIG. 2D.

FIGS. 14A-14N schematically illustrate selected steps of an example process for fabricating the flexible hybrid bonding layer shown in FIG. 2E.

FIGS. 15A-15L schematically illustrate selected steps of a process for fabricating an example flexible hybrid bonding layer or substrate comprising patterning a flexible layer.

FIG. 16A schematically illustrate an example of such flexible hybrid bonding substrate having contact pads, conductive vias, and/or conductive lines fully embedded in a dielectric layer.

FIG. 16B schematically illustrate an example of the flexible hybrid bonding layer FIG. 16A where the flexible layer includes two reinforcement layers.

FIGS. 17A-17B schematically illustrate cross-sectional side views of two elements (A) prior to hybrid bonding and (B) after hybrid bonding.

### DETAILED DESCRIPTION

There is a growing demand for directly bonding semiconductor elements having contact pads arranged at a fine pitch, so as to increase interconnect density and provide improved electrical capabilities. Direct hybrid bonds may be formed by fabricating semiconductor elements (e.g., wafers or dies) having polished bonding surfaces including a nonconductive field region and one or more conductive features (e.g., conductive contact pads) at least partially embedded in the nonconductive field region. The nonconductive field regions of two semiconductor elements can be directly bonded at low temperature without using an adhesive to form a bonded structure (e.g., via covalently bonded dielectric-to-dielectric surfaces). The directly bonded structure can be heated to cause expansion of the conductive contact pads therein so as to form a bond between opposing surfaces of the conductive contact pads and thereby provide electrical connection between the conductive contact pads. Accordingly, a hybrid bonding surface comprises nonconductive (e.g., dielectric) and conductive regions formed on a nonconductive (e.g., insulating) layer. In some embodiments, the nonconductive regions may comprise an inorganic dielectric material. In some cases, the nonconductive (e.g., dielectric or field regions) may be activated for direct bonding. A hybrid bonding interface comprises a boundary of two hybrid bonding surfaces providing electrical connection between at least two opposing contact pads. A hybrid bonding interface can be formed by directly bonding two hybrid bonding layers or substrates. A hybrid bonding interface comprises at least one covalently bonded interface between two dielectric bonding layers and at least one conductive interface between two conductive regions (e.g., to conductive contact pads) formed at least partially within the respective dielectric bonding layers. A hybrid bonding (or substrate) layer may comprise a layer (or substrate) having at least one hybrid bonding surface configured to be directly bonded to a hybrid bonding surface of another element (e.g., a component, die, structure, substrate, or the like). In some cases, a hybrid surface may comprise nonconductive (e.g., dielectric) and conductive regions where the nonconductive regions are not activated for direct bonding. In some examples, a dielectric region of a hybrid surface may be activated by adding suitable species (e.g., nitrogen species) to transform hybrid surface to a hybrid bonding surface.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 1708a and/or 1708b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The hybrid bonding interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the hybrid bonding interface between non-conductive bonding surfaces. In some embodiments, the hybrid bonding interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

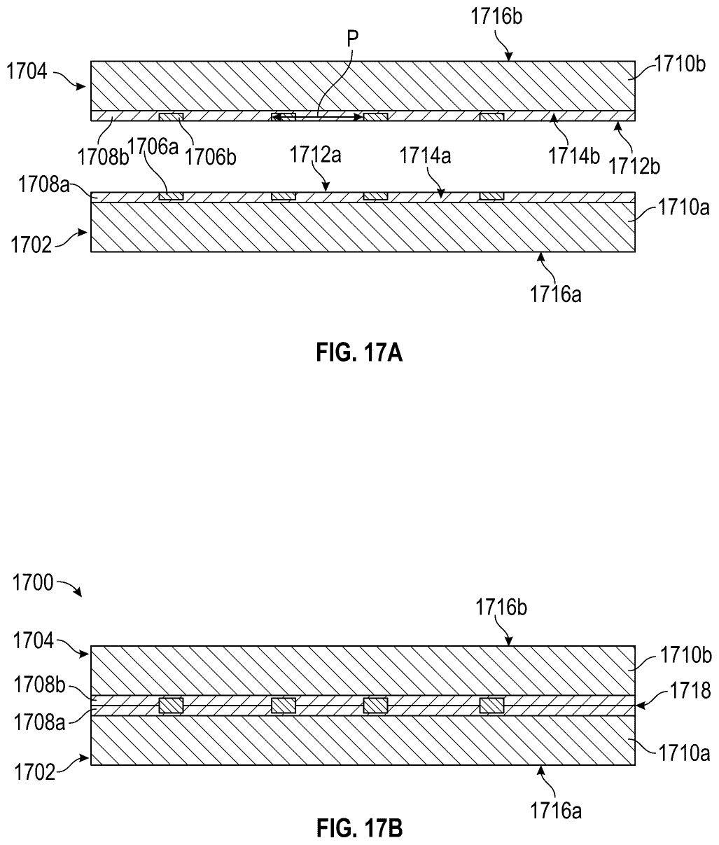

FIGS. 17A and 17B schematically illustrate cross-sectional side views of first and second elements 1702, 1704 prior to and after, respectively, a process for forming a directly bonded structure, and more particularly a hybrid bonded structure, according to some embodiments. In FIG. 17B, a bonded structure 1700 comprises the first and second elements 1702 and 1704 that are directly bonded to one another at a hybrid bonding interface 1718 without an intervening adhesive. Conductive features 1706a of a first element 1702 may be electrically connected to corresponding conductive features 1706b of a second element 1704. In the illustrated hybrid bonded structure 1700, the conductive features 1706a are directly bonded to the corresponding conductive features 1706b without intervening solder or conductive adhesive.

The conductive features 1706a and 1706b of the illustrated embodiment are embedded in, and can be considered part of, a first bonding layer 1708a of the first element 1702 and a second bonding layer 1708b of the second element 1704, respectively. Field regions of the bonding layers 1708a, 1708b extend between and partially or fully surround the conductive features 1706a, 1706b. The bonding layers 1708a, 1708b can comprise layers of non-conductive materials suitable for direct bonding, as described above, and the field regions are directly bonded to one another without an adhesive. The non-conductive bonding layers 1708a, 1708b can be disposed on respective front sides 1714b, 1714b of base substrate portions 1710a, 1710b.

The first and second elements 1702, 1704 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 1702, 1704, and back-end-of-line (BEOL) interconnect layers over such semiconductor portions. The bonding layers 1708a, 1708b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 1710a, 1710b, and can electrically communicate with at least some of the conductive features 1706a, 1706b. Active devices and/or circuitry can be disposed at or near the front sides 1714b, 1714b of the base substrate portions 1710a, 1710b, and/or at or near opposite backsides 1716a, 1716b of the base substrate portions 1710a, 1710b. In other embodiments, the base substrate portions 1710a, 1710b may not include active circuitry, but may instead comprise dummy substrates, passive interposers, passive optical elements (e.g., glass substrates, gratings, lenses), etc. The bonding layers 1708a, 1708b are shown as being provided on the front sides of the elements, but similar bonding layers can be additionally or alternatively provided on the back sides of the elements.

In some embodiments, the base substrate portions 1710a, 1710b can have significantly different coefficients of thermal expansion (CTEs), and bonding elements that include such different based substrate portions can form a heterogenous bonded structure. The CTE difference between the base substrate portions 1710a and 1710b, and particularly between bulk semiconductor (typically single crystal) portions of the base substrate portions 1710a, 1710b, can be greater than 5 ppm/° C. or greater than 10 ppm/° C. For example, the CTE difference between the base substrate portions 1710a and 1710b can be in a range of 5 ppm/° C. to 1700 ppm/° C., 5 ppm/° C. to 40 ppm/° C., 10 ppm/° C. to 1700 ppm/° C., or 10 ppm/° C. to 40 ppm/° C.

In some embodiments, one of the base substrate portions 1710a, 1710b can comprise optoelectronic single crystal materials, including perovskite materials, that are useful for optical piezoelectric or pyroelectric applications, and the other of the base substrate portions 1710a, 1710b comprises a more conventional substrate material. For example, one of the base substrate portions 1710a, 1710b comprises lithium tantalate (LiTaO3) or lithium niobate (LiNbO3), and the other one of the base substrate portions 1710a, 1710b comprises silicon (Si), quartz, fused silica glass, sapphire, or a glass. In other embodiments, one of the base substrate portions 1710a, 1710b comprises a III-V single semiconductor material, such as gallium arsenide (GaAs) or gallium nitride (GaN), and the other one of the base substrate portions 1710a, 1710b can comprise a non-III-V semiconductor material, such as silicon (Si), or can comprise other materials with similar CTE, such as quartz, fused silica glass, sapphire, or a glass. In still other embodiments, one of the base substrate portions 1710a, 1710b comprises a semiconductor material and the other of the base substrate portions 1710a, 1710b comprises a packaging material, such as a glass, organic or ceramic substrate.

In some arrangements, the first element 1702 can comprise a singulated element, such as a singulated integrated device die. In other arrangements, the first element 1702 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 1704 can comprise a singulated element, such as a singulated integrated device die. In other arrangements, the second element 1704 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive and may include markings indicative of the common singulation process for the bonded structure (e.g., saw markings if a saw singulation process is used).

While only two elements 1702, 1704 are shown, any suitable number of elements can be stacked in the bonded structure 1700. For example, a third element (not shown) can be stacked on the second element 1704, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent to one another along the first element 1702. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 1708a, 1708b, the bonding layers 1708a, 1708b can be prepared for direct bonding. Non-conductive bonding surfaces 1712a, 1712b at the upper or exterior surfaces of the bonding layers 1708a, 1708b can be prepared for direct bonding by polishing, for example, by chemical mechanical polishing (CMP). The roughness of the polished bonding surfaces 1712a, 1712b can be less than 30 Å rms. For example, the roughness of the bonding surfaces 1712a and 1712b can be in a range of about 0.1 Å rms to 15 Å rms, 0.5 Å rms to 10 Å rms, or 1 Å rms to 5 Å rms. Polishing can also be tuned to leave the conductive features 1706a, 1706b recessed relative to the field regions of the bonding layers 1708a, 1708b.

Preparation for direct bonding can also include cleaning and exposing one or both of the bonding surfaces 1712a, 1712b to a plasma and/or etchants to activate at least one of the surfaces 1712a, 1712b. In some embodiments, one or both of the surfaces 1712a, 1712b can be terminated with a species after activation or during activation (e.g., during the plasma and/or etch processes). Without being limited by theory, in some embodiments, the activation process can be performed to break chemical bonds at the bonding surface(s) 1712a, 1712b, and the termination process can provide additional chemical species at the bonding surface(s) 1712a, 1712b that alters the chemical bond and/or improves the bonding energy during direct bonding. In some embodiments, the activation and termination are provided in the same step, e.g., a plasma to activate and terminate the surface(s) 1712a, 1712b. In other embodiments, one or both of the bonding surfaces 1712a, 1712b can be terminated in a separate treatment to provide the additional species for direct bonding. In various embodiments, the terminating species can comprise nitrogen. For example, in some embodiments, the bonding surface(s) 1712a, 1712b can be exposed to a nitrogen-containing plasma. Other terminating species can be suitable for improving bonding energy, depending upon the materials of the bonding surfaces 1712a, 1712b. Further, in some embodiments, the bonding surface(s) 1712a, 1712b can be exposed to fluorine. For example, there may be one or multiple fluorine concentration peaks at or near a hybrid bonding interface 1718 between the first and second elements 1702, 1704. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 1700, the hybrid bonding interface 1718 between two non-conductive materials (e.g., the bonding layers 1708a, 1708b) can comprise a very smooth interface with higher nitrogen (or other terminating species) content and/or fluorine concentration peaks at the hybrid bonding interface 1718. In some embodiments, the nitrogen and/or fluorine concentration peaks may be detected using various types of inspection techniques, such as SIMS techniques. The polished bonding surfaces 1712a and 1712b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 1708a and 1708b can be directly bonded to one another without an adhesive. In some embodiments, the elements 1702, 1704 are brought together at room temperature, without the need for application of a voltage, and without the need for application of external pressure or force beyond that used to initiate contact between the two elements 1702, 1704. Contact alone can cause direct bonding between the non-conductive surfaces of the bonding layers 1708a, 1708b (e.g., covalent dielectric bonding). Subsequent annealing of the bonded structure 1700 can cause the conductive features 1706a, 1706b to directly bond.

In some embodiments, prior to direct bonding, the conductive features 1706a, 1706b are recessed relative to the surrounding field regions, such that a total gap between opposing contacts after dielectric bonding and prior to anneal is less than 15 nm, or less than 10 nm. Because the recess depths for the conductive features 1706a and 1706b can vary across each element, due to process variation, the noted gap can represent a maximum or an average gap between corresponding conductive features 1706a, 1706b of two joined elements (prior to anneal). Upon annealing, the conductive features 1706a and 1706b can expand and contact one another to form a metal-to-metal direct bond.

During annealing, the conductive features 1706a, 1706b (e.g., metallic material) can expand while the direct bonds between surrounding non-conductive materials of the bonding layers 1708a, 1708b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 1706a, 1706b can comprise discrete pads, contacts, electrodes, or traces at least partially embedded in the non-conductive field regions of the bonding layers 1708a, 1708b. In some embodiments, the conductive features 1706a, 1706b can comprise exposed contact surfaces of TSVs (e.g., through silicon vias).

As noted above, in some embodiments, in the elements 1702, 1704 of FIG. 17A prior to direct bonding, portions of the respective conductive features 1706a and 1706b can be recessed below the non-conductive bonding surfaces 1712a and 1712b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 1706a, 1706b or to average depths of the recesses relative to local non-conductive field regions. Even for an individual conductive feature 1706a, 1706b, the vertical recess can vary across the feature, and so can be measured at or near the lateral middle or center of the cavity in which a given conductive feature 1706a, 1706b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 1706a, 1706b across the direct hybrid bonding interface 1718 (e.g., small or fine pitches for regular arrays).

In some embodiments, a pitch p of the conductive features 1706a, 1706b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 1706a and 1706b to one of the lateral dimensions (e.g., a diameter) of the bonding pad is less than is less than 20, or less than 10, or less than 5, or less than 3 and sometimes desirably less than 2. In various embodiments, the conductive features 1706a and 1706b and/or traces can comprise copper or copper alloys, although other metals may be suitable, such as nickel, aluminum, or alloys thereof. The conductive features disclosed herein, such as the conductive features 1706a and 1706b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 1702, 1704, as shown, the orientations of one or more conductive features 1706a, 1706b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 1706b in the bonding layer 1708b (and/or at least one internal conductive feature, such as a BEOL feature) of the upper element 1704 may be tapered or narrowed upwardly, away from the bonding surface 1712b. By way of contrast, at least one conductive feature 1706a in the bonding layer 1708a (and/or at least one internal conductive feature, such as a BEOL feature) of the lower element 1702 may be tapered or narrowed downwardly, away from the bonding surface 1712a. Similarly, any bonding layers (not shown) on the backsides 1716a, 1716b of the elements 1702, 1704 may taper or narrow away from the backsides, with an opposite taper orientation relative to front side conductive features 1706a, 1706b of the same element.

As described above, in an anneal phase of hybrid bonding, the conductive features 1706a, 1706b can expand and contact one another to form a metal-to-metal direct bond. In some embodiments, the materials of the conductive features 1706a, 1706b of opposite elements 1702, 1704 can interdiffuse during the annealing process. In some embodiments, metal grains grow into each other across the hybrid bonding interface 1718. In some embodiments, the metal is or includes copper, which can have grains oriented along the 111 crystal plane for improved copper diffusion across the hybrid bonding interface 1718. In some embodiments, the conductive features 1706a and 1706b may include nanotwinned copper grain structure, which can aid in merging the conductive features during anneal. There is substantially no gap between the non-conductive bonding layers 1708a and 1708b at or near the bonded conductive features 1706a and 1706b. In some embodiments, a barrier layer may be provided under and/or laterally surrounding the conductive features 1706a and 1706b (e.g., which may include copper). In other embodiments, however, there may be no barrier layer under the conductive features 1706a and 1706b.

In some cases, a portion of a hybrid bonding substrate or layer may be displaced with respect to another portion of the same substrate or layer, e.g., by a mechanical force or due to thermal expansion. For example, heat generated by a first component directly bonded to a first portion of a hybrid bonding substrate may cause that portion to be expanded and move with respect to another portion of the hybrid bonding substrate that is directly bonded to a second component. As another example, a first portion of a hybrid bonding substrate or layer may be used to provide electrical connection between a first component and a second component vertically displaced with respect to the first component. In such cases, the hybrid bonding substrate or layer may be deformed and/or stressed resulting in development of defects, cracks in the substrate or layer, and in some cases, electrical disconnection between the first and second components. Various hybrid bonding layers and substrates disclosed herein may include a flexible region (e.g., a flexible region within a core insulating layer), flexible portion, or a flexible layer that allows two different portions or sections of a hybrid bonding layer or structure to be displaced by different amounts without causing mechanical damage in the substrate or layer or electrical disconnection between different sections of the substrate or layer. For example, some of the disclosed methods may be used to fabricate a flexible hybrid bonding layer or flexible hybrid bonding substrate comprising one or more contact pads and/or conductive lines at least partially embedded in a flexible (or deformable) layer having at least one hybrid bonding surface. In various implementations, a flexible hybrid bonding layer or flexible hybrid bonding substrate may include a core insulating layer within which the one or more contact pads and/or conductive lines are at least partially embedded and comprises a deformable region.

In various implementations, a flexible layer may comprise a compliant material that includes one or more organic materials such as a polymer, e.g., an elastomer, (PYRALIN® PI 2611) or polyamide-imide Torlon® or benzocyclobutene (BCB) for example a liquid crystal polymer (LCP) and/or a polyimide. In some cases, a flexible layer may comprise one or more compliant materials. For example, a mixture or combination of different types of polymers. In some cases, a flexible layer may comprise 5-10 weight %, 10-20 weight %, 20-40weight %, 40-50 weight %, 50-60 weight %, 60-70 weight %, 70-80 weight %, 80-90 weight %, or 90-100 weight %, polymer or another compliant material. In some cases, a flexible layer, a flexible substrate, or a core insulating layer of a flexible hybrid bonding layer may comprise a deformable region or a deformable layer comprising a compliant material. In some cases, the compliant material (e.g., a flexible substrate) may have a Young's modulus in a range of 0.2 GPa to 5 GPa, 5 GPa to 20 Gpa, 20 to 45 Gpa, 45 to 50 Gpa, or any ranges formed by these values or larger or smaller values. In some embodiments, the compliant material selected to have a Young's modulus that allows the corresponding flexible substrate (having a deformable region comprising the compliant material) to be deformed more than or equal to a minimum desired deformation. In some examples, the minimum desired deformation may comprise a radius of curvature of a bent flexible substrate to be less than 100 times, less than 50 times, or less than 20 times the thickness of the flexible substrate without disrupting an electrical connection within the substrate. As such, in some cases, the compliant material selected based at least in part on a thickness of the substrate (e.g., along a direction normal to a main surface of the substrate). For example, when a thickness of the deformable region, along a direction normal to a main surface of the substrate, is larger than 5 microns, the compliant material (the deformable region of the substrate) may be selected to have Young's modulus less than 40 GPa.

In some examples, a flexible hybrid bonding layer or substrate or the core insulating layer therein may be configured to allow two hybrid surface regions of a hybrid bonded flexible substrate to be displaced with respect to each other by more than the 20%, 50%, 100%, 200%, 300%, 400%, 500% of the thickness of the flexible substrate without suffering mechanical damage, and/or disrupting electrical connectivity (e.g., between the two hybrid surface regions (e.g., due to disconnection of an electrical link at least partially embedded in the layer or substrate). In some examples, a flexible layer or a compliant portion of a flexible layer (e.g., a polymer layer) may have a CTE of greater than 5 ppm/° C. and less than 80 ppm/° C. In some examples, a flexible layer or a compliant portion of a flexible layer (e.g., a polymer layer) may have a CTE of less than 15 ppm/° C., from 15 to 20 ppm/° C., from 20 to 30 ppm/° C., from 30-40 ppm/° C., from 40 to 50 ppm/° C., from 50 to 80 ppm/° C. In some examples, a flexible layer or substrate may comprise a composite material. In such examples, the composite material can be an inorganic material, an organic material, or a combination thereof. In such examples, the composite material may comprise particulate reinforcement in the form or fibers (e.g., chopped fibers), particles, or particles having any shapes. In some cases, the particulate reinforcement can be less than 10%, 20%, or 30% of the volume of the material. In some cases, the composite material may include less than 10 weight %, 20 weight %, or 50 weight % of the particulates. In some cases, particulate reinforcement may comprise inorganic or organic particles or fibers, for example a polyimide or silicone polymer containing milled para-aramid (Kelvar®) reinforcing particulates. In some embodiments, a flexible layer may comprise a flexible region that allows two regions or sections of the flexible layer on the opposite sides of the flexible region to be displaced relative to each other by an amount larger than X % of the thickness of the flexible layer without being damaged and/or without disrupting an electrical connection via the flexible region. In some cases, X can be larger than 20%, larger than 50%, larger than 90%, larger than 100%, larger than 150% or larger values. In some cases, such flexible region may comprise one or more conductive lines electrically connecting conductive portion of the two regions or sections. In some cases, the relative displacement between the two regions or sections can be along a direction parallel to a main surface of the flexible layer, or perpendicular to a main surface of the flexible layer.

In some embodiments, a sublayer, a layer, or region of a substrate or structure may be considered to be flexible even though the layer or structure is rendered inflexible due to presence of other layers or a surrounding material, such as an encapsulating material (e.g., a molding compound).

### Examples of Direct Bonding Methods and Directly Bonded Structures

As described above, in some embodiments, two elements (e.g., two layers, a layer and a die, a layer and a substrate, a die and a substrate, or other combinations) can be directly bonded to one another without an adhesive, e.g., by low temperature dielectric-to-dielectricbonding. In some cases, each element may include a non-conductive (e.g., dielectric) field region comprising at least one non-conductive material (dielectric material). In some examples, the non-conductive material (also referred to as dielectric bonding material) can be an inorganic material. A dielectric layer of the first element can be directly bonded to a corresponding dielectric layer of the second element without an adhesive. In some embodiments, the dielectric layer of at least one element may be disposed on a flexible region or flexible layer of the element. In some cases, the flexible region or flexible layer can be a deformable region of layer configured to be deformed without a damage to its morphology or a disruption in electrical connectivity therein. A region of a dielectric layer that is bonded to the corresponding region of another dielectric layer can be referred to as nonconductive bonding region, dielectric bonding region, or bonding region. In some cases, the bonding region of the dielectric layer may have a dielectric bonding surface or bonding surface. The bonding surface of a dielectric layer may be also referred to as a field area or a field region of the dielectric layer. In some examples, the dielectric layer may comprise a inorganic material. In some embodiments, the nonconductive material of the first element can be directly bonded to the corresponding nonconductive material of the second element using dielectric-to-dielectric bonding techniques (e.g., low temperature covalent bonding). In some cases, a first bonding region may have a first bonding surface and a second bonding region may have a second bonding surface. For example, dielectric-to-dielectric bonds may be formed between the first bonding surface of the first element and the second bonding surface of the second element without an adhesive using the direct bonding techniques disclosed at least in U.S. Pat. Nos. 9,564,414; 9,391,143; and 10,434,749, the entire contents of each of which are incorporated by reference herein in their entirety and for all purposes.

In some examples, the bonding surface of the dielectric bonding regions can be polished to a high degree of smoothness (e.g., to improve a dielectric-to-dielectric bond). The bonding surfaces can be cleaned and then activated by exposure to plasma and/or treatment user other etchants or etching processes. The activated surfaces may be rinsed with DI water or other suitable solvents to remove unwanted contaminants from the bonding surface of the substrates. After the rinsing, the cleaned surface is dried in a manner that the respective bonding surfaces are not contaminated prior to the bonding operation. The activation process may enable or facilitate direct dielectric-to-dielectric bonding process. In some embodiments, the activated bonding surfaces or the field area can be terminated with suitable species, such as a nitrogen species.

Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species may comprise nitrogen. Further, in some embodiments, the bonding surfaces can be exposed to fluorine. For example, there may be one or multiple fluorine peaks near layer and/or hybrid bonding interfaces. Thus, in the directly bonded structures, the hybrid bonding interface between two dielectric materials can comprise a very smooth interface with higher nitrogen content and/or fluorine peaks at the hybrid bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes. In various embodiments, the bonding surface prepared by the procedure described above may enable forming a bond between the first and the second element without an intervening adhesive.

In some embodiments, a dielectric layer may include one or more conductive contact pads. A conductive contact pad (also referred to as “contact pad”) comprises a conductive material (e.g., copper, aluminum, nickel, gold, silver, particulate conductors, i.e., carbon nano tubes (CNT) or a metal alloy or alloy of CNT and metal nanoparticles) and may be embedded in the dielectric layer. In some examples, a conductive contact pad may comprise a conductive bonding surface (e.g., a polished conductive surface) that can form a bond with the conductive bonding surface of another conductive contact pad without an adhesive. The bond formed between two contact pads (e.g., via their conductive bonding surfaces), can be an electrically conductive bond.

In some cases, a surface that comprises the bonding surface (dielectric bonding surface) of the dielectric layer and the conductive bonding surface of the conductive contact pad, may be referred to as a hybrid bonding surface. In various embodiments, two hybrid bonding surfaces may form hybrid direct bonds between the first and the second elements without an intervening adhesive. The hybrid direct bond may be formed such that a first dielectric bonding surface of the first element is bonded to a second dielectric bonding surface of second element, and a first conductive bonding surface of the first element is bonded to a second conductive bonding surface of the second element to electrically connect a first contact pad of the first element to a second contact pad of the second element. In some cases, after direct bonding, a hybrid bonding interface between a first hybrid bonding surface of the first element and a second hybrid bonding surface of the second element. A hybrid direct bond or hybrid bond may comprise at least one conductive region, a contact pad, and/or a conductive trace (e.g., a metallic trace) in addition to the dielectric bonding region. In some embodiments, each element may include one or more conductive contact pads and/or other conductive features (e.g., metal traces). In these embodiments, the conductive contact pads and/or other conductive features (e.g., metallic traces) of the first element can be directly bonded to corresponding conductive contact pads and/or conductive features of the second element. For example, a hybrid bonding technique can be used to provide conductor-to-conductor direct bonds along a hybrid bonding interface formed between two conductive bonding surfaces and between covalently direct bonded dielectric-to-dielectric surfaces, prepared as described above. In various embodiments, the conductor-to-conductor (e.g., contact pad to contact pad) direct bonds and the dielectric-to-dielectric direct bonds can be formed using the direct bonding techniques disclosed at least in U.S. Pat. Nos. 9,716,033 and 9,852,988, the entire contents of each of which are incorporated by reference herein in their entirety and for all purposes. Conductive contact pads (which may be surrounded by nonconductive dielectric field regions) may also directly bond to one another without an intervening adhesive.

In some embodiments, the respective contact pads can be recessed below bonding surfaces of the dielectric layer. In some examples, the conductive bonding surface of the contact pads of a dielectric layer can be recessed by less than 30 nm, less than 20 nm, less than 15 nm, or less than 10 nm, for example, or recessed in a range of 2 nm to 20 nm, or in a range of 4 nm to 10 nm, with respect to a bonding surface of the dielectric layer. In some examples, the conductive bonding surface of a contact pad can be recessed below the bonding surface by less than 5 Å, 10 Å, 20 Å, or 100 Å. In some implementations, a conductive feature of a bonding surface may protrude over the bonding surface. In some such implementations, the protrusion of the conductive feature over the bonding surface can be less than 10 nm.

In some embodiments, the dielectric bonding regions are directly bonded to one another without an adhesive at room temperature and, subsequently, the bonded structure is annealed at an elevated temperature (e.g., above room temperature). Upon annealing, the contact pads can expand and contact one another to form a metal-to-metal direct bond. In various implementations, depending on the thermal properties of the flexible substrates and the composition of the conductive pad, the annealing temperature may range from 80° C. to 350° C. and preferably from 120° C. to 300° C. In some cases, an inert or vacuum annealing ambient may be used for the high temperature bonding process. The annealing time may range from 15 minutes to more than 6 hours. In some examples, the annealing times can be proportional to the annealing temperature.

Beneficially, the use of hybrid bonding techniques, such as Direct Bond Interconnect, or DBI®, available commercially from Adeia of San Jose, CA, can enable a high density of pads connected across the hybrid bonding interface (e.g., small or fine pitches for regular arrays). In some embodiments, the pitch of the contact pads, or conductive traces embedded in the bonding surface of one of the bonded elements, may be less than 100 microns, or less than 50 microns or even less than 20 microns. For some applications, the ratio of the pitch of the contact pads to one of the dimensions of the contact pad (e.g., the width or the length of the contact pad) can be less than 20, or less than 10 and sometimes desirably less than 5. In other applications, the width of a contact pad (e.g., a longitudinal distance between two ends for the contact pad) embedded in the bonding surface of one of the bonded elements may range between 0.3 to 30 microns. In various embodiments, the contact pads and/or traces can comprise copper, although other metals may be suitable.

Thus, in direct hybrid bonding processes (herein referred to as direct bonding), the dielectric bonding regions and the contact pads of a first element can be directly bonded to those of a second element without an intervening adhesive and form a bonded structure. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. Similarly, the second element can comprise a singulated element, such as a singulated integrated device die. In other arrangements, the second element can comprise a carrier or substrate (e.g., a wafer).

Various embodiments disclosed herein relate to directly bonded structures in which at least two elements are directly bonded to one another without an intervening adhesive. Such directly bonded structures, which can comprise direct hybrid bonds, may be referred to as Direct Bond Interconnects (DBI®). In particular, directly bonded structures having one or more conductive interconnects (or vias) formed by direct bonding of conductive contact pads and at least one flexible region or layer are described.

In some embodiments, at least one element may comprise a flexible region or a flexible layer, a hybrid bonding surface, and one or more conductive contact pads (herein referred to as contact pads). In some examples, a flexible substrate or a flexible layer may be comprise a flexible or deformable material. In some examples, a flexible substrate or a flexible layer may be a flexible region comprising a deformable material. In some examples, a flexible substrate or a flexible layer may be composed of a flexible or deformable material (e.g., an organic material). In some cases, a flexible substrate or flexible layer may be composed of a flexible or deformable material (e.g., an organic material).

In some embodiments, a first hybrid bonding surface can be formed on a flexible layer or a flexible substrate. In some such embodiments, the flexible region or section of the flexible substrate or layer may comprise at least a portion of the hybrid bonding surface and at least one of the contact pads. In some cases, the one or more contact pads can be electrically connected to conductive traces and/or vias that are at least partially embedded in a flexible region of a flexible substrate or layer.

In some embodiments, another layer or a die (e.g., a component such as an electronic component) comprising a second hybrid bonding surface and at least one second contact pad may be directly bonded to the first hybrid bonding surface of the flexible layer or substrate. The die may comprise an integrated electronic device (e.g., a semiconductor electronic device). In some cases, the die may be directly bonded on the flexible layer or substrate to electrically connect the die to another die directly bonded to the flexible substrate or layer, or to another layer or substrate. Advantageously, the flexible portion of the flexible substrate (or layer) may provide a mechanically flexible electrical connection between the two dies, two layers, two substrates, a die and a substrate, and the like, allowing them to move with respect to each other (e.g., due to thermal expansion) while being electrically connected.

In some cases, the other element can be a second substrate comprising a hybrid bonding surface and a second contact pad. The second substrate may further comprise conductive traces and vias configured to electrically connect the second contact pad and one or more other contact pads of the second substrate. In some embodiments, the second substrate may comprise a flexible region or layer. In some examples, the second substrate may be composed of a flexible (or deformable) material.

As mentioned above a flexible layer, substrate, or region may comprise a flexible, deformable, or otherwise compliant material. In some embodiments, the deformable material can be an organic material comprising a polymer (e.g., liquid crystal polymer and/or a polyimide). In some cases, the deformable material can be transparent in the visible and infrared wavelength range thereby allowing the underlying structure to be imaged. For example, a flexible layer may have an optical transmission larger than 20%, 40%, 50%, 60%, 70%, 80%, or larger values in a wavelength range from 450 nm to 1200 nm, from 500 nm to 1000, or from 400 nm to 800 nm.

In some embodiments, two or more substrates may be stacked on or bonded (e.g., directly bonded) to one another to form a bonded structure and allow electric contact between one or more conductive lines in a first element (e.g., a first die) and one or more conductive lines in a second element (e.g., a second die). In some embodiments, two or more substrates may be stacked and bonded (e.g., hybrid bonded) to one another to form a bonded structure and allow one or both of an electrical path or an optical path between a first element (e.g., a first die) and a second element (e.g., a second die). Conductive contact pads of the first element may be electrically connected to corresponding conductive contact pads of the second element via the conductive pads and conductive lines of the intervening substrates. Any suitable number of elements (e.g., layers) can be stacked to form a multilayer bonded structure. Any number of layers or substrates can be stacked (e.g., daisy-chained) to form a layered structure of any suitable thickness or dimension. In some embodiments, at least one of the layers in the stack of layers may comprise a flexible region or layer or may be composed of a flexible (deformable) material.

Advantageously, a flexible substrate or layer, may reduce a mechanical coupling between the first element and the second element such that a change in the dimensions, or position of the first element or a change of strain in a region of the first element (e.g., due to temperature changes or a mechanical force) of the first element is different from the resulting change in the dimensions, or position of the second element or the resulting change of strain in a region of the second element. In some embodiments, the radius of curvature of a bent flexible substrate can be less than 100 times, less than 50 times, or less than 20 times the thickness of the substrate without disrupting an electrical connection within the substrate.

A substrate or layer that includes a flexible region or layer, a contact pad, and a hybrid bonding surface (configured for hybrid bonding) may be referred to as a flexible hybrid bonding substrate or layer. A structure or stack (e.g., a structure or stack described above) that comprises at least one element having a flexible region or layer, directly bonded to another element, which may or may not include a flexible region or layer, may be referred to as a composite flexible hybrid bonded structure. For example, one or more dies directly bonded to a flexible hybrid bonding substrate may form a composite flexible hybrid bonded structure.

In some cases, a flexible layer or substrates (e.g., a hybrid bonding flexible layer or substrate) may be included in a structure, device, part, or component used in an application where at least a portion of the structure, device, part, or component can move, be stretched, bent, or otherwise deformed during at least a portion of an operational period. Nonlimiting examples of such devices or components may include sensors on a wristband or ring configured for heart rate monitoring (or other health related monitoring), signal emitters arranged on wearable structures to emit signal locations for tracking the wearer's movements, or the like.

The flexible hybrid bonding substrates and layers and the corresponding composite flexible hybrid bonded structures (e.g., comprising one or more dies directly bonded to a flexible hybrid bonding substrate) described below, may allow non-planar die and/or height variation without disrupting electrical connection between components. In some embodiments, multilayer flexible hybrid bonding substrates or layers can provide a higher tolerance of non-planar die and/or height variation compared to single layer flexible hybrid bonded structures.

The direct bonding processes described above typically utilize one or more inorganic dielectric layers as the bonding layer that forms dielectric-to-dielectric direct bonds. However, unlike direct bonding processes, in some embodiments, one or both elements can comprise an organic dielectric bonding layer (referred to herein as an “organic chemical bonding process”). For example, in some embodiments, both elements 1702, 1704 to be bonded can comprise respective organic dielectric bonding layers (such as polyimide or benzocyclobutene (BCB)). In some examples, the bonding layers 1708a and/or 1708b may comprise one or more organic dielectric bonding layers. In some embodiments, one or both elements 1702, 1704 may not include a separate bonding layer. In some such embodiments, one or both elements 1702, 1704 may comprise a single organic material and a bonding surface prepared by polishing and activating a surface of the element. The organic bonding layers on each element 1702, 1704 can be the same material or different materials. In other embodiments, one element can comprise an organic dielectric bonding layer and the other element can comprise an inorganic dielectric bonding layer. In such organic bonding processes, both elements 1702, 1704 can be planarized as explained above. Prior to bonding, the organic layer(s) can be at least partially (e.g., fully) cured so as to form a hardened bonding surface for planarization. Thus, in organic bonding processes, the organic bonding layer(s) may not be in a flowable state at the time of bonding. For elements 1702, 1704 with organic bonding layers, the polishing process may result in planarized surfaces that are sufficiently planar so as to form a bond with the opposing element. For example, in embodiments in which an organic layer is planarized, the planarized surface can have a surface roughness in the range of 0.3 nm to 2 nm. In some embodiments, organic bonding layers may not be planarized at all. As explained above, in various embodiments, organic bonding layer(s) of one or both elements 1702, 1704 can be activated and/or terminated with a suitable species, e.g., utilizing a nitrogen-containing and/or water-containing plasma activation process. The elements 1702, 1704 with one or more organic bonding layers can be brought into contact at room temperature to form dielectric-to-dielectric bonds (e.g., organic-to-organic or organic-to-inorganic bonds). The strength of the bonds (which can comprise covalent bonds) can be, for example, in a range of 1000 mJ/m² to 4000 mJ/m².

In some organic bonding processes, conductive contact features can be at least partially embedded in the organic bonding layer(s). To effectuate contact between opposing contact features, the elements 1702, 1704 can be annealed, e.g., at a temperature below the glass transition temperature or melting point of the organic material(s) used in the bonding layer(s), such that the organic material does not melt or otherwise flow across the initial dielectric bond interface.

### Example Composite Flexible Hybrid Bonded Structures and Flexible Hybrid Bonding Layers

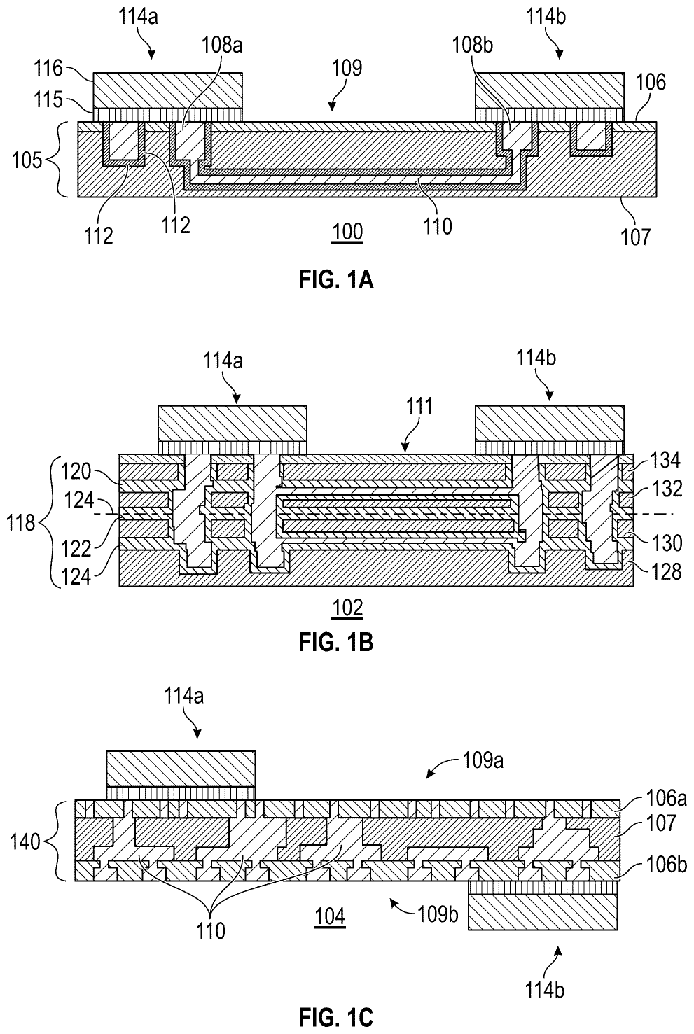

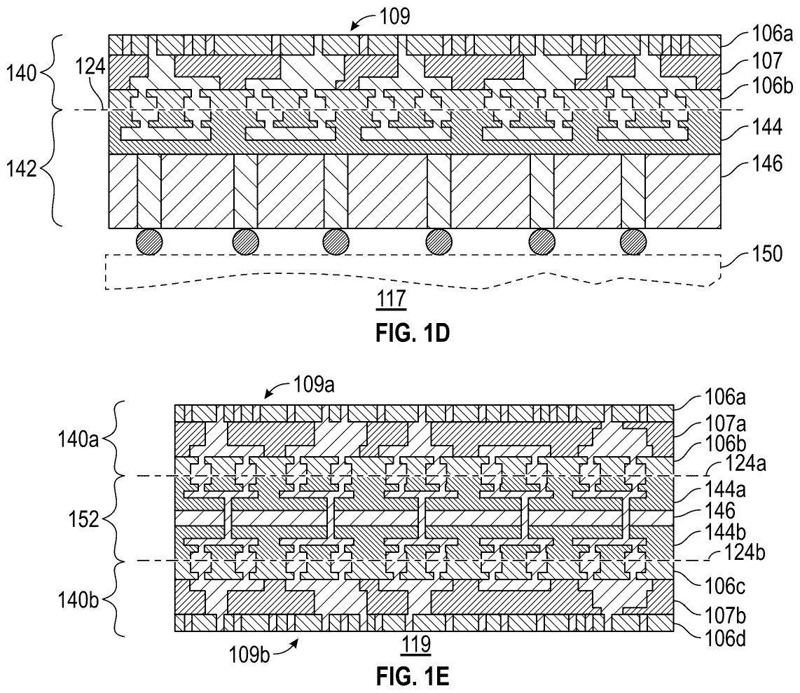

FIG. 1A schematically illustrates an example composite flexible hybrid bonded structure 100 comprising a flexible hybrid bonding layer 105 and at least two components 114a, 114b directly bonded (e.g., hybrid bonded) to two different regions of the flexible hybrid bonding layer 105. In some cases, a component may comprise a passive or active electronic component (e.g., semiconductor electronic component), an integrated device, a die, an electronic circuit, an optical device, a microelectromechanical device, an opto-electronic component, and the like.

The flexible hybrid bonding layer 105 comprises a flexible layer 107 (serving as a core insulating layer) and a dielectric bonding layer 106 (also referred to as a dielectric layer) disposed on the flexible layer 107. The dielectric bonding layer 106 can be an inorganic dielectric layer such as silicon oxide, silicon nitride, silicon oxynitride, or can include carbon, such as silicon carbide, silicon oxycarbonitride, low K dielectric materials, SiCOH dielectrics, silicon carbonitride or diamond-like carbon or a material comprising a diamond surface (such carbon-containing ceramic materials can be considered inorganic, despite the inclusion of carbon). The flexible hybrid bonding layer 105 further comprises two or more contact pads 108a, 108b at least partially embedded in the flexible layer 107 and extending to a hybrid bonding surface 109 of the dielectric bonding layer 106. A first component 114a is directly bonded to a first region of hybrid bonding surface 109 via a first hybrid bonding interface and a second component 114b is directly bonded to a second region of the hybrid bonding surface 109 via a second hybrid bonding interface. One or more contact pads in the first section of the flexible hybrid layer 105 are electrically connected to corresponding contact features of the first component 114a via the first hybrid bonding interface and one or more contact pads in the second section of the flexible hybrid bonding layer 105 are electrically connected to corresponding contact features of the second component 114b via the second hybrid bonding interface. In some embodiments, each one of the components 114a and 114b may comprise a bulk region or layer 116 (in which active circuitry can be formed) and a dielectric bonding layer 115 having a hybrid bonding surface (including an insulating bonding layer with embedded contact features) configured to be directly bonded to respective portions of the hybrid bonding surface 109. In some embodiments, a contact pad 108a in the first section of the flexible hybrid bonding layer 105 may be electrically connected to a contact pad 108b in the second section of the flexible hybrid bonding layer 105 via a conductive line 110. In some examples, the conductive line 110 is at least partially embedded in the flexible layer 107. In some embodiments, a barrier layer 112 (e.g., an isolation layer) may separate a contact pad and/or a conductive line of the flexible hybrid bonding layer 105 from the flexible layer 107. For example, the contact pads 108a, 108b, and/or the conductive line 110 may be formed in an opening having a barrier layer lining. In some examples, the barrier layer 112 may comprise a dielectric material. In some examples, a portion of the barrier layer 112 on a sidewall or bottom portion of contact pads 108a, 108b, may be configured to allow the contact pads 108a, 108b, to be electrically connected via a conductive trace 110. In some cases, the dielectric bonding layer 106 and barrier layer 112 may comprise substantially the same material (e.g., a dielectric material) or have similar compositions. In some cases, the dielectric bonding layer 106 and barrier layer 112 may comprise different material or have different compositions. In some examples, the barrier layer 112 may comprise a conductive material. In some examples, the barrier layer 112 may be configured to protect the corresponding contact pad by blocking or reducing transport of the certain species (e.g., water molecules or gas) from the flexible layer 107 to the contact pad and vice versa. In some cases, at least a portion of the flexible layer 107 extending from the first section to the second section of the flexible hybrid bonding layer 105 may comprise a flexible, mechanically deformable, or otherwise a compliant material as described above.

FIG. 1B schematically illustrates another example composite flexible hybrid bonded structure 102 comprising two components or dies 114a, 114b (e.g., electronic and/or semiconductor components, and the like) directly bonded two separate sections of a flexible substrate or layer 118 comprising a plurality of the flexible sublayers 128, 130, 132, 134. In some embodiments, at least two consecutive flexible sublayers may be separated by a dielectric layer. For example, the dielectric layer 122 between the dielectric sublayers 132 and 130 may comprise a hybrid bonding interface 124 formed by directly bonding two dielectric bonding layers disposed on the flexible sublayers 132 and 130. In some cases, each flexible sublayer 128, 130, 132, or 134 may comprise a conductive region. In some cases, a conductive region may comprise a contact pad, a conductive line, or a conductive via. In some cases, conductive regions of the two consecutive flexible sublayers may be electrically connected via a hybrid bonding interface. A flexible sublayer may include a conductive line electrically connecting a contact pad in the first section of the flexible hybrid bonding layer or substrate 118 to a contact pad in the second section of the flexible hybrid bonding layer or substrate 118. In some implementations, the composite flexible hybrid bonded structure 102 may comprise one or more features described above with respect to the composite flexible hybrid bonded structure 100. For examples, the conductive regions of the composite flexible hybrid bonded structure 102 may be separated from the respective flexible layer by a barrier layer where the barrier layer can be conductive or insulating. In some embodiments, the flexible sublayer 134 (e.g., the top flexible sublayer) on which the components 114a and 114b are directly bonded, comprises a hybrid bonding surface 111, a first contact pad in the first section and a second contact pad in the second section of the flexible hybrid bonding layer (or substrate) 118. A first component 114a is directly bonded to a first region of hybrid bonding surface 111 via a first hybrid bonding interface and a second component 114b is directly bonded to a second region of the hybrid bonding surface 111 via a second hybrid bonding interface. In some examples, the first and second contact pads of the flexible sublayer 134 are electrically connected on one or more conductive regions of the flexible sublayers 128, 130, and 132 via one or more hybrid bonding interfaces. In some embodiments, at least one of the flexible sublayers 128, 130, 132, 134 may comprise a flexible or deformable region extending between first and second components 114a, 114b so as to allow the first and second components 114a, 114b to be displaced relative to each other without disrupting the electrical connection therebetween. In various examples, the relative displacement can be larger than a fraction of a thickness of the composite flexible hybrid bonded structure 102. The fraction can be from 10% to 30%, from 30% to 50%, from 50% to 70%, from 70% to 90%, from 90% to 100%, or larger than 100%.

In some embodiments, the flexible hybrid bonding layer 105 or 118 may be disposed on (e.g., bonded to using an adhesive or direct hybrid bonding techniques) a carrier substrate. The carrier substrate may be configured to support one or more flexible hybrid bonding layers, other substrates or layers, and/or components. In some cases, the carrier substrate can comprise any suitable type of support structure, such as an integrated device die, a wafer, a reconstituted wafer or die, an interposer, etc. The carrier substrate may comprise semiconductor, dielectric (e.g., glass), composite material (e.g., including particulates), metal, or combination thereof. In some embodiments, a carrier substrate may be configured to temporarily support a flexible hybrid bonding layer and may be removed once the flexible hybrid bonding layer is fabricated.

FIG. 1C schematically illustrates another example composite flexible hybrid bonded structure 104 comprising at least two components 114a, 114b directly bonded two opposite main surfaces of a double-sided flexible hybrid bonding layer 140. The double-sided flexible hybrid bonding layer 140 may comprise a flexible layer 107, and two dielectric bonding layers 106a, 106b (dielectric bonding layers), disposed on opposite main surfaces of the flexible layer 107. In some cases, the dielectric bonding layers 106a, 106b may comprise inorganic dielectric materials. The first dielectric bonding layer 106a may comprise a hybrid bonding surface 109a and one or more contact pads or conductive features that are electrically connected to the component 114a, via hybrid bonding interface, and the second dielectric layer 106b may comprise a hybrid bonding surface 109b and one or more contact pads or conductive features that are electrically connected to the component 114b, via another hybrid bonding interface. In some examples, a contact pad in the dielectric layer 106a or 106b, may be extended from a hybrid surface of the respective dielectric layer to an opposite surface of the dielectric layer forming an interface with the flexible layer 107. A contact pad of a dielectric bonding layer 106a may be electrically connected to a contact pad of the dielectric bonding layer 106b, via a conductive region (e.g., a conductive via and traces) within the flexible layer 107.

FIG. 1D schematically illustrates an example flexible hybrid bonding substrate 117 comprising the double-sided flexible hybrid bonding layer 140 (described above with respect to flexible hybrid bonded structure 104) directly bonded to a thick dielectric layer 144 having one or more contact pads and conductive lines. The flexible hybrid bonding substrate 117 may comprise a first dielectric bonding layer 106a (the top dielectric layer) having a hybrid bonding surface 109. In some embodiments, one or two dies may be bonded (e.g., hybrid bonded) on the hybrid bonding surface 109. In some cases, the thick dielectric layer 144 can be formed or disposed on a carrier substrate 146 comprising one or more conductive lines and/or conductive vias. In some cases, a contact pad in a second dielectric bonding layer 106b (the bottom dielectric layer) of the double-sided flexible hybrid bonding layer 140 is electrically connected to a contact pad of the thick dielectric layer 144 via a hybrid bonding interface 124 formed between the second dielectric bonding layer 106b and the tick dielectric layer 144. In some embodiments, the double-sided flexible hybrid bonding layer 140 may be formed over dielectric layer 144 with or without the second dielectric bonding layer 106b by damascene methods. In some embodiments, the carrier substrate 146 can be mounted on a chip package or printed circuit board (PCB) via one or more solder bumps providing electrical connection between the underlying chip package or PCB and a conductive via in the carrier substrate 146. In some embodiments, the chip package or PCB may be electrically connected to a contact pad of the first dielectric bonding layer 106a via conductive regions (e.g., conductive lines, vias, contact pads) of the carrier substrate 146, thick dielectric layer 144, and the double-sided flexible hybrid bonding layer 140. In some examples, the carrier substrate 146 and the thick dielectric layer may comprise inorganic dielectric materials. In some examples, the carrier substrate 146 may comprise glass.

FIG. 1E schematically illustrates an example double-sided flexible hybrid bonding substrate 119 comprising two double-sided flexible hybrid bonding layers 140a, 140b, directly bonded to two opposite hybrid bonding surfaces of a double-sided hybrid dielectric layer 152. The double-sided flexible hybrid bonding substrate 119 may comprise a first dielectric bonding layer 106a (the top dielectric bonding layer) having a first hybrid bonding surface 109a and a second dielectric bonding layer 106d (the bottom dielectric bonding layer) having a second hybrid bonding surface 109b. In some embodiments, one or two dies may be bonded (e.g., hybrid bonded) on the first hybrid bonding surface 109a and/or the second hybrid bonding surface 109b. In some embodiments, the double-sided flexible hybrid bonding layers 140a and/or 140b may comprise one or more features described above with respect to the double-sided flexible hybrid bonding layer 140. In some cases, the double-sided hybrid dielectric layer 152 may comprise a middle layer 146 and two dielectric layers (e.g., dielectric bonding layers) 144a, 144b disposed on two opposite surfaces of the middle layer 146. In some embodiments, the middle layer 146 and dielectric layers 144a, 144b may comprise inorganic dielectric materials. In some examples, the middle layer 146 may comprise glass. In some embodiments, the middle layer 146 may comprise a device die, a wafer, a substrate, a package or a flat panel. In some examples, the middle layer 146 may comprise semiconductor devices, and back end of line (BEOL) wiring and/or a redistribution layer (RDL) to provide electrical connection to or between semiconductor devices. In some cases, portions of the middle layer 146 may further comprise dielectric layers 144a, 144b formed on opposite major surfaces of the middle layer 146. The dielectric layers 144a, 144b may comprise dielectric bonding surfaces forming hybrid bonding interfaces 124a and 124b with dielectric bonding layers 106b, 106c, of the double-sided flexible hybrid bonding layers 140a, 140b.

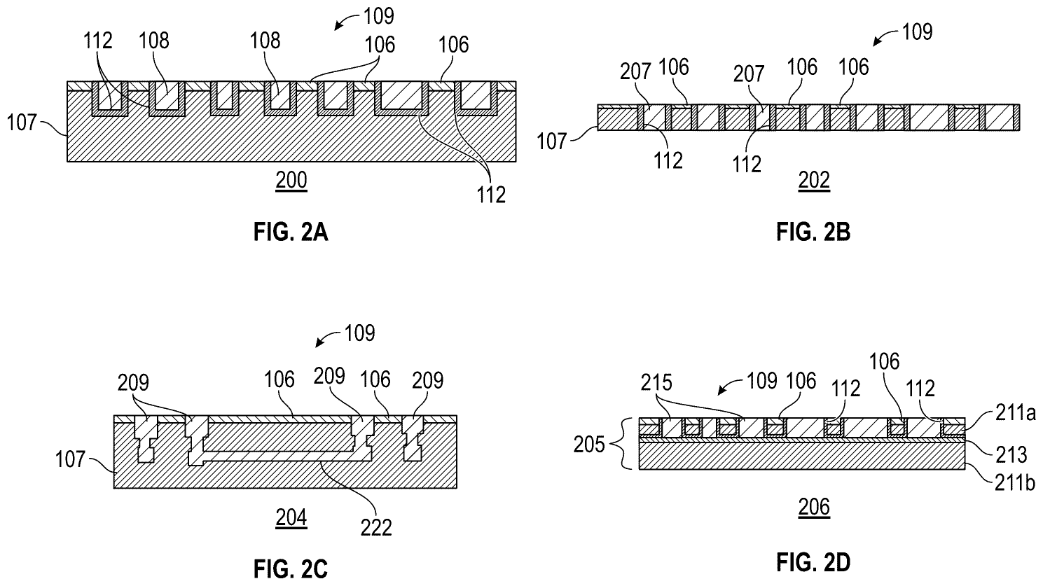

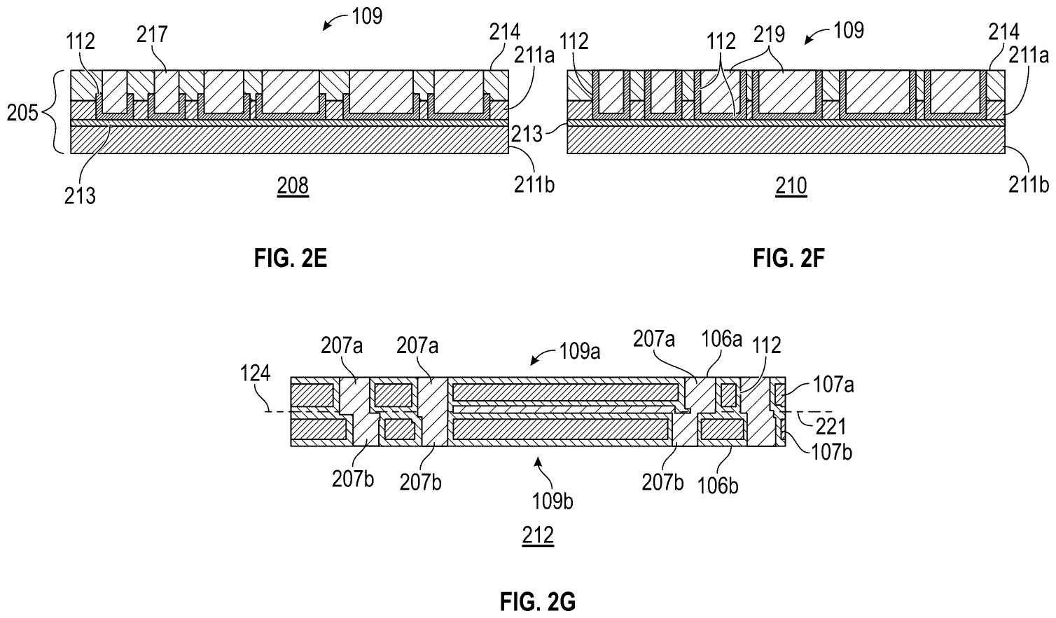

FIG. 2A schematically illustrates a flexible hybrid bonding layer 200 comprising a flexible layer 107, a dielectric bonding layer 106, one or more contact pads 108, and a hybrid bonding surface 109 over the dielectric bonding layer 106. The contact pads 108 are formed within openings extending from the hybrid bonding surface 109 to the flexible layer 107, e.g., using a damascene method. A barrier layer 112 lining the internal surface (e.g., bottom surface and sidewall surface) of an opening may separate a contact pad from the flexible layer 107. In some cases, at least a portion of the flexible layer 107 includes a flexible region or sublayer comprising a deformable or a compliant material. In some cases, the flexible region or layer may extend between a first and a second contact pad of the contact pads 108. The first and second contact pads can be electrically connected by a conductive line at least partially embedded in the flexible layer 107. In some cases, the flexible region or layer may be configured to allow the first and second contact pads be displaced relative to each other without disrupting the electrical connection therebetween. In various examples, the relative displacement can be larger than a fraction of a thickness of the composite flexible hybrid structure 200 The fraction can be from 10% to 30%, from 30% to 50%, from 50% to 70%, from 70% to 90%, from 90% to 100%, or larger than 100%.

FIG. 2B schematically illustrates a flexible hybrid bonding layer 202 comprising a flexible layer 107, a dielectric bonding layer 106 disposed on the flexible layer 107, one or more contact pads 207, and a hybrid bonding surface 109 comprising surface regions of the dielectric bonding layer 106 and contact pads 207, where the contact pads extend from the hybrid bonding surface 109 to an opposite surface of the flexible hybrid bonding layer 202. The contact pads 207 may comprise conductive vias extending from the hybrid bonding surface 109 to the opposite surface of the flexible hybrid bonding layer 202. A barrier layer 112 lining the sidewall surface of a through hole within, which a conductive via is formed, may separate a contact pad from the flexible layer 107. In some embodiments, a surface of the flexible layer 107 opposite to the hybrid bonding surface 109 may comprise a second hybrid bonding surface. In some examples, the second hybrid bonding surface may comprise a second dielectric layer disposed on the flexible layer 107. In some embodiments, two flexible hybrid bonding layers similar to flexible hybrid bonding layer 202 may be directly bonded to form a double-sided flexible hybrid bonding layer.

FIG. 2C schematically illustrates a flexible hybrid bonding layer 204 comprising a flexible layer 107, one or more contact pads 209, a hybrid bonding surface 109, and a conductive line 222 electrically connecting two or more contact pads of the contact pads 209. The contact pads 209 are formed within openings extending from the hybrid bonding surface 109 to the flexible layer 107. The contact pads 209 and the conductive line 222 can be directly in contact with the flexible layer 107. In some embodiments an inorganic nitride layer (not shown) may be disposed on the top portion of the conductive line 222.

FIG. 2D schematically illustrates a flexible hybrid bonding layer 206 comprising a flexible layer 205, a dielectric bonding layer 106 disposed on the flexible layer 205, one or more contact pads 215, and a hybrid bonding surface 109 formed on the dielectric bonding layer 106. The flexible layer 205 comprises two flexible sublayers 211a, 211b separated by an intermediate layer 213. The contact pads 215 are formed within openings extending from the hybrid bonding surface 109 to the intermediate layer 213. The side walls of a contact pad may be separated from a first flexible sublayer 211a by a barrier layer 112 and a bottom portion of the contact pad may be separated from the second flexible sublayer 221b by the intermediate layer 213. In some cases, the conductive barrier may comprise titanium (Ti), titanium nitride (TiN), tantalum (Ta), tantalum nitride (TaN), tantalum oxide (tantalum with a small amount of oxygen content, tungsten (W), tungsten nitride (WN), cobalt-phosphorus alloy (CoP), cobalt-tungsten alloy CoW, Cobalt silicate (CoSi,) Nickel-Vanadium (NiV), and combinations thereof.

FIG. 2E schematically illustrates a flexible hybrid bonding layer 208 comprising a flexible layer 205, a thick dielectric layer 214 disposed on the flexible layer 205, one or more contact pads 217, and a hybrid bonding surface 109 formed on the thick dielectric layer 214 (also referred to as a dielectric bonding layer 214). The flexible layer 205 comprises two flexible sublayers 211a, 211b separated by an intermediate layer 213. The contact pads 215 are extended from the hybrid bonding surface 109 to a portion of the first flexible sublayer. The sidewalls of a bottom portion of a contact pad within the first flexible sublayer 211a may be separated from the first flexible sublayer 211a by the barrier layer 112. The barrier layer 112 may also separate a bottom surface of a contact pad from the intermediate layer 213, respectively. In some examples, sidewalls of a top portion of the contact pad within the thick dielectric layer 214 may form an interface with the dielectric material without any intervening layer.

FIG. 2F schematically illustrates a flexible hybrid bonding layer 210 comprising a flexible layer 205, a thick dielectric layer 214 disposed on the flexible layer 205, one or more contact pads 219, and a hybrid bonding surface 109 formed on the thick dielectric layer 214. The flexible hybrid bonding layer 210 may comprise one or more features described above with respect to the flexible hybrid bonding layer 208, however the barrier layer 112 may extend to a top portion the contact pads 219 within the thick dielectric layer 214 to separate of the sidewalls of the contact pad from the thick dielectric layer. In some embodiments, the thickness of the thick dielectric layer 214 can be larger than 1.3 microns or 2 microns. In some embodiments, the thickness of the thick dielectric layer 214 can be larger than 0.53%, 510%, of the sum of the thicknesses of the flexible sublayers 211a and 211b.

FIG. 2G schematically illustrates a double-sided flexible hybrid bonding layer 212 comprising two opposing hybrid bonding surfaces 109a, 109b, two directly bonded double-sided flexible hybrid sub-layers between the two hybrid bonding surfaces 109a, 109b. A first double sided flexible sub-layer includes a first flexible layer 107a and a second double-sided flexible sub-layer includes a second flexible layer 107b, where the two flexible layers 107a, 107b are separated by a dielectric layer 221 having a direct bonding interface and formed by directly bonding of the first and second flexible hybrid sub-layers. In the example shown, the dielectric layer 221 may be formed by directly bonding a first dielectric layer disposed on the first flexible layer 107a opposite to a first hybrid bonding surface 109a, and a second dielectric layer disposed on the second flexible layer 107b opposite to a second hybrid bonding surface 109b. Each flexible hybrid sub-layer comprises one or more contact pads 207a, 207b. A first contact pad of the first flexible hybrid sub-layer may extend from the first hybrid bonding surface 109a to the hybrid bonding interface 221 where it is electrically connected to a second contact pad of the second flexible hybrid sub-layer 107b, the second contact pad extending from the second hybrid bonding surface 109b to the hybrid bonding interface 221.

In various embodiments, the hybrid bonding surfaces 109, 109a, or 109b, of the example flexible hybrid bonding layers 200, 202, 204, 206, 208, 210, 212 described above may have dielectric bonding regions comprising surface regions of the dielectric bonding layers 106, 106a, 106b, 214 and conducive regions comprising the surface regions of the respective contact pads. In some embodiments additional flexible hybrid sub-layers may be directly bonded over the bonding surfaces 109a or 109b as needed, to form a multilayer flexible hybrid sub-layer stack.

Various hybrid bonding layers, substrates, and structures described above may be used to fabricate structures, substrates, devices, and systems, e.g., by providing electrical connections between chips, processors, memories, electrical devices (e.g., inductors, capacitors, and the like), integrated circuits (e.g., controllers, voltage regulators, and the like), e.g., to connect multilayer chips/stacks to larger devices that cannot be integrated within the stack, to fabricate more compact systems, to allow deformable connection between different parts, section, and components of an electronic system, or to provide other benefits. Example hybrid bonding substrate and structures that may comprise the layers, substrates, and structures described above are discussed in U.S. Patent Application number ______ filed on Dec. 20, 2024, Attorney Docket No. TSSRA.243A, entitled “COMPOSITE HYBRID BONDED STRUCTURES,” which is hereby incorporated by reference herein in its entirety and for all purposes.

### Example Fabrication Methods

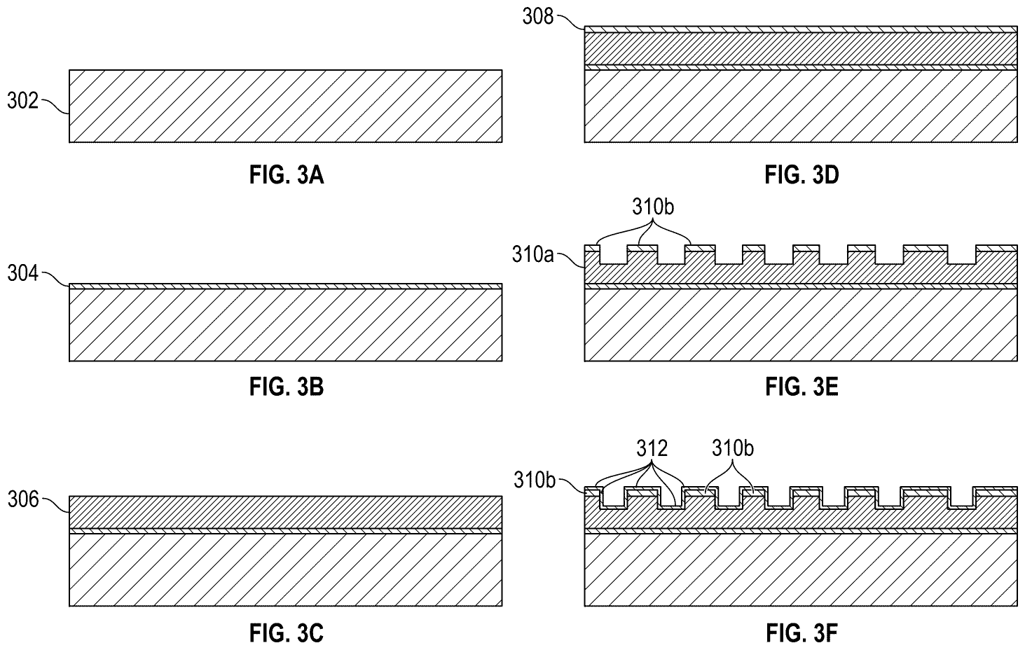

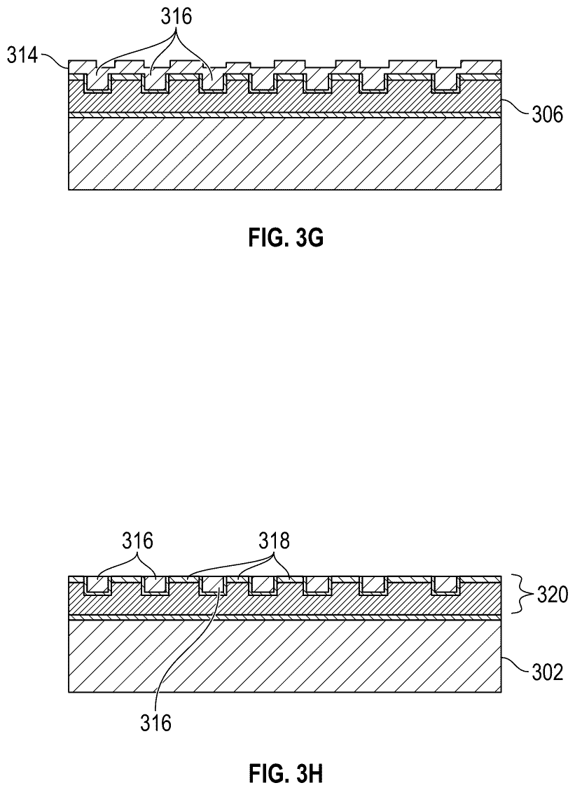

FIGS. 3A to 3H schematically illustrate selected steps of a process for fabricating an example of the flexible hybrid bonding substrate (or layer) 200. In some embodiments, the flexible hybrid bonding substrate (or layer) 200 may be fabricated on a temporary carrier substrate and then detached from the carrier substrate for usage in a bonded structure or interconnected assembly. At fabrication step 1 (FIG. 3A), a carrier substrate 302 may be provided. In some embodiments, the carrier substrate 302 may comprise a glass substrate. In some cases, the carrier substrate 302 may comprise a semiconductor material or a composite material (e.g., a composite material including one or more particulates), an insulating material, semiconductor material, and conductive material. In some examples, a main top surface of carrier substrate 302 may comprise a planarized and polished surface. At fabrication step 2 (FIG. 3B), an intermediate layer 304 may be coated on main surface (e.g., the top surface) of the carrier substrate 302. In some cases, the intermediate layer 304 can be a temporary intermediate layer that can be removed to detach the carrier substrate 302 from the finished substrate or layer at later fabrication step. In some cases, the intermediate layer 304 may comprise a nitride, or an ultraviolet (UV) radiation or laser or microwave degradable polymer adhesive layer arrangement. At step 3 (FIG. 3C), a flexible layer 306 (also referred to as a core insulating layer) may be disposed above the carrier substrate 302 and on the intermediate layer 304. In some embodiments, the flexible layer 306 may be laminated or coated on the intermediate layer 304. In some examples, the flexible layer 306 may comprise an organic material such as a polymer. In some cases, the flexible layer 306 may contain particulates. The concentration of the particulates in the flexible layer 306 can be less than 10%, 20%, 30%, or 40%. The thickness of the flexible layer 306 can be from 20 to 200 microns. In some cases, the flexible layer 306 may comprise a material (e.g., organic material) having a CTE larger than 5 ppm/° C., and/or less than 70 ppm/° C. In some cases, the flexible layer 306 may comprise a material (e.g., organic material) having a glass transition temperature (Tg) larger than 230° C. At fabrication step 4 (FIG. 3D), a top surface of the flexible layer 306 (opposite to the intermediate layer 304), may be planarized and then coated by a first dielectric layer 308 (also referred to as first dielectric bonding layer). In some case, when the flexible layer 306 is deposited by spin coating, the top surface of flexible layer 306 can be smooth enough for direct deposition of the first dielectric layer 308. In some examples, the thickness of the first dielectric layer 308 can be from 0.1 micron to 1 micron and preferably less than 3 microns. In some cases, the first dielectric layer 308 may comprise an inorganic dielectric, such as silicon nitride (SiN), silicon dioxide (SiO₂) a silicon nitride and silicon dioxide (SiN/SiO₂) composite, or silicon carbide (SiC). In some embodiments, the first dielectric layer 308 may formed by spin coating. In some examples, the planarization process may comprise mechanical polishing, chemical mechanical polishing (CMP), or other polarization and/or polishing processes. In some examples, before planarization, the flexible layer may be degassed prior to coating of the first dielectric layer 308. The degassing process may comprise exposing the flexible layer 306 to elevated temperature in a high vacuum or low-pressure environment. At fabrication step 5 (FIG. 3E), the first dielectric layer 308 (e.g., an inorganic dielectric layer) and the flexible layer 306 are patterned to form a patterned flexible layer 310a by forming one or more openings exposing the underlying flexible layer 306. In some examples, a photoresist may be disposed on the first dielectric layer 308 and then photolithographically patterned to expose one or more regions of the dielectric layer 308. Next, the exposed regions of the first dielectric layer 308 and corresponding regions of the flexible layer 306 are etched, e.g., using an anisotropic etching process such as reactive ion etching (RIE), to form the openings. After the etching process, the photoresist is stripped, and the resulting patterned structure (e.g., the patterned flexible layer 310a and the patterned dielectric layer 310b) is cleaned and degassed. An individual opening may include a bottom surface and a sidewall surface within the patterned flexible layer 310a where a region of the sidewall surface can include a portion of the patterned dielectric layer 310a. At fabrication step 6 (FIG. 3F), a second dielectric layer 312 (also referred to as a barrier layer) is disposed over the patterned flexible layer 310a and patterned dielectric layer 310b to coat the bottom surfaces and sidewall surfaces of the openings. Advantageously, the second dielectric layer 312 coated on the bottom surfaces and sidewall surfaces of the openings formed in the patterned flexible layer 310a may serve as a protection layer (e.g., a moisture barrier) for the underlying patterned flexible layer 310a. In some cases, the first and second dielectric layers 308, 312 may comprise substantially the same material. In some cases, the second dielectric layer 312 (the barrier layer) may comprise Aluminum oxide, SiN/SiO₂, SiN, SiC, or SiOₓN_{y}. The thickness of the second dielectric layer 312 over the bottom surface and the sidewall surfaces of an opening can be from 30 nm to 50 nm, form 50 nm to 70 nm, from 70 nm to 100 nm or any ranges formed by these values. In various implementations, the composition of the second dielectric layer 312 can be different from or substantially identical to that of the first dielectric layer 308. In some embodiments, e.g., when the patterned flexible layer 310a comprises certain polymeric materials that provides sufficient adhesion to the conductive features and the conductive pads are formed from a metal less prone to contamination, deposition of the second dielectric layer 312 can be omitted.

At fabrication step 7 (FIG. 3G), a seed layer (not shown) may be coated on the second dielectric layer 312. In some cases, before coating the seed layer, an adhesion layer (not shown) may be disposed on the second dielectric layer 312 and the seed layer may be coated on the adhesion layer. Next a conductive layer 314 may be disposed on the seed layer to fill the openings thereby forming a plurality of contact pads at least partially embedded in the flexible layer 306. In some cases, the openings may be overfilled with a conductive material to form the conductive layer 314 that extends over the patterned dielectric layer 310b. In some examples, the conductive layer 314 may be formed by electroplating (e.g., in a plating bath containing super-filling additives), evaporation, sputtering, printing, lamination, spin coating, injection molding or other physical or chemical metal deposition processes. In some cases, the thickness of the conductive layer 314 may exceed the depth of an opening (e.g., along z-axis). In some embodiments, after depositing (or coating) the conductive layer 314, the substrate 302 coated with the conductive layer 314 may be annealed at a temperature preferably below the glass transition temperature (T_{g}) of the polymeric layer 306. At fabrication step 8 (FIG. 3H), the conductive layer 314 is polished to remove a portion of the conductive layer 314 above the second dielectric layer 312, the seed layer, and the adhesion layer, to provide a planarized and smooth hybrid bonding surface comprising top conductive surfaces of the contact pads 316 and polished dielectric bonding surface regions 318 (also referred to dielectric bonding regions) therebetween. In some cases, the dielectric bonding surface regions may comprise the second dielectric layer 312. In some cases (such as the example shown), a portion of the second dielectric layer 312 (the barrier layer) may be removed during the polishing process such that the dielectric bonding surface regions comprise the patterned dielectric layer 310b. In some examples, the patterned dielectric layer 310b may serve as an etch or polish stop when removing the second dielectric layer 312. In some cases, a small portion of the patterned dielectric layer 310b may be removed during polishing process. The resulting structure above the carrier substrate 302 can be a flexible hybrid bonding substrate 320 comprising a flexible layer, one or more contact pads, a hybrid bonding surface configured for bonding to a hybrid bonding surface of another element (e.g., an electronic component or another substrate) and providing electrical connection between the one or more contact pads and contact pads in the other element. The hybrid bonding surface of the flexible hybrid bonding substrate 320 may be further prepared for a direct hybrid bonding process by activating the dielectric region (also referred to as the field area).

In some cases, multiple components may be bonded to the hybrid bonding surface of the flexible hybrid bonding substrate 320 to fabricate individual flexible hybrid bonded structures comprising different sections of the flexible hybrid bonding substrate 320.

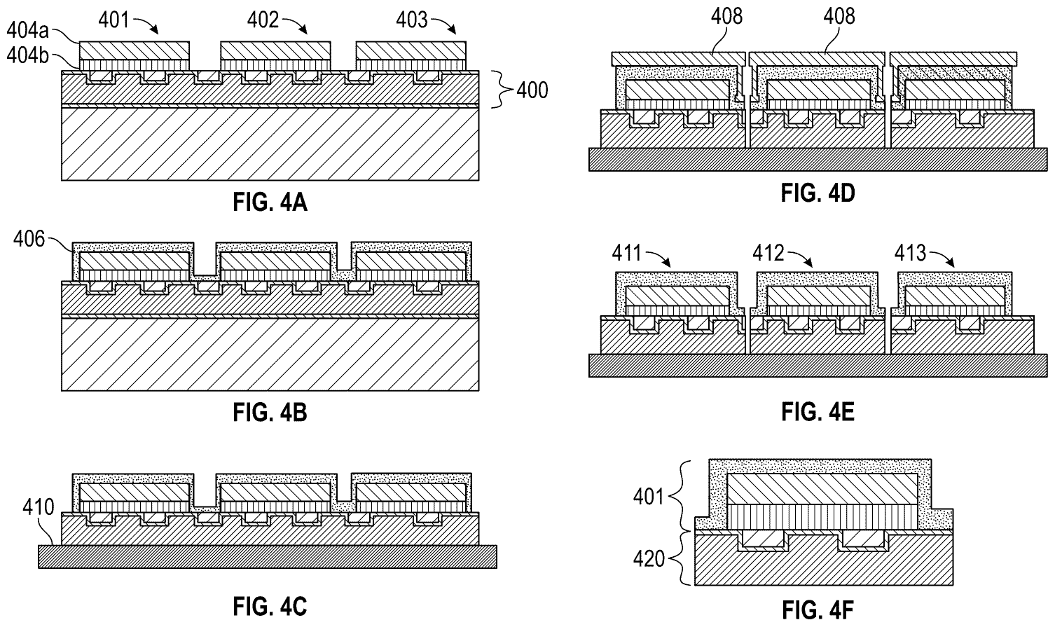

FIGS. 4A-4F schematically illustrate selected steps of a process for fabricating individual flexible hybrid bonded structures using the flexible hybrid bonding substrate 320. At fabrication step 1 (FIG. 4A), one or more individual components or dies (e.g., electronic and/or semiconductor components) each having a hybrid bonding surface are directly bonded to a flexible hybrid bonding substrate 400. In some examples, the hybrid bonding surface of each component is bonded to the hybrid bonding surface of the flexible hybrid bonding substrate 320 using the direct bonding process described above. In the example shown, three dies 401, 402, 403, each having a bulk portion 404a (in which active circuitry can be formed) and a bonding layer 404b, are directly bonded to the flexible hybrid bonding substrate 320. In some examples, the bonding layer 404b may include a hybrid bonding surface comprising a dielectric bonding region and conductive region of a contact pad of the corresponding component. At fabrication step 2 (FIG. 4B), an encapsulating protective layer 406 is coated on the components 401, 402, 403, and on the exposed regions of the hybrid bonding surface of the flexible hybrid bonding substrate 320. In some examples, the encapsulating protective layer 406 may comprise an inorganic dielectric material, such as silicon oxide, silicon nitride, silicon oxynitride, silicon oxynitrocarbide, or any other suitable inorganic dielectric. In some embodiments, a single inorganic layer can be provided. In other embodiments, multiple inorganic layers can be provided over the dies 401, 402, 403. For example, in some embodiments, a first dielectric layer (e.g., silicon nitride or silicon oxide) can be provided as a conformal layer over the dies 401, 402, 403. A second dielectric layer (e.g., silicon oxide) can be provided between adjacent dies as a filler material. In other embodiments, the encapsulating protective layer 406 can comprise a particulate reinforced organic material, such as silicon or silicon oxide, or silicate reinforced elastomer or epoxy resin or other resins. At fabrication step 3 (FIG. 4C), the flexible hybrid bonding substrate 320 is separated from the carrier substrate 302, mounted on a dicing sheet 410, coated with a dicing protective layer 408 (as shown in FIG. 4D), and singulated into individual composite flexible hybrid bonded structures using a dicing process. The protective layer 408 may be configured to protect the underlying structures from damage during the dicing process. The singulation process may comprise mechanical dicing, laser dicing or other suitable singulation methods. In some embodiments, after separating the flexible hybrid bonding substrate 320 from the carrier substrate 302 a bottom surface of the flexible hybrid bonding substrate 320 (opposite to the hybrid bonding surface) may be cleaned to remove the residues of intermediate layer 304, before mounting the flexible hybrid bonding substrate 320 on the dicing sheet 410. At fabrication step 4 (FIG. 4E), the dicing protective layer 408 is removed (e.g., stripped) and the resulting composite flexible hybrid bonded structures 411, 412, 413 are cleaned. In some examples, the protective layer 408 may be removed by dissolving the protective layer 408 in a suitable solvent. In some examples, where the protective layer 408 comprises a photoresist layer, the solvent may comprise a photoresist developer. In some implementations, the stripped dies, flexible substrate and the dicing sheet may be rinsed with a suitable solvent (e.g., DI water) to further remove undesirable contaminants and then dried. The drying procedure may comprise spin drying of the cleaned singulated dies 411, 412 and 413 and dicing sheet. At fabrication step 5 the individual singulated dies 411, 412 and 413 (e.g., composite flexible hybrid bonded structures) are separated from the dicing sheet 410. FIG. 4F illustrates an individual composite flexible hybrid bonded structure comprising a flexible hybrid bonding substrate 420 and a component or die 401 covered by a protective layer. The flexible hybrid bonding substrate 420 includes one or more contact pads electrically connected to an internal electrical circuitry of the component 401, e.g., via a direct bonding interface that provides a conductive connection between the contact pads and contact pads of the component 401.

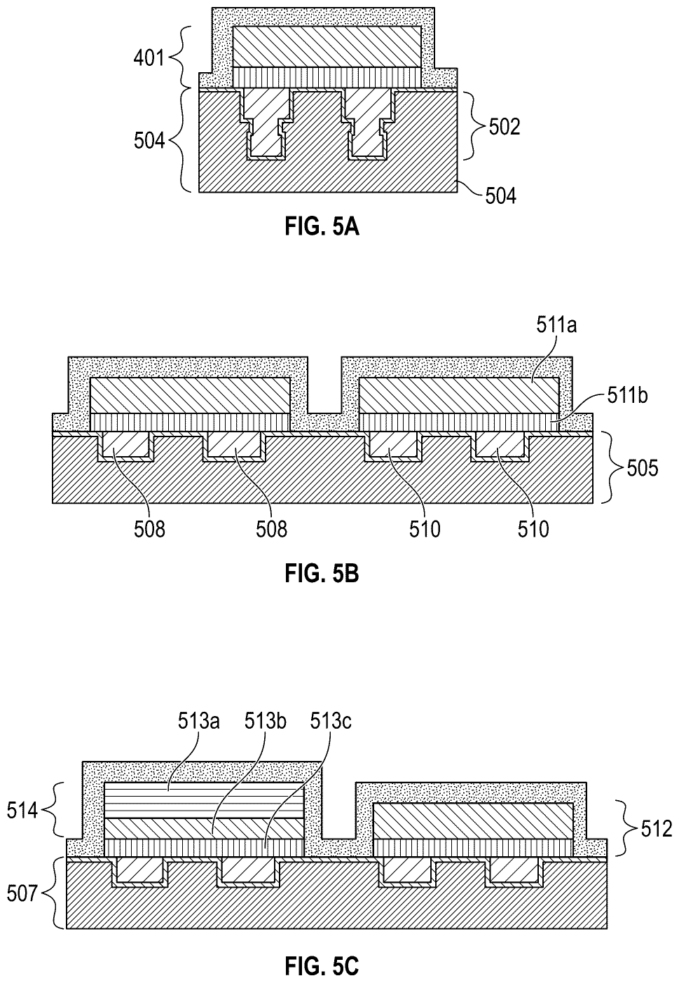

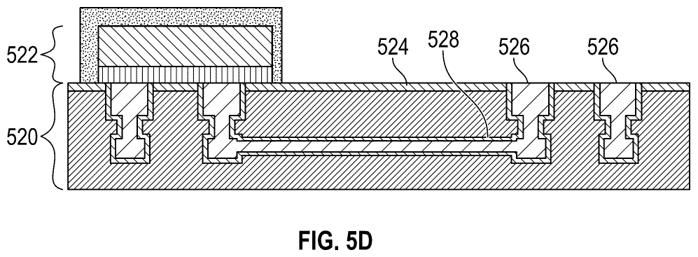

In some embodiments, at fabrication steps 5 to 8 (FIGS. 3E-3H), in addition to contact pads 316, one or more conductive lines can be formed within the patterned flexible layer 310a. The conductive lines can be at least partially embedded in the flexile layer. In some cases, the conductive lines can be separated from the flexible material by a barrier layer having the same composition as (or a different composition from) the second dielectric layer (barrier layer) 312. In some examples, these conductive lines may provide electrical connections between two or more contact pads of the contact pads 316. In some embodiments, the conductive lines within a flexible layer of a flexible hybrid bonding substrate may be formed within different vertical sublayers of the flexible layer. Conductive lines of each sublayer may be connected to the conductive lines of an adjacent sublayer and/or a contact pad of the flexible hybrid bonding substrate by one or conductive vias. In some cases, a conductive via may comprise two directly bonded conductive pads. In some embodiments, the conductive lines may comprise a multilayer BEOL or RDL structure. FIG. 5A schematically illustrates an example composite flexible hybrid bonded structure comprising a die (e.g., an electronic component 401) directly bonded to a flexible hybrid bonding substrate 504 having two vertical conductive stacks. Each conductive stack 502 comprises a contact pad connected to a conductive line embedded in the flexible hybrid bonding substrate 504 by a conductive via. The two contact pads are in electrically connected to the conductive pads of the component 502 via a hybrid bonding interface.

In some embodiments, the flexible hybrid bonding substrates 400, 504, 505, 507, and 520 may comprise one or more features described above with respect to the flexible hybrid bonding substrate 320. In some embodiments, the barrier layers and the dielectric bonding layers of the flexible hybrid bonding substrates 400, 504, 505, 507 may comprise substantially the same dielectric material. After forming the conductive pad for example, a dielectric barrier for example SiN or SiC layer is coated over the conductive layer. In some cases, the flexible (e.g., polymeric layer) may be formed over the dielectric barrier layer and portions of the flexible substrate beneath. The formed structure is planarized to form the flexible hybrid bonding substrate 504.

In some embodiments, an individual composite flexible hybrid bonded structure may comprise a flexible hybrid bonding substrate bonded to two or more components. In some such embodiments, at least two components of the composite flexible hybrid bonded structure may have different number of bonded layers. FIG. 5B schematically illustrates a composite flexible hybrid bonded structure comprising two components directly bonded to a flexible hybrid bonding substrate. A first component is electrically connected to a first pair of contact pads 508, and a second component is electrically connected to a second pair of contact pads 510 of the flexible hybrid bonding substrate. Each component has a single layer bulk portion 511a (in which active circuitry can be formed) and a dielectric bonding layer 511b. FIG. 5C schematically illustrates a composite flexible hybrid bonded structure comprising two components having different structures (e.g., different number of layers). A first component 512 has a dielectric bonding layer and a single layer bulk portion, and a second component 514 has a dielectric bonding layer 513c and a double layer bulk portion comprising first and second layers 513a, 513b.

In some cases, a flexible hybrid composite structure may comprise a flexible hybrid bonding substrate comprising a dielectric bonding layer having a first region and a second region. The first region can be directly bonded to one or more components via one or more contact pads and the second region may comprise one or more exposed conductive surface regions of additional contact pads that are electrically connected to the one or more contact pads of the first region. In some cases, the one or more exposed conductive surface regions may be configured to provide electrical connection between the bonded component and another component, a circuit, another substrate, or the like. FIG. 5D schematically illustrates a hybrid composite structure comprising a component 522 directly bonded to the hybrid bonding layer 524 of the flexible hybrid bonding substrate 520 to provide electrical connection between to component 522 and conductive pads 526 of the flexible hybrid bonding substrate 520 away from the component 522. The conductive pads 526 may be electrically connected to another element by directly bonding the element to the hybrid bonding layer 524. For example, the conductive pads 526 may serve as electrical contacts for testing the electrical connections between component 522 and conductive features in the flexible substrate 520. In other applications, the conductive pads 526 may serve as the electrical contacts for providing power, ground connection, or signals to the component 522 or in some cases, other components bonded to the flexible hybrid bonding substrate 520. In examples, the conductive pads 526 may be configured to be wire bonded to other components.

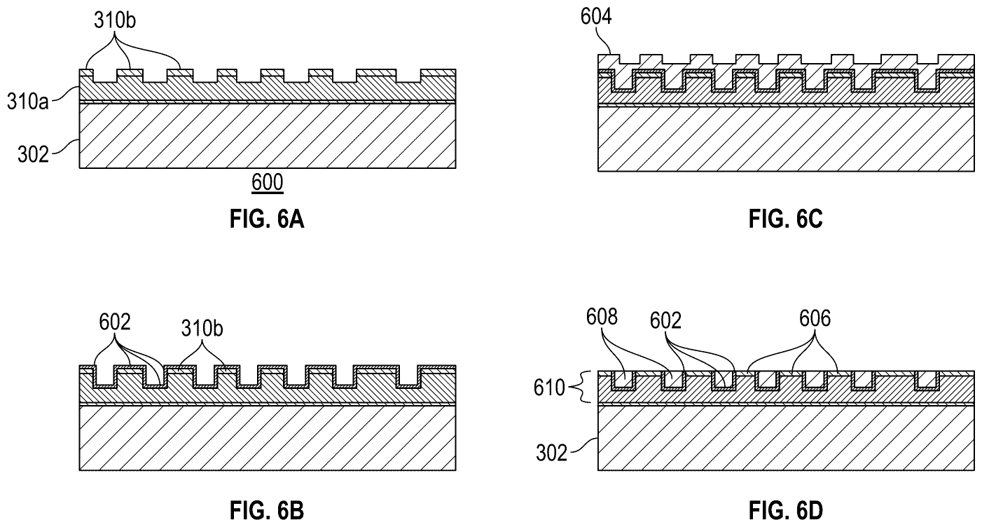

In some embodiments, the flexible layer of a flexible hybrid bonding substrate can be isolated from the conductive pads therein by a conductive barrier layer. For example, with reference to FIG. 3F, the bottom and sidewall surfaces of the openings within which the contact pads are formed may be coated with a conductive barrier layer (instead of the second dielectric layer 312). FIGS. 6A to 6D schematically illustrate selected steps of a process for fabricating an example flexible hybrid bonding substrate having a conductive barrier layer between its conductive pads and the flexible layer. At fabrication step 1 (FIG. 6A), an initial structure 600 similar to the structure shown in FIG. 3A may be formed on a carrier substrate 302. The structure 600 may comprise a patterned dielectric layer 310b comprising one or more openings and a patterned dielectric layer 310b therebetween. In some examples, the initial structure 600 may be formed based on the fabrication steps described above with respect to FIGS. 3A to 3E. At fabrication step 2 (FIG. 6B), a barrier layer 602 (e.g., a conductive barrier layer) may be disposed on the patterned dielectric layer 310a (e.g., the side walls and the bottom surface of the openings) and the patterned dielectric layer 310b. In some cases, before depositing the barrier layer 602 the flexible layer may be degassed and cleaned. Advantageously, the barrier layer 602 may serve as a moisture barrier and prevents migration of conductive material (e.g., copper) into the patterned flexible layer or a neighboring dielectric. In some cases, when the barrier layer 602 is conductive it can allow connection to a conductive pad or another conductive region. In some examples, the conductive barrier layer 602 may comprise tantalum, titanium, nickel, cobalt, tungsten and their respective alloys and combination thereof for example TaN, TaN/Ta, TiN, TiN/Ti TiW, TiW/Ti. The thickness of the conductive barrier layer can be from 5 nm to 100 nm over the bottom surface and from 5 nm to 100 nm over the sidewall surface of an opening. At the fabrication step 3 (FIG. 6C), a seed layer may be coated on the barrier layer and a conductive layer 604 may be disposed on the over the barrier layer to fill the openings thereby forming contact pads. In some cases, the openings may be overfilled with a conductive material to form the conductive layer 604 that extends over the patterned dielectric layer 310b. In some examples, the conductive layer 604 may be formed by electroplating (e.g., in a plating bath containing super-filling additives), evaporation, sputtering, or other physical or chemical metal deposition processes. In some cases, the thickness of the conductive layer 604 may exceed the depth of an opening (e.g., along z-axis). In some embodiments, the seed layer material may be different from that of the coated metal. For example, the seed layer coated over the barrier layer may comprise an alloy of copper (not shown) and the conductive metal 604 can be copper or a copper alloy different from the alloy of the seed layer. In another example, the seed layer may comprise an alloy of nickel and the coated conductive layer 604 can comprise copper. At fabrication step 4 (FIG. 6D), the conductive layer 604 is polished to remove a portion of the conductive layer 604 above the barrier layer 604 and the second dielectric layer, to provide a planarized and smooth hybrid bonding surface comprising top conductive surfaces of the contact pads 608 and polished dielectric bonding surface regions 606 (also referred to dielectric bonding regions or field regions) therebetween. The resulting structure above the carrier substrate 302 can be a flexible hybrid bonding substrate 610 comprising a flexible layer, one or more contact pads 608 isolated from the flexible layer at least by a barrier layer 602, and a hybrid bonding surface configured for bonding to a hybrid bonding surface of another element (e.g., an electronic component or another substrate) and to provide electrical connection between the one or more contact pads 608 and contact pads in the other element. The hybrid bonding surface of the flexible hybrid bonding substrate 610 may be further prepared for a direct hybrid bonding process, by activating the polished dielectric bonding surface regions 606.

In some embodiments, where the patterned flexible layer 310a comprises a high temperature polymeric material, e.g., a high temperature epoxy such as a novolac epoxy or benzocyclobutene (BCB), a seed layer may be disposed on the patterned flexible layers 310a and the patterned dielectric layer 310b prior to deposition of the conductive layer 604, in these embodiments, deposition of the barrier layer 602 maybe omitted.

In various implementations, similar to the flexible hybrid bonding substrate 320 the flexible hybrid bonding substrate 610 may be directly bonded to one or more elements (e.g., one or more components or dies) to form individual composite flexible hybrid bonded structures. For example, the process described above with respect to FIGS. 4A-4F may be used to fabricate individual composite flexible hybrid bonded structures each comprising a separated section of the flexible hybrid bonding substrate 610 directly bonded to a component.

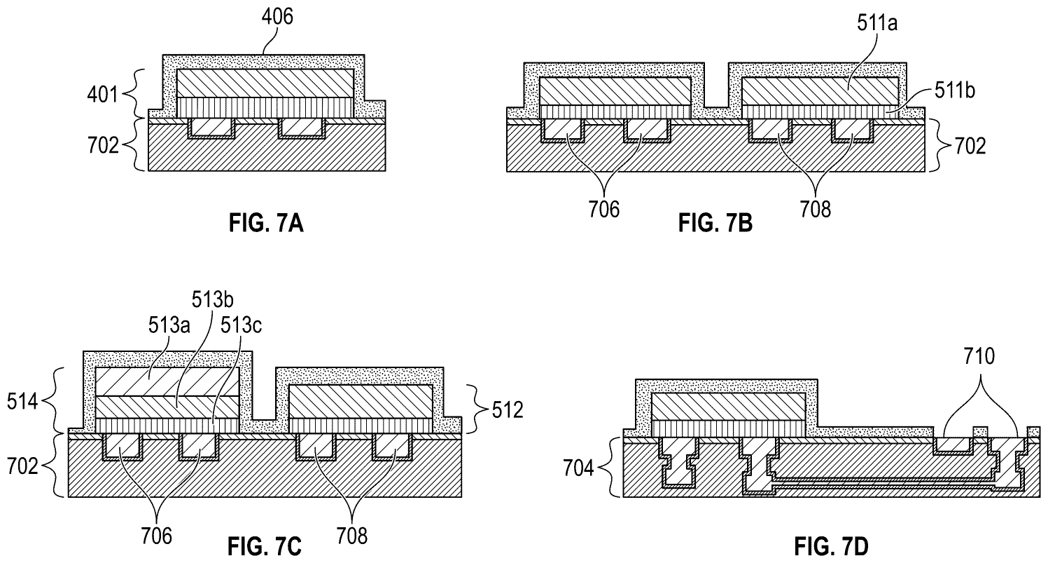

FIG. 7A schematically illustrates a singulated section of the flexible hybrid bonding substrate 610 directly bonded to a component 401 covered by a protective layer 406. The singulated flexible hybrid bonding substrate includes at least one contact pad that is electrically connected to an internal electrical circuitry of the component 401, e.g., via a directly bonded interface that includes a conductive connection between the contact pad and a contact pad of the component. In some cases, a composite flexible hybrid bonded structure may include a flexible hybrid bonding substrate having multiple conductive layers, each layer comprising a via, a conductive line, a contact pad, or a combination thereof wherein at least one contact pad is isolated from the corresponding flexible layer by a barrier layer (e.g., conductive barrier layer). FIG. 7B schematically illustrates a composite flexible hybrid bonded structure formed by direct bonding of two components to a flexible hybrid bonding substrate 702 having two pairs of contact pads 706, 708. A first component 514 is electrically connected to a first pair of contact pads 706, and a second component is electrically connected to a second pair of contact pads 708. In some examples, the two components can be substantially identical and each may comprise a dielectric bonding layer 511b and a single layer bulk portion 511a. FIG. 7C schematically illustrates a composite flexible hybrid bonded structure comprising two components having different structures (e.g., number of layers) directly bonded to the flexible hybrid bonding substrate 702. A first component 514 is electrically connected to a first pair of contact pads 706, and a second component 512 is electrically connected to a second pair of contact pads 708 of the flexible hybrid bonding substrate 704. The first component 514 can have a dielectric bonding layer 513c and a double layer bulk portion (e.g., comprising a first and a second bulk portions 513a, 513b). The first bulk portion 513a may have a bonding dielectric layer and conductive features therein (not shown) that can be directly bonded to the second bulk portion 513b. The second bulk portion 513b may have a through via electrode (not shown) configured to electrically communicate with the bonding surface of the first bulk portion 513a. In some cases, both components and the exposed portion of the dielectric bonding surface of the flexible hybrid bonding substrate 702 in the composite flexible hybrid bonded structures shown in FIGS. 7A and 7B may be covered by an encapsulating protective layer.

FIG. 7D schematically illustrates a composite flexible hybrid bonded structure comprising a component, having a dielectric bonding layer and a single layer bulk portion, bonded to a flexible hybrid bonding substrate 704. The components can be directly bonded to a hybrid bonding surface of the flexible hybrid bonding substrate 704 having contact pads isolated from the corresponding flexible layer by a barrier layer (e.g., conductive barrier layer). In some cases, the component and the exposed portion of the dielectric bonding surface of the flexible hybrid bonding substrate 704 may be covered by an encapsulating protective layer. In some embodiments, the flexible hybrid bonding substrate 704. In some embodiments, the flexible hybrid bonding substrate 704 may comprise one or more contact pads 710 configured to serve as electrical contacts for testing the electrical connections between component and conductive features in the flexible hybrid bonding substrate 704 and/or for providing power, ground connection, or signals to the components bonded to the flexible hybrid bonding substrate 704. In examples, portions of encapsulating protective layer formed on the conductive pads 710 may be removed (e.g., etched) to expose the conductive surface of the contact pads 710 for electrical connection. In examples, the conductive pads 710 may be configured to be wire bonded to other components.

In some cases, a first region of the flexible hybrid bonding substrate 610 may be directly bonded to one or more components via one or more contact pads and the second region may comprise one or more exposed conductive surface regions of additional contact pads that are electrically connected to the one or more contact pads of the first region. In some cases, the one or more exposed conductive surface regions may be configured to provide electrical connection between the bonded component and another component, a circuit, another substrate, or the like.

In some embodiments, at least a portion of any the flexible hybrid bonding substrates 320, 504, 505, 507, 702, or 704 extending from a first region to a second region of the flexible hybrid bonding substrate, can be mechanically flexible or deformable such that the second region can be displaced with respect to the first region within a small displacement range without causing a mechanical damage to the flexible hybrid bonding substrate and/or disrupting an electrical connection between the first and second sections. In some examples, the first region may be directly bonded to a first element and the second region may be directly bonded to a second element. Each of the first and second regions may comprise one or more contact pads. In some cases, the first and second region can be separated along a direction parallel to a hybrid bonding surface of the flexible hybrid bonding substrate. In some cases, a lower bound of the small displacement range can be from 10% to 30%, from 30% to 50%, from 50% to 70%, from 70% to 90%, from 90% to 100%, of the thickness of the flexible substrate.

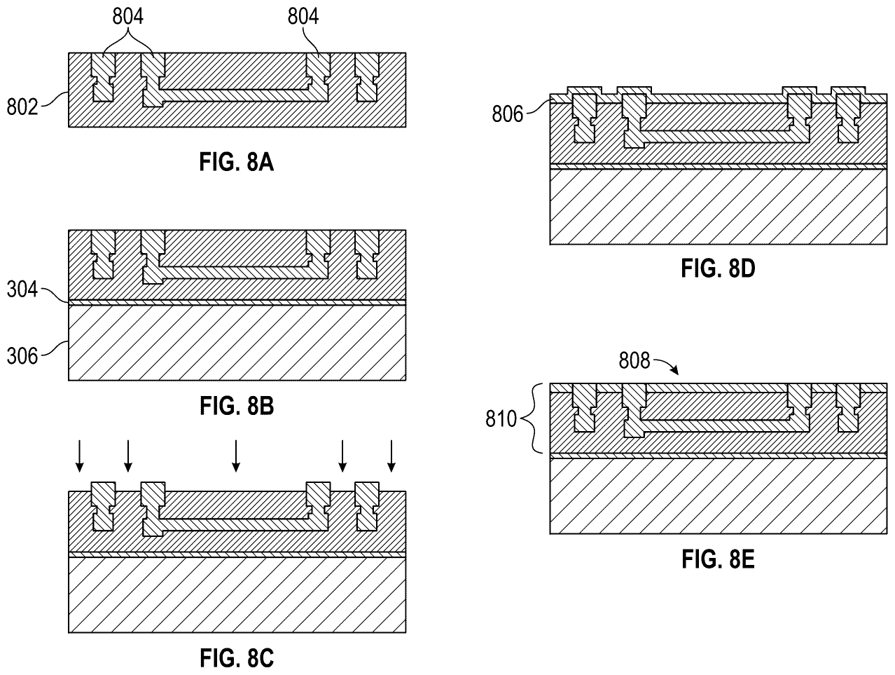

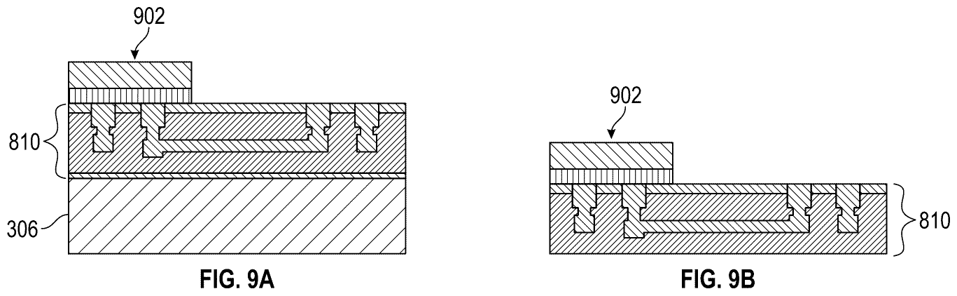

In some embodiments, a flexible hybrid bonding substrate may include contact pads and/or conductive lines that are directly in contact with a flexible layer or portion. FIGS. 8A to 8E schematically illustrate selected steps of a process for fabricating an example of such flexible hybrid bonding substrate. At fabrication step 1 (FIG. 8A), a flexible layer 802 having one of more contact pads 804 may be provided. In some examples, the flexible layer 802 may include at least one conductive line. In some such examples, the conductive line can be embedded in the flexible layer 802. In some cases, the conductive line may electrically connect two contact pads of the flexible layer 802. At fabrication step 2 (FIG. 8B), the flexible layer 802 may be attached (e.g., laminated) to a main surface of a carrier substrate 306 using an intermediate layer 304. At fabrication step 3 (FIG. 8C), a top surface of the flexible layer opposite to the carrier substrate 306 may be polished (e.g., using chemical mechanical polishing) and then etched to reduce a thickness of the flexible layer 802 and to form protruded portions of the contact pads 804. In some examples, the etching process can be a wet etching process or a dry etching process (e.g., reactive ion etching). At fabrication step 4 (FIG. 8D), the etched surface of the flexible layer 802 may be cleaned and dried, and a dielectric layer 806 (e.g., an inorganic bonding dielectric layer) may be coated over the flexible layer 802. The dielectric layer 806 may cover the exposed regions of the conductive pads 804 and the regions therebetween. At fabrication step 5 (FIG. 8E), the surface of the dielectric layer 806 may be planarized to form a hybrid bonding surface and thereby a flexible hybrid bonding substrate 810. In some embodiments, the flexible hybrid bonding substrate 810 may be separated from the carrier substrate 306 and bonded to one or more components to form flexible hybrid composite structures. In some cases, the individual flexible hybrid composite structures may be formed using singulated sections flexible hybrid bonding substrate 810, e.g., using a process similar to the process described above with respect to FIGS. 4A-4F. In various examples, a component can be directly bonded to the flexible hybrid bonding substrate 810 before or after separating the flexible hybrid bonding substrate 810 from the carrier substrate 306. FIG. 9A illustrates the flexible hybrid bonding substrate 810 directly bonded to a component 902 before being separated from the carrier substrate 306. FIG. 9B illustrates the flexible hybrid bonding substrate 810 directly bonded to a component 902 after being separated from the carrier substrate 306.

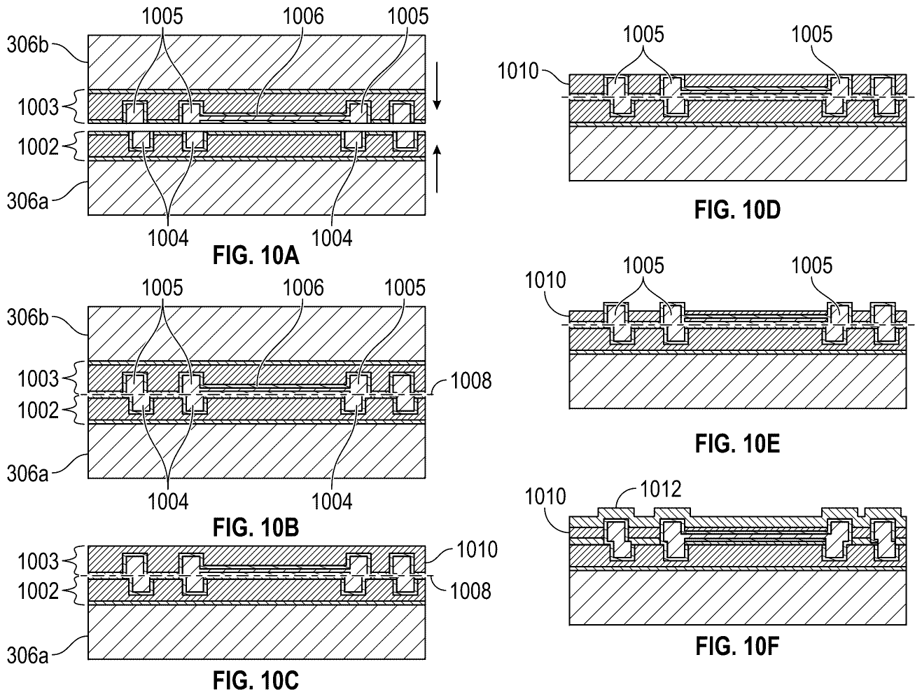

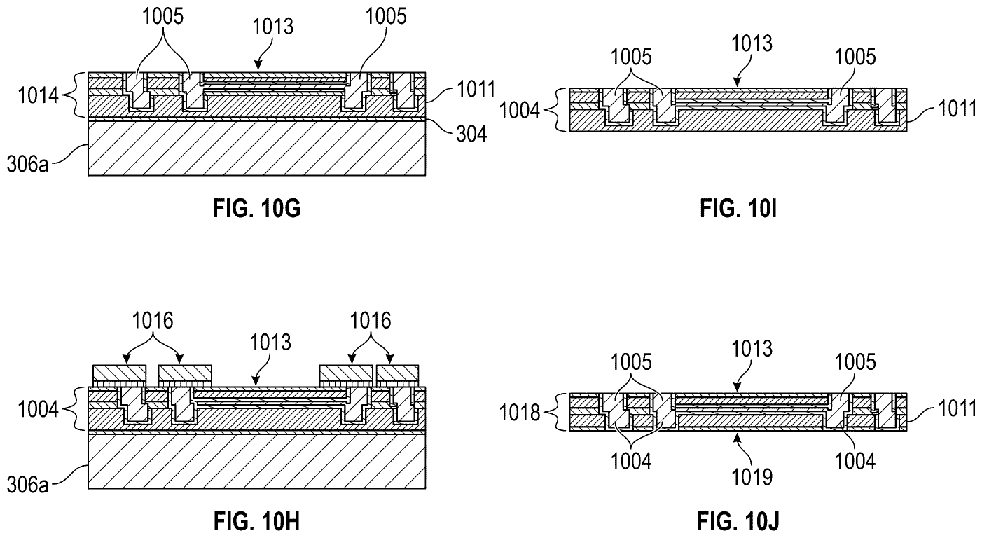

In some embodiments, two flexible hybrid bonding substrates can be directly bonded to form a multilayer flexible hybrid bonding substrate (or structure) comprising embedded conductive lines and conductive vias at least partially formed by connected contact pads as a result of direct bonding. FIGS. 10A to 10G schematically illustrate selected steps of a process for fabricating an example of the multilayer flexible hybrid bonded structure. At fabrication step 1 (FIG. 10A), two flexible hybrid bonding substrates 1002, 1003, may be provided. In various embodiments, the flexible hybrid bonded structures 1002, 1003, may be fabricated on two separate carrier substrates 306a, 306b, respectively, using the methods described above with respect to FIGS. 3A-3H, or FIGS. 6A-6D. At fabrication step 2 (FIG. 10B), the hybrid bonding surface of the two flexible hybrid bonding substrates are put into contact such that at least some of the contact pads 1004 of the first flexible hybrid bonding substrate 1002 are aligned with the contact pads 1005 of the second flexible hybrid bonding substrate. In some examples, the contact pads 1004 and/or contact pads 1005 may have been formed in openings within the respective flexible layer coated with a barrier layer (e.g., a conductive or dielectric barrier layer). Next, the resulting hybrid bonding interface 1008 is annealed (e.g., at a selected temperature for direct bonding) to directly bond the corresponding dielectric bonding layers and electrically connect the respective contact pads 1004, 1005. In some cases, the contact pads 1004, 1005, are electrically connected to conductive lines of the respective flexible hybrid bonding substrates. Some of these conductive lines may provide electrical connection between the contact pads. For example, conductive line 1006 may electrically connect two contact pads of the contact pads 1005. At fabrication step 3 (FIG. 10C), the carrier substrate 306b is detached from the second flexible hybrid bonding substrate 1003 to expose a main surface of the flexible layer 1010 of the second flexible hybrid bonding substrate 1003 opposite to the hybrid bonding interface 1008. At fabrication step 4 (FIG. 10D), the exposed surface of the flexible layer 1010 in polished to remove a portion of the flexible layer 1010 and to reduce a thickness of the flexible layer 1010, e.g., substantially down to a thickness of the contact pads 1005 (along a direction perpendicular to the hybrid bonding interface 1008). In some examples, the polishing process may be stopped at a boundary of a barrier layer defining a bottom of an opening within which a contact pad of the contact pads 1005 is formed. The polishing process may comprise mechanical milling, CMP or a combination thereof. At fabrication step 5 (FIG. 10E), the exposed surface of the flexible layer 1010 may be etched to further reduce its thickness of the flexible layer 1010 and protrude a portion of the contact pads 1005. In some cases, the flexible layer 1010 may be etched using a dry etching process such as plasma etching. At fabrication step 6 (FIG. 10F), a dielectric layer 1012 is disposed over the etched surface of the flexible layer 1010. The thickness of the dielectric layer 1012 can be greater that protruded portions of the contact pads 1005. At the fabrication step 7 (FIG. 10G), the dielectric layer 1012 is polished (e.g., using chemical mechanical polishing) to planarize the dielectric layer 1012 and the protruded portion of the contact pads 1005 and to form a hybrid bonding surface 1013 over the resulting layered flexible hybrid bonded structure 1014. The polishing process may be stopped before the thickness of the portion of dielectric layer 1012 left over the flexible layer 1010 becomes less than 10 nm or less than 5 nm. Next, the resulting hybrid bonding surface 1013 can be activated (e.g., using water and nitrogen plasma treatment or air plasma) and then the layered flexible hybrid bonding substrate 1014 can be cleaned with a suitable solvent to remove contaminating byproducts of the activations process. The cleaned substrate surface 1013 can be rinsed with DI water and dried. The drying step may include a low temperature (e.g., <150° C.) moisture desorption process in vacuum.

Advantageously, the method described above with respect to FIGS. 10A-10G may be used to fabricate a stack of flexible layers comprising a dense arrangement of conductive lines, conductive pads, and conductive vias embedded in multiple flexible layers connected via hybrid bonding interfaces.

In some embodiments, one or more elements (e.g., a substrate, a component, or the like) may be directly bonded to the flexible hybrid bonding substrate 1014 before or after detaching the carrier substrate 306a from the flexible hybrid bonding substrate 1014. In the example shown in FIG. 10H, four components 1016 (e.g., semiconductor electronic components) are directly bonded to the hybrid bonding surface 1013 of the flexible hybrid bonding substrate 1014 to form a flexible hybrid composite structure.

In some embodiments, two multilayer flexible hybrid bonding substrates, or a multilayer flexible hybrid bonding substrate and a single layer flexible hybrid bonding substrate may be directly bonded to make more complex flexible hybrid bonding substrates or structures.

In some embodiments, a multilayer flexible hybrid bonding substrate can be further processed to fabricate a double-sided multilayer flexible hybrid bonding layer e.g., the double-sided flexible hybrid bonding layer 212) comprising two opposing hybrid bonding surfaces each configured to be directly bonded a component, another layer, or a substrate. For example, as shown in FIG. 10I, after fabrication step 7 (FIG. 10G), the two-layer flexible hybrid bonding substrate 1014 may be separated from the carrier substrate 306a and the intermediate layer 304 may be removed to expose a bottom surface of the flexible layer 1011 opposite to the hybrid bonding layer 1013. Next, the flexible layer 1011 may be polished, etched, coated with a second dielectric layer, and then planarized according to fabrication steps 4-6 (FIGS. 10D-10F) to form a second hybrid bonding surface 1019 on the opposite side of the double-sided two-layer flexible hybrid bonding layer 1018 with respect to the hybrid bonding surface 1013 (FIG. 10J). The second hybrid bonding surface 1019 may comprise conductive regions associated with the contact pads 1004 of the first flexible hybrid bonding substrate 1002. The second hybrid bonding surface 1019 may be activated and cleaned for bonding to a component, another substrate, or another layer. In some cases, a double-sided multilayer hybrid bonding layer (e.g., double-sided two-layer flexible hybrid bonding layer 1018) may be used as an intermediate hybrid bonding layer in a multilayer stack, for providing electrical connection between a component and an underlying substrate, or for providing electrical connection between two components on the opposite sides of the double-sided multilayer hybrid bonding layer 1018.

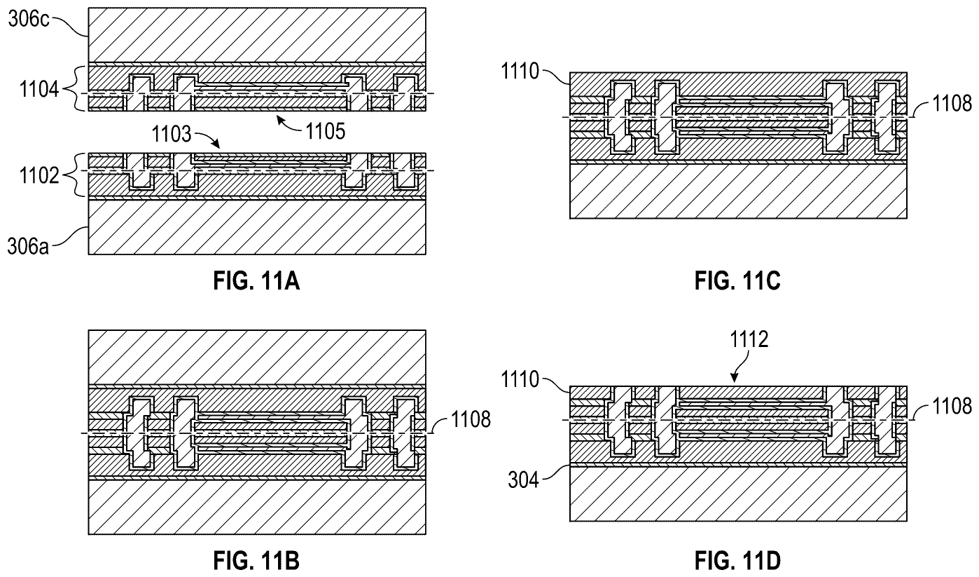

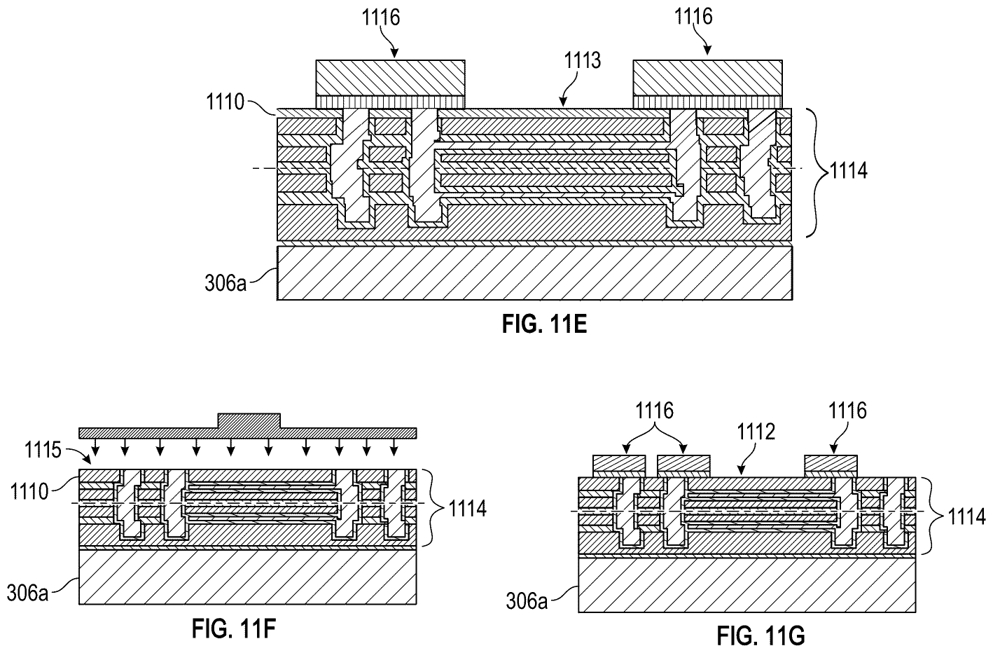

FIGS. 11A to 11E schematically illustrate selected steps of a process for fabricating an example multilayer flexible hybrid bonded structure by directly bonding two multilayer flexible hybrid bonded structures. In the example shown, two multilayer flexible hybrid bonded structures 1102, 1104, each having two flexible layers are directly bonded to form a 4-layer flexible hybrid bonded structure. At fabrication step 1 (FIG. 11A), two two-layer flexible hybrid bonding substrates 1102, 1104, may be provided. The flexible hybrid bonded structures 1002, 1004, may be fabricated on two separate carrier substrates 306a, 306c, respectively, using the methods described above with respect to FIGS. 10A-10G or other methods. At fabrication step 2 (FIG. 11B), the hybrid bonding surfaces 1103 and 1005 of the two two-layer flexible hybrid bonding substrates 1102, 1104, are put into contact such that at least some of the contact pads of the first two-layer flexible hybrid bonding substrate 1102 are aligned with those of the second two-layer flexible hybrid bonding substrate 1104. Next, the resulting hybrid bonding interface 1108 is annealed (e.g., at a selected temperature or temperatures for direct bonding) to directly bond the corresponding dielectric bonding layers and electrically connect the respective contact pads. At fabrication step 3 (FIG. 11C), the carrier substrate 306c is detached from the second two-layer flexible hybrid bonding substrate 1003 to expose a main surface of the flexible layer 1110 of the second two-layer flexible hybrid substrate 1004 opposite to the hybrid bonding interface 1108.

At fabrication step 4 (FIG. 11D), the exposed surface of the flexible layer 1110 is polished to remove a portion of the flexible layer 1110 and to reduce a thickness of the flexible layer 1110, e.g., substantially down to a thickness of the contact pads 1005 (along a direction perpendicular to the hybrid bonding interface 1008) and form a polished surface 1112 comprising top surface regions of the flexible layer 1110 and contact pads 1005. In some examples, the polishing process may be stopped at a boundary of the contact pads 1005. In some other examples, the polishing process may be stopped at a boundary of a barrier layer defining a bottom of an opening within which a contact pad of the contact pads 1005 is formed. The polishing process may comprise mechanical milling, CMP or a combination thereof. In some embodiments, the fabrication process may continue by performing fabrication steps similar to those described above with respect to FIGS. 10D-10G to form a hybrid bonding surface 1113 over the layered flexible hybrid bonding substrate 1114, where the hybrid bonding surface comprises dielectric bonding surface regions of a dielectric (e.g., an inorganic dielectric layer) formed on the flexible layer 1110. In some embodiments, one or more elements (e.g., a substrate, a component, or the like) may be directly bonded to the flexible hybrid bonding substrate 1114 before or after detaching the carrier substrate 306a from the flexible hybrid bonding substrate 1114. In the example shown in FIG. 11F, two components 1116 (e.g., semiconductor electronic components) are directly bonded to the hybrid bonding surface 1113 of the flexible hybrid bonding substrate 1114 to form a flexible hybrid composite structure.

In some other embodiments, at the 4^{th} fabrication step (FIG. 11D), the exposed surface of the flexible layer 1110 may be polished to remove a portion of the flexible layer 1110 and dielectric (or barrier layer) coating of the contact pads and form a planarized organic bonding surface 1112 comprising conductive regions (associated with contact pads) and polished surface regions of the flexible layer 1110 therebetween. In some examples, the polishing process may be stopped after exposing a portion of the contact pad under the dielectric (or barrier layer) coating. The polishing process may comprise mechanical milling, CMP or a combination thereof. In some embodiments, at a fabrication step 5 (FIG. 11F) the organic bonding surface 1112 (formed at the 4^{th} fabrication step, FIG. 11D), may be activated (e.g., using a nitrogen plasma treatment) to form an activated bonding surface 1113 and then rinsed. In some cases, after rinsing, the organic bonding surface 1112 may be dried using a low temperature (e.g., <150° C.) moisture desorption process in vacuum. In some embodiments, one or more elements (e.g., a substrate, a component, or the like) may be bonded to the activated organic bonding surface 1113 before or after detaching the carrier substrate 306a from the flexible hybrid bonding substrate 1114. In the example shown in FIG. 11G, three components 1116 (e.g., semiconductor electronic components) are bonded to the activated organic bonding surface 1113 of the flexible hybrid bonding substrate 1114 to form a flexible hybrid composite structure.

In some examples, the process described above with respect to FIGS. 10A-10G, and 11A to 11E, may be used to fabricate multilayer flexible hybrid bonded structures or substrates having more than 4 flexible layers, more than 10 flexible layers, more than 20 flexible layers, or greater number of flexible layers. In some embodiments, a single layer or multilayer flexible hybrid bonding substrate or structure may be directly bonded to a structure, substrate, or layer that does not include a flexible layer. In some embodiments, at least one layer of a multilayer stack formed by direct bonding may not include a flexible layer or flexible region. In some embodiments, a multilayer stack formed by direct bonding may comprise one or more layers each comprising a flexible layer or flexible region, and one or more layers that do not include a flexible layer or flexible region.

In some embodiments, the four-layer flexible hybrid bonding substrate 1114 can be further processed to fabricate a double-sided four-layer flexible hybrid bonding layer comprising two opposing hybrid bonding surfaces each configured to be directly bonded to a component, another layer, or a substrate. In some cases, such double-sided four-layer flexible hybrid bonding layer may be fabricated using fabrication steps described above with respect to FIGS. 10I and 10J for fabricating the double-sided two-layer flexible hybrid bonding layer 1018.

In some embodiments, a flexible hybrid bonding substrate or layer may be fabricated by forming a patterned conductive layer and then filling the volume between the conductive regions with a flexible (deformable) material. In various embodiments, the patterned conductive layer may be formed using wet etching or thru-mask metal plating.

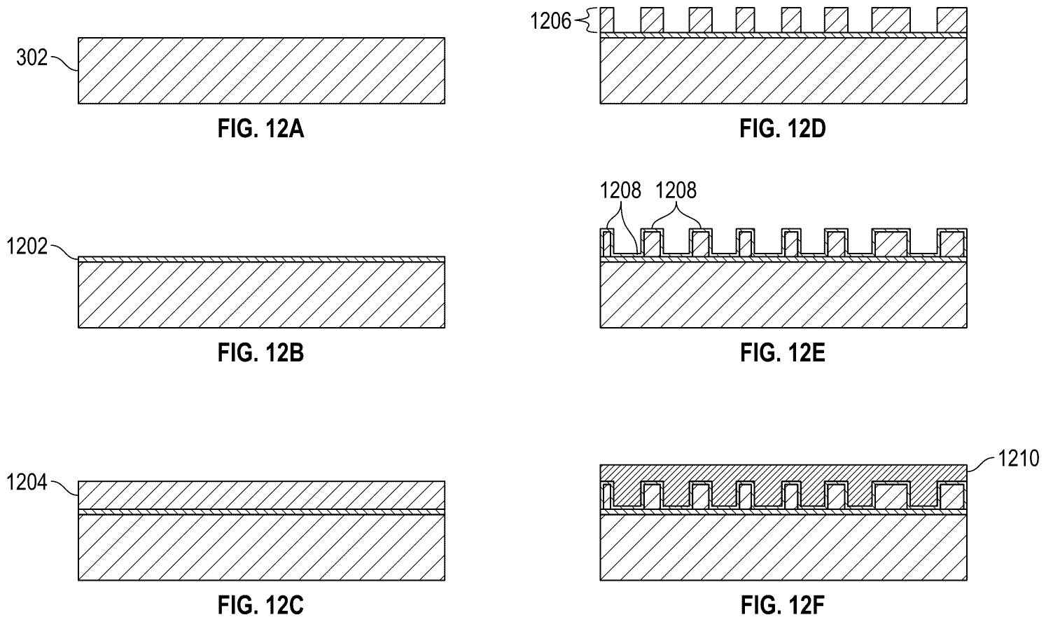

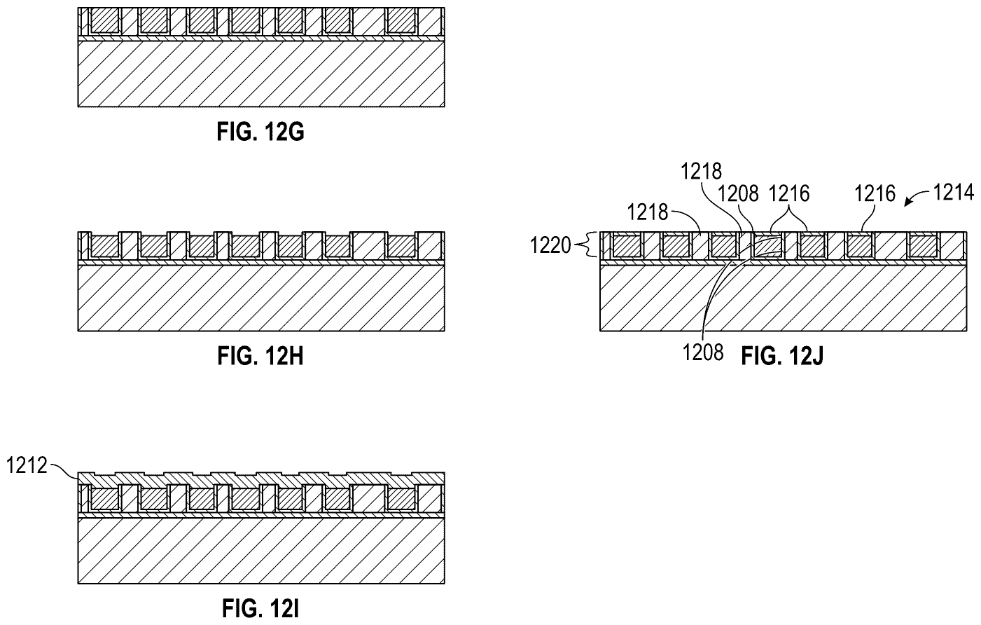

FIGS. 12A to 12J schematically illustrate selected steps of a process for fabricating an example of the flexible hybrid bonding layer or substrate 206 by wet etching of a conductive layer. At fabrication step 1 (FIG. 12A), a carrier substrate 302 may be provided. In some embodiments, the carrier substrate 302 may comprise a glass substrate. In some examples, a main top surface of the carrier may comprise a planarized and polished surface. At fabrication step 2 (FIG. 12B), an intermediate layer 1202 may be coated on the top surface of the carrier substrate 302. In some cases, the intermediate layer 1202 can be a removable temporary intermediate layer that can be removed to detach the carrier substrate 302 from the finished substrate or layer. In some cases, the intermediate layer 1202 may comprise a nitride, or another temporary adhesive layer. At fabrication step 3 (FIG. 12C), a conductive layer 1204 may be laminated or disposed over the intermediate layer 1202. The thickness of the conductive layer 1204 can be from 1 to 20 microns. In some cases, the conductive layer 1204 may be formed or disposed on the intermediate layer 1202 using thermal or e-beam evaporation, sputtering, or other metal deposition methods. In various embodiments, the conductive layer 1204 may comprise copper, aluminum, nickel, silver, tungsten, tin, chromium, gold, or an alloy comprising one these or other elements. At fabrication step 4 (FIG. 12D), the exposed surface of the conductive layer 1204 may be polished (e.g., using chemical mechanical polishing) to provide a planarized and smooth surface for photolithography. In some embodiments, the polishing step may be omitted. Next, the conductive layer is patterned, e.g., using photolithography and dry or wet etching. For example, a layer of photoresist (PR) is coated on the conductive layer 1204, patterned using UV exposure via a mask followed by PR development, and wet etching of the exposed portions of the conductive layer 1204 that are not covered by the patterned PR. In some examples, where the conductive layer comprises copper or copper alloy, a copper solvent (e.g., ferric chloride) may be used for wet etching. After forming the patterned conductive layer 1206, the remaining PR layer may be stripped. In some examples, the regions of the conductive layer 1204 that are not covered by PR may be etched all the way down to the intermediate layer 1202. It should be understood that depending on the thickness of the conductive layer 1204 and parameters of the photolithography and wet etching processes, the side walls of the unetched conductive regions can be sloped to various degrees. At fabrication step 5 (FIG. 12E), a dielectric layer 1208 (serving as a barrier layer) may disposed (e.g., coated) on the patterned conductive layer 1206 and the exposed regions of the intermediate layer 1202. The thickness of the dielectric layer can be from 10 nm to 300 nm. In some examples, the dielectric layer may comprise an inorganic dielectric layer, such as SiN, SiO₂, SiN/SiO₂, or SiC or Al₂O₃. At fabrication step 6 (FIG. 12F), a flexible layer 1210 may be provided over the patterned conductive layer 1206, and on the dielectric layer 1208. The flexible layer 1210 may be formed over the patterned structure 1208 by spin coating or spray coating or vacuum lamination or evaporation or by printing or by other known methods. In some examples, the fabrication step-5 may be skipped and at the fabrication step 6 the flexible layer 1210 can be directly laminated or disposed on the patterned conductive layer and the exposed regions of the intermediate layer 1202. At fabrication step 7 (FIG. 12G), the flexible layer 1210 is polished to remove a portion of the flexible layer 1210 and to reduce the thickness of the flexible layer 1010, e.g., substantially down to a thickness of the patterned conductive layer 1206. In some examples, the polishing process may be stopped after a portion of the dielectric layer 1208 coated on top surface of the patterned conductive layer 1206. The polishing process may comprise mechanical milling, CMP or a combination thereof. At fabrication step 8 (FIG. 12H), the exposed surface of the flexible layer 1210 may be etched to further reduce its thickness and protrude a portion of the patterned conductive layer 1206. In some cases, the flexible layer 101 may be etched using a dry etching process such as plasma etching. At fabrication step 9 (FIG. 12I), a second dielectric layer 1212 is disposed over the etched surface of the flexible layer 1210 and the patterned conductive layer 1206. At the fabrication step 10 (FIG. 12J), the dielectric layer 1212 is polished (e.g., using chemical mechanical polishing) to remove portions of the second dielectric layer 1212 above the conductive regions and planarize the remaining portion of the second dielectric layer 1212 and the protruded portion of the patterned conductive layer 1206 to form a hybrid bonding surface 1214. The patterned conductive layer 1206 may comprise contact pads 1218 that are separated from the flexible layer 1210 by the dielectric 1208. The hybrid bonding surface 1214 comprises the top conductive surfaces of the contact pads 1216 and a dielectric bonding region (field region) comprising the remaining portion of the second dielectric layer 1216. Next, the hybrid bonding surface 1214 is activated (e.g., using a nitrogen plasma treatment). In some cases, the resulting flexible hybrid bonding substrate 1220 is cleaned, rinsed and dried as described earlier. In some embodiments, the rinsed and dried activated bonding surface 1214 may be further dried in a vacuum oven to desorb moisture from the bonding surface prior to directly bonding components on the activated surface 1214.

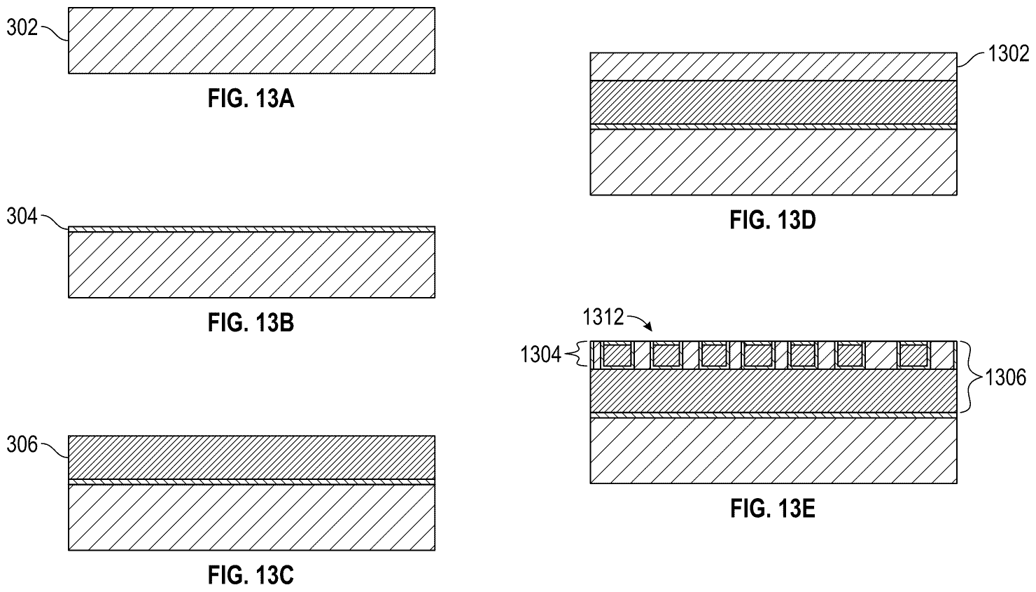

FIGS. 13A to 13E schematically illustrate selected steps of a process for fabricating an example flexible hybrid bonding layer or substrate by wet etching of a conductive layer. At fabrication step 1 (FIG. 13A), a carrier substrate 302 may be provided. At fabrication step 2 (FIG. 13B), an intermediate layer 304 may be coated on the top surface of the carrier substrate 302. In some cases, the intermediate layer 304 can be a removable temporary intermediate layer that can be removed to detach the carrier substrate 302 from the finished substrate or layer. In some cases, the intermediate layer 304 may comprise a nitride. At fabrication step 3 (FIG. 13C), a flexible layer 306 may be coated or laminated the intermediate layer 304. The thickness of the flexible layer 306 can be from 5 to 100 microns. At fabrication step 4 (FIG. 13D), the exposed surface of the flexible layer 306 is polished (e.g., using chemical mechanical polishing) to provide a planarized and smooth surface. Next, a conductive layer 1302 is formed by sputtering, evaporation, electroplating or even laminated on the flexible layer 306. The thickness of the conductive layer 1302 can be from 1 to 25 microns. In various embodiments, the conductive layer 1302 may comprise copper, aluminum, nickel, tin, chromium, gold, or an alloy comprising one of these or other elements.

After fabrication step 4 (FIG. 13D), the process may proceed according to the fabrication steps described above with respect to FIGS. 12D-12J to fabricate a flexible hybrid bonding substrate 1306 having a second flexible layer 1304 comprising contact pads and a hybrid bonding surface 1312. The second flexible layer 1304 can be substantially similar to the flexible hybrid bonding substrate 320 fabricated based on the fabrication process described above with respect to FIGS. 3A to 3H; however instead of patterning the flexible layer (using dry etching) and disposing a conductive material over the patterned flexible layer, in this case a conductive layer is patterned (using wet etching) and a flexible material is laminated over the patterned conductive layer.

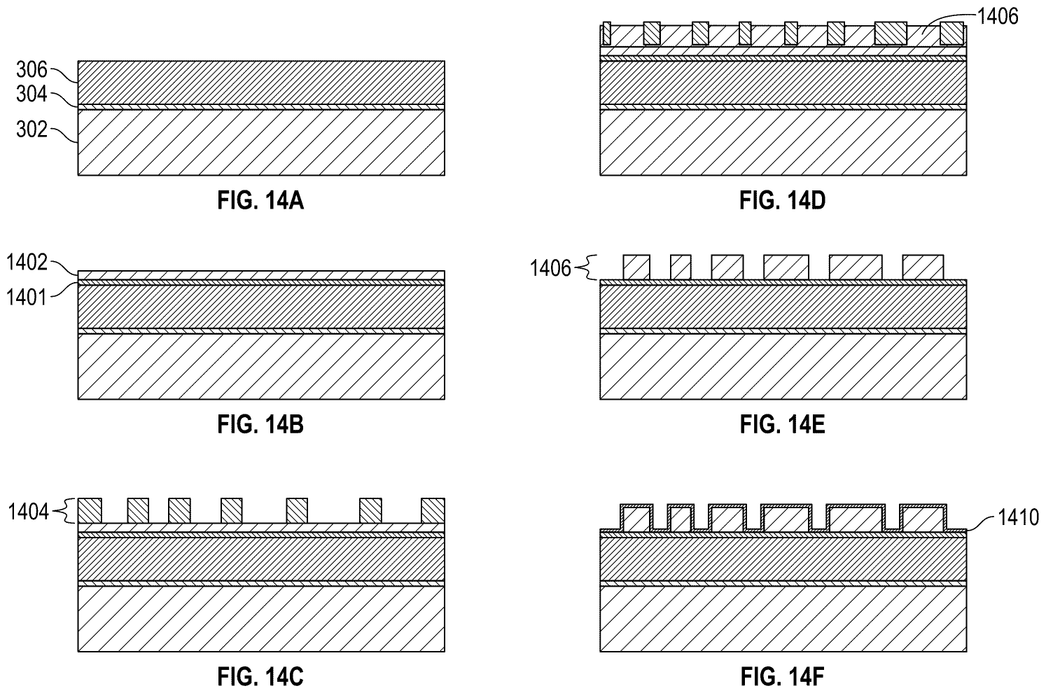

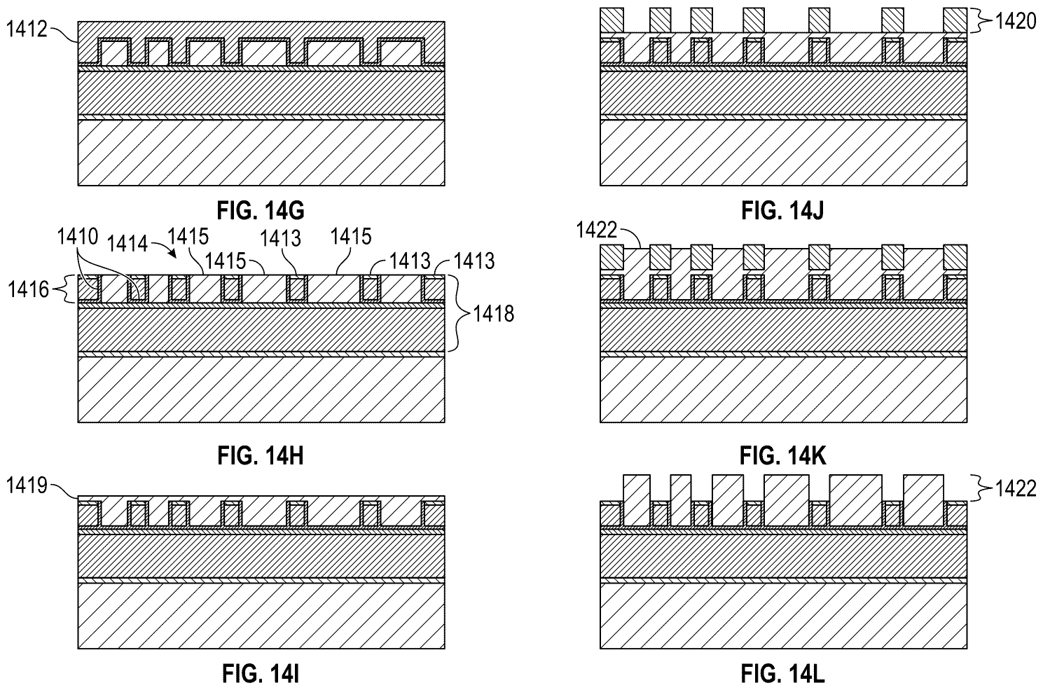

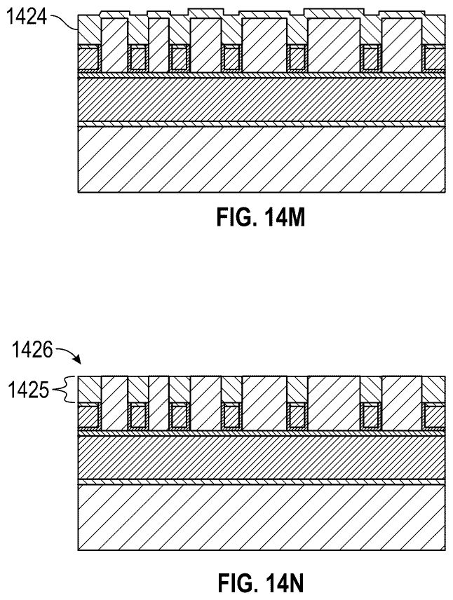

In some embodiments, the patterned conductive layer may be fabricated using thru-mask plating instead of wet etching. FIGS. 14A to 14N schematically illustrate selected steps of a process for fabricating an example flexible hybrid bonding layer or substrate by forming a patterned conductive layer using thru-mask plating of a. At fabrication step 1 (FIG. 14A), an initial substrate having a flexible layer 306 disposed on a carrier substrate 302 and an intermediate layer 304 therebetween, may be provided. In some embodiments, the initial substrate may have been fabricated using the fabrication steps described above with respect to FIGS. 13A-13C. In some cases, the flexible layer 306 can have a thickness from 3 to 100 microns. At fabrication step 2 (FIG. 14B), a second adhesion layer 1401 is coated on the flexible layer 306 and a seed layer 1402 (e.g., conductive seed layer) is coated on the adhesion layer 1401. At fabrication step-3 (FIG. 14C), a PR layer is disposed on the seed layer 1402 and is patterned using photolithography to form a patterned PR layer 1404. In some examples, the PR layer may be spin coated on the seed layer 1402 and patterned using UV exposure via a mask followed by PR development to form a patterned PR layer 1404 also referred to as PR mask 1404. The thickness of the PR layer can be from 3 to 25 microns. In some cases, the thickness of the PR layer may be determined based at least in part on a desired thickness of the conductive pads in the resulting flexible hybrid bonding layer. The PR mask 1404 may comprise one or more openings within which the conductive pads are formed. In some examples, the width of different openings formed in the patterned photoresist layer 1404 can be different. For example, a width of a first opening in the patterned resist layer 1404 can be larger than a width of a second opening in the patterned resist layer 1404 by more than 20%, more than 40%, more than 60%, more than 80%, or more than 100%. At fabrication step 4 (FIG. 14D), a conductive layer 1406 may be disposed over the PR mask 1404 and the exposed regions of the underlying seed layer 1402 to form a patterned conductive layer 1406 comprising one or more conductive pads. In some examples, a conductive pad is formed when an opening within the PR mask 1404 is filled with a conductive material. In some cases, the thickness of the conductive layer 1406 can be from 2 to 20 microns. In some cases, the thickness of the patterned conductive layer 1406 may be determined based at least in part on a desired thickness of the conductive pads in the resulting flexible hybrid bonding layer. In some cases, the patterned conductive layer 1406 may be formed using electrodeposition or electroless methods, by printing, or by physical vapor deposition methods such as e-beam evaporation, sputtering, or other metal deposition methods. In various embodiments, the conductive layer 1406 may comprise copper, aluminum, tin, and nickel, or an alloy comprising one of these or other elements. At fabrication step 5 (FIG. 14E), the PR mask 1404 is stripped and the regions of seed layer 1402 under the PR mask are removed to expose surface regions of the underlying intermediate layer 1401. At fabrication step 6 (FIG. 14F), a barrier layer 1410 is coated on the patterned conductive layer 1406 and the exposed surface regions of the intermediate layer 1401. In some cases, the barrier layer 1410 may comprise a conductive material (e.g., a conductive material selectively coated on the patterned conductive layer 1406 by electroless plating methods. In some cases, the conductive barrier layer 1410 may comprise nickel, cobalt, a nickel-cobalt allow, or other types of metals or metal alloys. In some embodiments, the deposition of the barrier layer may be skipped and the flexible layer 1412 may be directly deposited over patterned conductive layer 1406 (e.g., when the flexible layer 1412 comprises certain organic materials). At fabrication step 7 (FIG. 14G), a flexible layer 1412 may be coated over the patterned conductive layer 1406 and on barrier layer 1410 to fill the volume between the contact pads. In some cases, the thickness of the flexible layer 1412 may exceed the thickness of the patterned conductive layer 1406 and fully cover the underlying structure to generate a flexible top surface. At fabrication step 8 (FIG. 14H), the process may proceed according to the fabrication steps described above with respect to FIGS. 12F-12J to form a flexible hybrid bonding layer 1416 having a hybrid bonding surface 1414. The hybrid bonding surface 1414 may comprise dielectric bonding regions and conductive regions separated from the dielectric bonding regions by the barrier layer 1410.

In some embodiments, an additional hybrid bonding layer may be fabricated over the flexible hybrid bonding layer 1415. In some cases, the additional hybrid bonding layer may comprise an extended dielectric layer through which the contact pads of the flexible hybrid bonding substrate 1415 are electrically connected to a hybrid bonding surface over the additional hybrid bonding layer. FIGS. 14I to 14N schematically illustrate the fabrication steps for fabricating the additional hybrid bonding layer over the flexible hybrid bonding layer 1416. At fabrication step 9 (FIG. 14I), a second seed layer 1419 (e.g., conductive seed layer) is coated on the hybrid bonding surface 1414 of the flexible hybrid bonding layer 1416. At fabrication step 10 (FIG. 14J), a second PR layer is disposed on the seed layer 1419 and is patterned using photolithography to form a second patterned PR layer 1420 (also referred to as second PR mask). In some examples, the second PR mask 1420 may be formed using similar method described above with respect to formation of the PR mask 1404. A thickness of the second PR mask 1420 can be from 1 to 10 microns. In some cases, the thickness of the second PR mask 1420 may be determined based at least in part on a desired thickness of the additional dielectric layer. The second PR mask 1420 may comprise one or more openings within which the conductive pads are formed. At fabrication step 11 (FIG. 14K), a conductive layer 1422 may be disposed over the second PR mask 14202 and the exposed regions of the underlying second seed layer 1419 to form a second patterned conductive layer 1422 comprising one or more conductive pads. In some examples, a conductive pad is formed when an opening within the second PR mask 1420 is filled with a conductive material. In some cases, the openings of the within the second PR mask 1420 are aligned with the contact pads of the hybrid bonding surface 1414. As such at least, some of the constant pads of the second pattered conductive layer 1422 may be electrically connected to the contact pads of the flexible hybrid bonding layer 1416. In some embodiments, a contact pad of the second patterned conductive layer 1422 may be fabricated above a contact pad of the flexible hybrid bonding layer 1416 to form a conductive via.

In some cases, the thickness of the second patterned conductive layer 1422 can be from 2 to 20 microns. In some cases, the thickness of the second patterned conductive layer 1433 may be determined based at least in part on a desired thickness of the conductive pads in the resulting flexible hybrid bonding layer. In some cases, the second patterned conductive layer 1422 may be formed or disposed using thermal or e-beam evaporation, sputtering, electroplating, electroless, printing or other metal deposition methods. In various embodiments, the second pattered conductive layer 1422 may comprise copper, aluminum, nickel, tin, chromium, gold, or an alloy comprising one of these or other elements.

At fabrication step 12 (FIG. 14L), the second PR mask 1420 is stripped and the regions of seed layer 1419 under the second PR mask are removed to expose dielectric regions of the hybrid bonding surface 1414. At fabrication step 13 (FIG. 14M), a dielectric layer 1424 is disposed over the patterned conductive layer 1422 and the exposed dielectric regions of the hybrid bonding surface 1414. At fabrication step 14 (FIG. 14N), the dielectric layer 1424 is planarized and activated to form a hybrid bonding surface 1426 over the dielectric layer 1424. In some cases, the thickness of the resulting dielectric layer 1425 can be equal or smaller than the thickness of the second patterned conductive layer 1422. In some embodiments, the thickness of the dielectric layer 1425, after planarization, can be larger than 50 nm and even more than 3 microns. In some embodiments, the thickness of the dielectric layer 1425, after planarization, can be larger than 2%, 10%, 20%, or 35% of the combined thicknesses of the flexible layer 306 and flexible layer 1412.

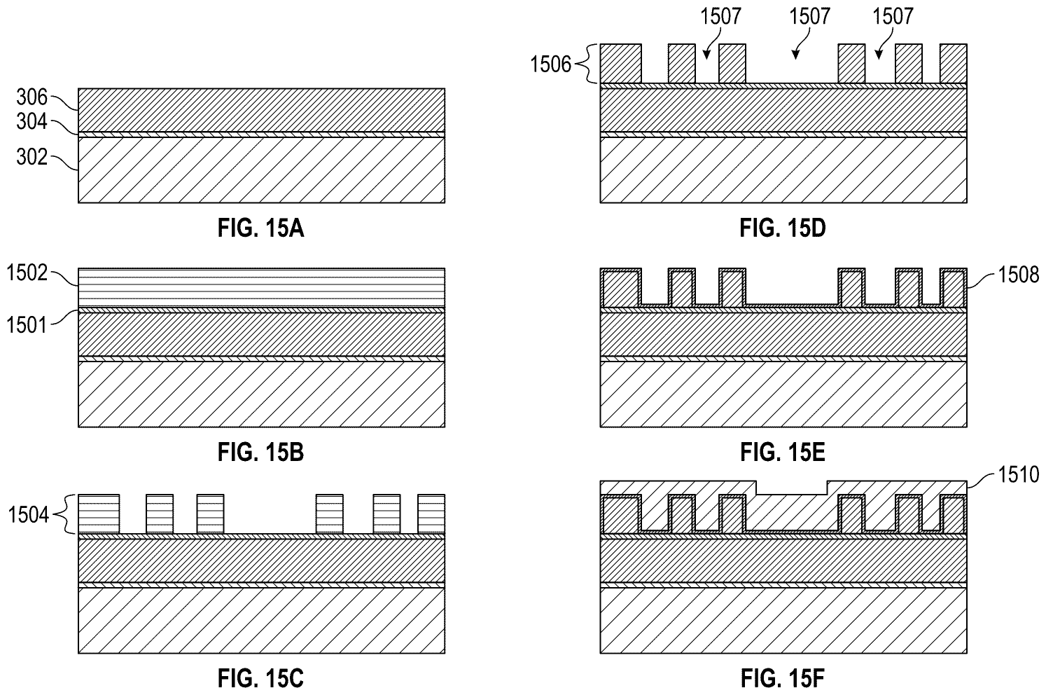

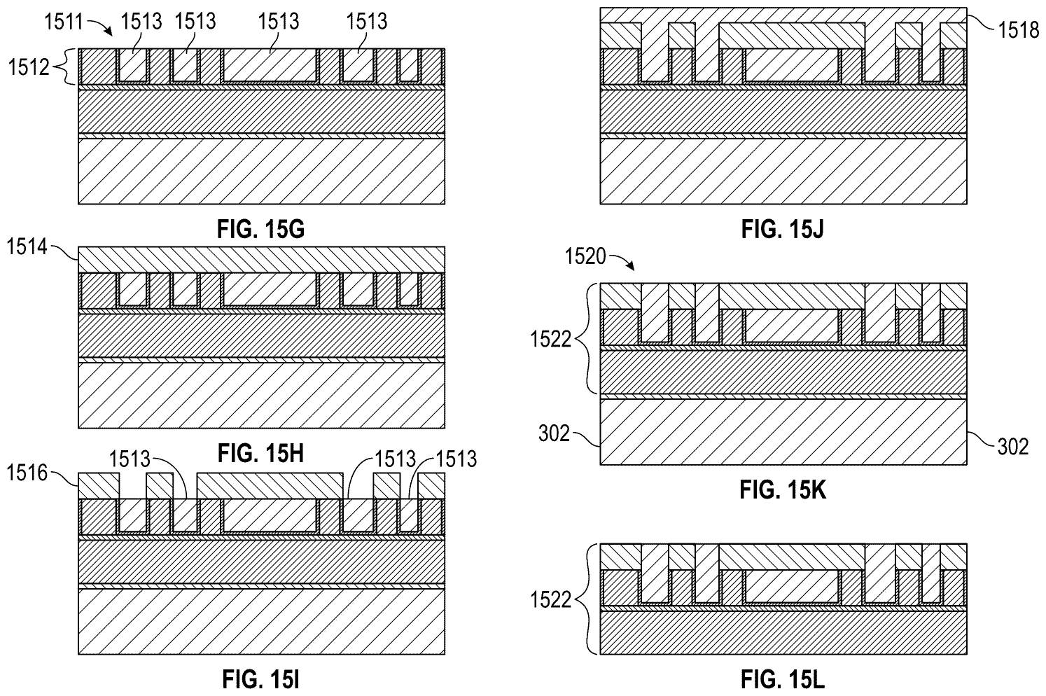

In some examples, a flexible hybrid bonding layer may be formed by patterning a flexible layer and filling the resulting opening with a conductive material to form contact pads therein and forming a hybrid bonding layer comprising an extended dielectric layer over the flexible layer. FIGS. 15A to 15L schematically illustrate selected steps of a process for fabricating an example flexible hybrid bonding layer or substrate comprising patterning a flexible layer. At fabrication step 1 (FIG. 15A), an initial substrate having a first flexible layer 306 disposed on a carrier substrate 302 and an intermediate layer 304 therebetween, may be provided. In some embodiments, the initial substrate may have been fabricated using the fabrication steps described above with respect to FIGS. 13A-13C. In some cases, the first flexible layer 306 can have a thickness from 5 to 100 microns. At fabrication step 2 (FIG. 15B), a second adhesion layer 1501 may be coated on the first flexible layer 306. Next, a precursor layer 1502 is coated (or disposed) on the second intermediate layer 1501. In some cases, the precursor layer 1502 may comprise a material that can be transformed to a flexible (deformable) material upon further treatment. In some examples, the precursor layer 1502 may comprise a polymer resin that when baked at high temperature transforms to a polymer. In some cases, the precursor layer 1502 can have a thickness from 5 to 100 microns. At fabrication step 3 (FIG. 15C), the precursor layer 1502 is patterned to form a patterned flexible layer 1504. In some examples, the precursor layer 1502 may be spin coated on the second intermediate layer 1501 and patterned using UV exposure via a mask followed by dissolving (or etching) the regions of the precursor layer 1502 exposed to UV radiation. For example, the precursor layer may comprise a photoimagable organic material, for example, a photosensitive polyimide layer. In some other examples, the precursor layer 1502 may be patterned using direct laser writing. At fabrication step 4 (FIG. 15D), the patterned precursor layer 1504 may be treated (or cured) to form a patterned flexible layer 1506. In some examples, the patterned precursor layer 1504 may comprise a polymer resin, the treatment at step 5 may comprise high temperature baking, and the patterned flexible layer 1506 may comprise a patterned polymer layer. The patterned flexible layer 1506 may comprise one or more openings 1507 for forming contact pads. In some cases, an opening in the pattered flexible layer 1506 may be extended down to the second intermediate layer 1501. In some cases, the second intermediate layer 1501 may serve as a etch stop layer to protect the underlying first flexible later 306. At fabrication step 5 (FIG. 15E), a barrier layer (or adhesion layer) 1508 (e.g., a conductive barrier layer) may be disposed (e.g., coated) on the patterned flexible layer 1506 and, in some cases, on the exposed regions of the second intermediate layer 1501. In embodiments, a seed layer (not shown), may be coated on the barrier layer 1508. At fabrication step 6 (FIG. 15F), a conductive layer 1510 is disposed (e.g., coated) over the patterned flexible layer 1506 and on the seed layer (or the barrier layer 1508) to form contact pads in the openings of the patterned flexible layer 1506. In some cases, the opening may be overfilled and the conductive layer 1510 may cover the regions of the pattern flexible layer 1506 in between openings. At fabrication step 7 (FIG. 15G), the conductive layer 1510 may be planarized to form a hybrid surface comprising the top surface regions of the contact pads 1513 and the pattered flexible layer 1506 therebetween. At fabrication step 8 (FIG. 15H), a dielectric layer 1514 is disposed on hybrid surface 1511. The thickness of the dielectric layer 1514 can be from 0.2 to 5 microns. In some embodiments, thickness of the dielectric layer 1514 can be greater than or equal to, 2%, 3%, 4%, 5%, 6%, 7%, 10%, of a thickness of the flexible layer 306 (or the core insulating layer).

In some embodiments, the dielectric layer 1514 may comprise more than one dielectric layer, at least two dielectric layers having different material compositions and thereby different physical characteristics (e.g., different CTE). At fabrication step 9 (FIG. 15I), the dielectric layer 1514 may be patterned to form a patterned dielectric layer 1516 comprising one or more openings 1513 over one or more contact pads 1513 of the hybrid bonding layer 1512. In some examples, the dielectric layer 1514 may be patterned using photolithography and etching. At fabrication step 10 (FIG. 15J), a conductive layer 1518 is disposed on the patterned dielectric layer 1516 and exposed regions of the hybrid surface 1511 to form contact pads over the contact pads 1513 of the flexible hybrid bonding layer 1512 by filling the openings 1513 of the patterned dielectric layer 1516 with a conductive material (e.g., a metal). In some examples, the openings of the patterned dielectric layer 1516 may be coated by a barrier layer (e.g., a conductive barrier layer) before deposition of the conductive layer 1518. In some cases, the openings 1513 may be overfilled and the conductive layer 1518 may extend over surface regions of the patterned dielectric layer 1516 between the openings 1513. At fabrication step 11 (FIG. 15K), conductive layer 1518 may be polished to remove the portion of the conductive layer extended over the patterned dielectric layer 1516, and in some cases, a portion of the contact pads formed in the openings 1513 to form a hybrid bonding surface 1520. At fabrication step 12 (FIG. 15L), the flexible hybrid bonding substrate 1522 may be detached from the carrier substrate 302. The hybrid bonding surface 1520 of the flexible hybrid bonding substrate 1522 can be activated for direct bonding before or after removing the carrier substrate 302.

In some embodiments, non-conductive regions (e.g., organic regions) of the top major surface of the intermediate structure shown in FIG. 15G may be activated (e.g., (e.g., using a nitrogen plasma treatment) and prepared for bonding to a die. As such the fabrication steps described above with respect to FIGS. 15A to 15G may be used to fabricate a flexible substrate having an organic bonding region.

In some embodiments, any one of the conductive layers 604, 1204, 1302, 1406, 1422, 1510, 1518 may comprise two or more metal sub-layers comprising different compositions (e.g., metal types). In some examples, at least one physical property of a metal sub-layer can be different from that of another meat-sublayer in the same conductive layer. For example, two metal sub-layers of a conductive layer may have different coefficients of thermal expansion.

In some examples, any one of the conductive layers the conductive layers 604, 1204, 1302, 1406, 1422, 1510, 1518 may comprise a bilayer metal stack comprising nickel (Ni) and Cu (e.g., a first sub-layer comprising Ni and a second sub-layer comprising Cu disposed on the first sub-layer). In some embodiments, any one of the conductive layers 604, 1204, 1302, 1406, 1422, 1510, 1518 may comprise a metal stack having three sub-layers. three layers. For example, a conductive layer may comprise a first metal-sublayer comprising copper, a second metal sub-layer comprising Ni or Sn, and a third metal sub-layer comprising copper, where the second metal sublayer is disposed over the first metal sub-layer, and the third metal sub-layer is disposed over the second metal sub-layer.

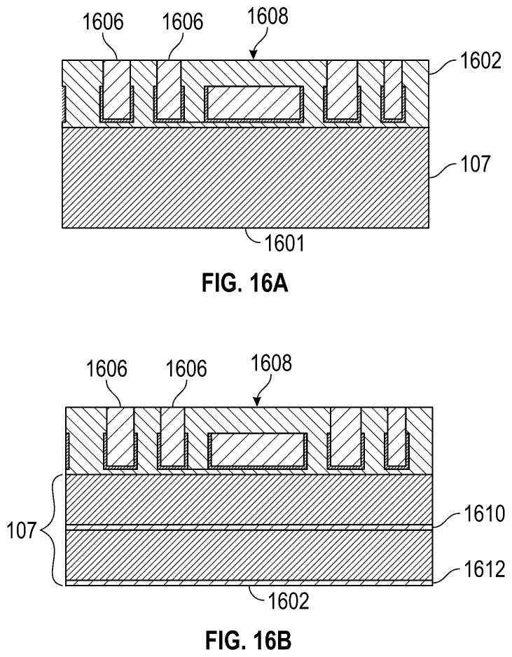

In some embodiments, the contact pads, conductive vias, and/or conductive lines of a flexible hybrid bonding substrate (or layer) may be fully embedded in a dielectric layer (e.g., an inorganic dielectric layer) disposed on a flexible layer. FIG. 16A schematically illustrates an example of such flexible hybrid bonding substrate 1601. The flexible hybrid bonding substrate 1601 comprises a flexible layer 107 and a thick dielectric layer 1602 attached to a main surface of the flexible layer 107. In some examples, the thick dielectric layer 1602 can be deposited or coated on the flexible layer 107. In some examples, the flexible layer 107 can be laminated to the thick dielectric layer 1602. The thick dielectric layer 1602 may comprise conductive lines and vias embedded therein and contact pads 1606 that electrically connect the conductive lines and conductive vias to a hybrid bonding surface 1608 formed on a surface of the thick dielectric layer 1602 (e.g., a main surface opposite to the main surface of the flexible layer 107. In some embodiments, the dielectric bonding region and conductive region of the hybrid bonding surface 1608 may comprise the surface regions (e.g., top surface regions) of the contact pads 1606 and the thick dielectric layer 1602, respectively. The thickness of the flexible layer 107 can be from 5 to 90 microns. The thickness of the thick dielectric layer 1602 can be from 0.3 to 5 microns. In some embodiments, thickness of the thick dielectric layer 1602 can be greater than or equal to, 2%, 3%, 4%, 5%, 6%, 7%, 10%, of a thickness of the flexible layer 107 (or a core insulating layer on which the thick dielectric layer 1602 is formed). In some embodiments, the conductive features 1606 and dielectric layer 1608 may comprise a dual damascene layer.

In some embodiments, a flexible layer of a flexible hybrid bonding layer (or substrate) may comprise a reinforcement layer configured to improve mechanical stability of the flexible layer (e.g., the reinforcement layer may control or reduce warpage of the flexible layer). In some cases, the reinforcement layer may comprise a conductive material (e.g., copper, or a copper alloy, or other metals). Advantageously, a conductive reinforcement layer not only improves the mechanical stability of the flexible layer but can also serve as an electromagnetic shielding layer that protects the conductive lines embedded in the corresponding flexible hybrid bonding layer, and/or a circuitry connected to the flexible hybrid bonding layer (e.g., a component directly bonded to the flexible hybrid bonding layer), from parasitic effects of external electromagnetic radiation.

In some embodiments, the reinforcement layer may be positioned below the transmission lines, vias, and contact pads of the corresponding flexible hybrid bonding layer opposite to the hybrid bonding surface of flexible hybrid bonding layer. In such embodiments, the reinforcement layer may be embedded in the flexible layer or disposed on a main surface of the flexible layer opposite to the hybrid bonding surface. In some examples, the thickness of a bottom reinforcement layer can be from 10 to 500 microns.

In some embodiments, the flexible layer 107 of the flexible hybrid bonding layers 202-210 and 1601 may comprise a least one reinforcement layer. FIG. 16B illustrates, a flexible hybrid bonding layer 1602 having a flexible layer 107 with a first reinforcement layer 1610 disposed within the flexile layer 107, and a second reinforcement layer 1612 disposed on the bottom surface of the flexible layer 107. In various embodiments, the first and second reinforcement layers 1610, 1612 may have the same or different thicknesses. In various embodiments, the first and second reinforcement layers 1610, 1612 may have the same or different material compositions.

In various embodiments, a dielectric bonding layer may comprise silicon oxide, silicon nitride, silicon oxynitride, silicon oxynitrocarbide, SiOxNy, SiOx, SiC or any other suitable nonconductive layer and may disposed using sputtering or a vapor deposition process (e.g., PVD, PECVD, MOCVD, and the like).

In some embodiments, a dielectric bonding layer 106 may comprise two or dielectric sub-layers. For example, the dielectric bonding layer may comprise a first dielectric sub-layer (e.g., an intermediate or coupling sub-layer) disposed directly on a substrate or core insulating layer (e.g., a flexible layer) and a second dielectric sub-layer (e.g., a bonding sub-layer) may be disposed over the coupling dielectric.

In some cases, a sidewall of an opening in which contact pad is formed can make a slope larger than 90 degrees with respect to a major surface of an underlying surface (e.g., surface of a flexible dielectric layer or a dielectric bonding layer). In some examples, the slope of the sidewall of the opening can be from 95 to 110, from 110 to 120 degrees, from 120 to 130 degrees, from the 130 to 150 degrees, or any ranges formed by these values, or larger or smaller values. Similarly, a sidewall of a patterned PR layer (e.g., patterned PR layer 1420) used to fabricate contact pads can make a slope larger than 90 degrees with respect to a major surface of an underlying surface flexible dielectric layer or a dielectric bonding layer). In some examples, the slope of the sidewall of the opening can be from 95 to 110, from 110 to 120 degrees, from 120 to 130 degrees, from the 130 to 150 degrees, or any ranges formed by these values, or larger or smaller values.

In various embodiments, before a conductive layer is disposed on a surface or layer using electroplating, a seed layer may be disposed on the surface or layer (e.g., using sputtering, PECVD, PVD and other physical or chemical deposition methods), before the deposition of a conductive layer.

In some embodiments, a barrier layer may have a thickness less than 400 nanometers (nm), less than 100 nm, less than 10 nm, or less than 2 nm, but more than 0.001 nm. In some examples, a barrier layer may have a thickness larger than or equal to 5 nm and smaller than or equal to 100 nm. The barrier layer may be disposed using deposition processes including but not limited to, sputtering, PECVD, sputtering, PVD, atomic layer deposition (ALD) and the like.

In some cases, the conductive barrier may comprise titanium (Ti), titanium nitride (TiN), tantalum (Ta), tantalum nitride (TaN), tantalum oxide (tantalum with a small amount of oxygen content, tungsten (W), tungsten nitride (WN), cobalt-phosphorus alloy (CoP), cobalt-tungsten alloy CoW, cobalt silicid (CoSi,) nickel-vanadium (NiV), nickel-phosphorus (NiP), nickel-tungsten (NiW) and combinations thereof.

In various embodiments, a polished surface of a dielectric or conductive region of a hybrid bonding surface may have a roughness of less than 10 Å rms, 5 Å rms, 3 Å rms, or 2 Å rms.

In some cases, a CMP process used to polish or etch a layer may be a selective CMP process for stopping on a layer below the etched or polished layer. For example, the conductive material overburden disposed over a dielectric layer (e.g., a flexible layer, a dielectric bonding layer, or an intermediate layer) may be removed by a selective CMP process for stopping on dielectric layer.

In some cases, after polishing a hybrid bonding surface a polished conductive surface of a contact pad can be recessed with respect to the hybrid bonding surface. In some examples, a vertical distance between the polished conductive surface and a polished dielectric surface of the hybrid bonding surface can be from 1 nm to 50 nm. In some such cases, a vertical distance (along z-axis) between the surface of the contact pad and the corresponding hybrid bonding surface may be selected to allow formation of a conductive bond between the contact pad and another contact pad.

In some embodiments, a conductive layer (also referred to as conductive filler) may comprise a conductive material such as copper, nickel, or a conductive alloy.

In some embodiments, a seed layer may be disposed between a barrier layer and a contact pad.

In some embodiments, a barrier layers may comprise a conductive layer that prevents migration of the conductive material (e.g., copper) from a contact pad to a dielectric bonding layer and/or a flexible layer within which the contact pad is formed.

In some cases, a depth of an opening within which a contact pad is formed, measured from a corresponding hybrid bonding surface, can from 1 to 2 microns, from 2 to 5 microns, from 5 to 10 microns, or larger values.

Each contact pad may have a width W along a direction parallel to the corresponding bonding surface. In some cases, a width of the first contact pad 102 and a width of the second contact pad 112 may be substantially equal or may differ. Once the polished bonding surfaces have been generated on both elements 100/110, they may be aligned such that the bonding surfaces 204 of the first element 100 are substantially parallel with the bonding surfaces 214 of the second element 110, and at least a region of the conductive surface 244 of the contact pad 102 is aligned with a region of the conductive surface 245 of the contact pad 112 in a plane parallel to the bonding surfaces.

In some embodiments an element may be directly bonded to a flexible hybrid bonding layer or substrate by: aligning contact pads of the element and the flexible hybrid bonding layer, bringing the hybrid bonding surfaces the element and the flexible hybrid bonding layer (e.g., the inorganic dielectric layer) into contact, and elevating the temperature of the resulting interface (e.g., to a temperature less than 400 degrees) to cause the expansion of the contact pads and formation of a direct metal-to-metal (e.g., copper-to-copper) bonds. The metal-to-metal bond can be an electrically conductive junction.

In various embodiments described above a flexible layer or sublayer is an insulation layer that isolates the contact pads and conductive lines fully or partially embedded in the flexible layer or sub layer.

In various embodiments described above, thickness of a layer or sublayer may be defined with respect to a direction normal to an underlying surface on which the layer is formed.

### Example Embodiments

Various additional example embodiments of the disclosure can be described by the following examples:

### Example Embodiment I

Example 1. A substrate for hybrid bonding to at least one component, the substrate comprising:
a core insulating layer comprising a deformable region;
an inorganic dielectric bonding layer over the core insulating layer;
an opening through the inorganic dielectric bonding layer extending below the inorganic dielectric bonding layer into the core insulating layer;
a barrier layer coated on sidewalls and a bottom surface of the opening; and
a first conductive contact pad formed within the opening, the first conductive contact pad separated from the core insulating layer and the inorganic dielectric bonding layer by the barrier layer;
wherein a surface of the inorganic dielectric bonding layer is prepared for direct hybrid bonding.

Example 2. The substrate of Example 1, wherein the deformable region comprises an insulating organic material.

Example 3. The substrate of Example 2, wherein the insulating organic material comprises a polymer.

Example 4. The substrate of Example 1, wherein the deformable region comprises a flexible material.

Example 5. The substrate of Example 1, wherein a thickness of the deformable region, along a direction normal to a main surface of the substrate, is larger than 5 microns.

Example 6. The substrate of Example 5, wherein a Young's modulus of the deformable region is less than 40 GPa.

Example 7. The substrate of Example 1, wherein a coefficient of thermal expansion (CTE) of the deformable region is larger than 2 ppm/° C.

Example 8. The substrate of Example 7, wherein a coefficient of thermal expansion (CTE) of the deformable region is larger than 4 ppm/° C.

Example 9. The substrate of Example 1, wherein the opening has a depth less than a thickness of the core insulating layer.

Example 10. The substrate of Example 1, further comprising a second conductive contact pad spaced apart from the first conductive contact pad by a gap, wherein the deformable region at least partially bridges the gap.

Example 11. The substrate of Example 10, wherein the first and second conductive contact pads are electrically connected by a conductive line at least partially embedded in the deformable region.

Example 12. The substrate of Example 11, wherein the deformable region is bent without disrupting electrical connection via the conductive line and the radius of curvature of a bent flexible substrate is less than 100 times the thickness of the substrate along a direction normal to a main surface of the substrate.

Example 13. The substrate of Example 1, wherein the surface of the inorganic dielectric bonding layer is activated and terminated with a species.

Example 14. The substrate of Example 13, wherein the species comprises nitrogen.

Example 15. The substrate of Example 1, wherein the first conductive contact pad comprises a conductive material disposed within the opening over the barrier layer.

Example 16. The substrate of Example 15, wherein the conductive material comprises a metal.

Example 17. The substrate of Example 1, wherein the barrier layer comprises a dielectric material.

Example 18. The substrate of Example 17, wherein the barrier layer comprises silicon nitride, a combination of silicon nitride and silicon oxide, or silicon carbide.

Example 19. The substrate of Example 18, wherein a composition of the barrier layer is identical to that of the inorganic dielectric bonding layer.

Example 20. The substrate of Example 1, wherein the barrier layer comprises a conductive material.

Example 21. The substrate of Example 20, wherein the conductive material comprises TaN or TiN.

Example 22. The substrate of Example 1, wherein the inorganic dielectric bonding layer comprises SiOxNy, SiOx, or SiC.

Example 23. The substrate of Example 1, wherein the deformable region is transparent in a visible wavelength range.

Example 24. The substrate of Example 1, wherein a thickness of the barrier layer is from 5 to 100 nanometers.

### Example Embodiment II

Example 1. A bonded structure comprising:
a first die;
a second die spaced apart from the first die by a gap; and
an interconnect assembly comprising a hybrid bonding layer, the hybrid bonding layer comprising a core insulating layer having a conductive line therein and a hybrid bonding surface formed over the core insulating layer, the first die directly bonded to a first conductive contact pad, the second die directly bonded to a second conductive contact pad;
wherein:
   the first and second conductive contact pads are at least partially formed within the core insulating layer and are separated from the core insulating layer by barrier layers; and
   the core insulating layer comprises a deformable region at least partially extending between the first and second conductive contact pads.

Example 2. The bonded structure of Example 1, wherein the deformable region comprises an insulating organic material.

Example 3. The bonded structure of Example 2, wherein the insulating organic material comprises a polymer.

Example 4. The bonded structure of Example 1, wherein a thickness of the deformable region, along a direction normal to a main surface of the substrate, is larger than 5 microns.

Example 5. The bonded structure of Example 4, wherein Young's modulus of the deformable region is less than 40 GPa.

Example 6. The bonded structure of Example 1, wherein a coefficient of thermal expansion (CTE) of the deformable region is larger than 2 ppm/° C.

Example 7. The bonded structure of Example 6, wherein a coefficient of thermal expansion (CTE) of the deformable region is larger than 4 ppm/° C.

Example 8. The bonded structure of Example 1, wherein the conductive line is at least partially embedded in the deformable region and electrically connects the first and second conductive contact pads.

Example 9. The bonded structure of Example 6, wherein the deformable region is bent without disrupting electrical connection via the conductive line and the radius of curvature of a bent flexible substrate is less than 100 times the thickness of the substrate along a direction normal to a main surface of the substrate.

Example 10. The bonded structure of Example 1, wherein the barrier layers comprise a dielectric material.

Example 11. The bonded structure of Example 10, wherein the barrier layers comprise silicon nitride, a combination of silicon nitride and silica, or silicon carbide.

Example 12. The bonded structure of Example 1, wherein the barrier layers comprise a conductive material.

### Example Embodiment III

Example 1. A method of fabricating a substrate for bonding to at least one component, the method comprising:
providing a core insulating layer having a deformable region;
forming a dielectric layer over the core insulating layer;
forming an opening in the core insulating layer through the dielectric layer, the opening having a depth less than a thickness of the dielectric layer;
coating a barrier layer over the dielectric layer, the barrier layer lining sidewalls and a bottom surface of the opening;
filling the opening with a conductive material after coating the barrier layer; and
preparing a surface of the substrate for direct hybrid bonding.

Example 2. The method of Example 1, wherein providing the core insulating layer comprises:
providing a carrier substrate;
coating an intermediate layer on a main surface of the carrier substrate; and
disposing the core insulating layer over the intermediate layer.

Example 3. The method of Example 2, wherein disposing the core insulating layer comprises laminating the core insulating layer.

Example 4. The method of Example 1, wherein the deformable region comprises an insulating organic material.

Example 5. The method of Example 4, wherein the insulating organic material comprises a polymer.

Example 6. The method of Example 1, wherein the dielectric layer comprises an inorganic dielectric material.

Example 7. The method of Example 1, wherein the conductive material comprises a metal.

Example 8. The method of Example 1, wherein the barrier layer comprises a dielectric material.

Example 9. The method of Example 8, wherein the barrier layer comprises silicon nitride, a combination of silicon nitride and silica, or silicon carbide.

Example 10. The method of Example 1, wherein the barrier layer comprises a conductive material.

Example 11. The method of Example 1, wherein a thickness of the deformable region, along a direction normal to a main surface of the substrate, is larger than 5 microns.

Example 12. The method of Example 11, wherein a Young's modulus of the deformable region is less than 40 GPa.

Example 13. The method of Example 1, wherein a coefficient of thermal expansion (CTE) of the deformable region is larger than 2 ppm/° C.

Example 14. The method of Example 13, wherein a coefficient of thermal expansion (CTE) of the deformable region is larger than 4 ppm/° C.

### Example Embodiment IV

Example 1. A method of fabricating a substrate for bonding to at least one component, the method comprising:
providing a core insulating layer having a conductive contact pad therein, the core insulating layer comprising a deformable region;
etching a portion of a top surface of the core insulating layer to cause at least a portion of the conductive contact pad to protrude;
providing a dielectric layer over the etched portion of the top surface of the core insulating layer and the protruded conductive contact pad;
preparing a surface of the dielectric layer to form a hybrid bonding surface.

Example 2. The method of Example 1, further comprising polishing the top surface of the core insulating layer before etching.

Example 3. The method of Example 1, wherein the deformable region comprises an organic material.

Example 4. The method of Example 2, wherein the organic material comprises a polymer.

Example 5. The method of Example 1, wherein a thickness of the deformable region, along a direction normal to a main surface of the substrate, is larger than 5 microns.

Example 6. The method of Example 5, wherein a Young's modulus of the deformable region is less than 40 GPa.

Example 7. The method of Example 1, wherein a coefficient of thermal expansion (CTE) of the deformable region is larger than 2 ppm/° C.

Example 8. The method of Example 7, wherein a coefficient of thermal expansion (CTE) of the deformable region is larger than 4 ppm/° C.

### Example Embodiment V

Example 1. A multilayer substrate to be directly bonded to at least one element, the multilayer substrate comprising:
a first hybrid bonding surface;
a first core insulating layer comprising a first conductive contact pad and the first hybrid bonding surface;
a second core insulating layer below the first core insulating layer, the second core insulating layer comprising a second conductive contact pad; and
a first bonded dielectric layer between the first and second core insulating layers, the first bonded dielectric layer comprising a first pair of directly bonded dielectric layers at a first direct bonding interface;
wherein the first direct bonding interface comprises a first conductive via electrically connected to the first and second conductive contact pads.

Example 2. The multilayer substrate of Example 1, further comprising a first dielectric layer over the first core insulating layer, the first dielectric layer comprising the first hybrid bonding surface.

Example 3. The multilayer substrate of Example 1, wherein the first core insulating layer comprises a first conductive line at least partially embedded in the first core insulating layer.

Example 4. The multilayer substrate of Example 1, wherein the first conductive contact pad is separated from the first core insulating layer by a barrier layer.

Example 5. The multilayer substrate of Example 4, wherein the barrier layer comprises a dielectric material.

Example 6. The multilayer substrate of Example 4, wherein the barrier layer comprises a conductive material.

Example 7. The multilayer substrate of Example 1, wherein one or both of the first and second core insulating layers comprise a deformable region.

Example 8. The multilayer substrate of Example 7, wherein a thickness of the deformable region, along a direction normal to a main surface of the multilayer substrate, is larger than 5 microns.

Example 9. The multilayer substrate of Example 8, wherein a Young's modulus of the deformable region is less than 40 GPa.

Example 10. The multilayer substrate of Example 7, wherein a coefficient of thermal expansion (CTE) of the deformable region is larger than 2 ppm/° C.

Example 11. The multilayer substrate of Example 10, wherein a coefficient of thermal expansion (CTE) of the deformable region is larger than 4 ppm/° C.

Example 12. The multilayer substrate of Example 7, wherein the deformable region is bent without disrupting electrical connection via a conductive line embedded in the first or second core insulating layer and the radius of curvature of a bent flexible substrate is less than 100 times the thickness of the multilayer substrate along a direction normal to a main surface of the multilayer substrate.

Example 13. The multilayer substrate of Example 1, further comprising a second hybrid bonding surface opposite to the first hybrid bonding surface.

Example 14. The multilayer substrate of Example 13, further comprising a second dielectric layer over the second core insulating layer, the second dielectric layer comprising the second hybrid bonding surface.

Example 15. The multilayer substrate of Example 14, wherein a conductive region of the first hybrid bonding surface is electrically connected to a conductive region of the second hybrid bonding surface via the first and second conductive contact pads.

Example 16. The multilayer substrate of Example 1, wherein:
the first core insulating layer comprises a first sublayer and a second sublayer separated from the first sublayer via a second bonded dielectric layer, the second bonded dielectric layer comprising a second pair of directly bonded dielectric layers at a second direct bonding interface; and
the second core insulating layer comprises a third sublayer and a fourth sublayer separated from the third sublayer via a third bonded dielectric layer, the third bonded dielectric layer comprising a third pair of directly bonded dielectric layers at a third direct bonding interface.

Example 17. The multilayer substrate of Example 16, wherein the second bonded dielectric layer comprises a second conductive via through the second direct bonding interface and the third bonded dielectric layer comprises a third conductive via through the third direct bonding interface, wherein the first, second, and third conductive vias are electrically connected.

Example 18. The multilayer substrate of Example 16, further comprising a first dielectric layer over the first sublayer, the first dielectric layer comprising the first hybrid bonding surface.

Example 19. The multilayer substrate of Example 16, further comprising a second hybrid bonding surface opposite to the first hybrid bonding surface.

Example 20. The multilayer substrate of Example 19 further comprising a second dielectric layer over the fourth sublayer, the second dielectric layer comprising the second hybrid bonding surface.

Example 21. The multilayer substrate of Example 18, wherein one or both of the first and second core insulating layers comprise a deformable region.

Example 22. The multilayer substrate of Example 13, wherein at least one of the first, second, third, and fourth sublayers comprise a deformable region.

Example 23. The multilayer substrate of any of Examples 21 or 22, wherein a thickness of the deformable region, along a direction normal to a main surface of multilayer substrate, is larger than 5 microns.

Example 24. The substrate of Example 23, wherein a Young's modulus of the deformable region is less than 40 GPa.

Example 25. The multilayer substrate of any of Examples 21 or 22, wherein a coefficient of thermal expansion (CTE) of the deformable region is larger than 2 ppm/° C.

Example 26. The substrate of Example 26, wherein a coefficient of thermal expansion (CTE) of the deformable region is larger than 4 ppm/° C.

Example 27. The multilayer substrate of any of Examples 21 or 22, wherein the deformable region is bent without disrupting electrical connection via a conductive line embedded in the first or second core insulating layer and radius of curvature of a bent flexible substrate is less than 100 times the thickness of the multilayer substrate along a direction normal to a main surface of the multilayer substrate.

Example 28. The multilayer substrate of any of Examples 21 or 22, wherein the deformable region comprises an insulating organic material.

### Example Embodiment VI

Example 1. A method of fabricating a multilayer substrate having at least a top hybrid bonding surface, the method comprising:
providing a first flexible hybrid bonding layer having a first core insulating layer, a first conductive contact pad and a first hybrid bonding surface;
providing a second flexible hybrid bonding layer having a second core insulating layer, a second conductive contact pad and a second hybrid bonding surface;
directly bonding the first and second hybrid bonding surfaces to electrically connect the first and second conductive contact pads and form a first intermediate dielectric layer between the first and second core insulating layers;
etching a top portion of the first core insulating layer opposite the first intermediate dielectric layer to protrude a portion of the first conductive contact pad opposite the first intermediate dielectric layer;
   depositing a top dielectric layer over the etched top portion of the first core insulating layer and the protruded portion of the first conductive contact pad; and
   planarizing and preparing the planarized top dielectric layer to form a top hybrid bonding surface for direct hybrid bonding.

Example 2. The method of Example 1, further comprising:
etching a bottom portion of the second core insulating layer opposite the first intermediate dielectric layer to protrude a portion of the second conductive contact pad opposite the first intermediate dielectric layer;
depositing a bottom dielectric layer over the etched bottom portion of the second core insulating layer and the protruded portion of the second conductive contact pad; and
planarizing and preparing the bottom dielectric layer to form a bottom hybrid bonding surface for direct hybrid bonding.

Example 3. The method of Example 1, wherein the first and second core insulating layers are formed on first and second carrier substrates, respectively, and the method further comprises:
detaching the first carrier substrate from the first core insulating layer before directly bonding the first and second hybrid bonding surfaces.

Example 4. The method of Example 2, wherein the first and second core insulating layers are formed on first and second carrier substrates, respectively, and the method further comprises:
detaching the first carrier substrate from the first core insulating layer before directly bonding the first and second hybrid bonding surfaces; and
detaching the second carrier substrate from the second core insulating layer before etching the bottom portion of the second core insulating layer.

Example 5. The method of any of Examples 3 and 4, wherein the first and second carrier substrates are glass substrates.

Example 6. The method of Example 1, wherein the first conductive contact pad is separated from the first core insulating layer by a first barrier layer.

Example 7. The method of Example 6, wherein the first barrier layer comprises a dielectric material.

Example 8. The method of Example 6, wherein the first barrier layer comprises a conductive material.

Example 9. The method of Example 1, wherein each of the first and second core insulating layers comprise a deformable region.

Example 10. The method of Example 9, wherein a thickness of the deformable region, along a direction normal to a main surface of the multilayer substrate, is larger than 5 microns.

Example 11. The method of Example 12, wherein a Young's modulus of the deformable region is less than 40 GPa.

Example 12. The method of Example 9, wherein a coefficient of thermal expansion (CTE) of the deformable region is larger than 2 ppm/° C.

Example 13. The method of Example 14, wherein a coefficient of thermal expansion (CTE) of the deformable region is larger than 4 ppm/° C.

Example 14. The method of Example 9, wherein the deformable region is bent without disrupting electrical connection via the conductive line embedded in the multilayer substrate and the radius of curvature of a bent flexible substrate is less than 100 times the thickness of the multilayer substrate along a direction normal to a main surface of the substrate.

Example 15. The method of Example 9, wherein the deformable region comprises an insulating organic material.

Example 16. The method of Example 1, wherein:
the first core insulating layer comprises a first flexible sublayer comprising the first conductive contact pad and a second flexible sublayer comprising a third conductive contact pad;
the second flexible sublayer is separated from the first flexible sublayer via a second intermediate dielectric layer; and
the first and third conductive contact pads are electrically connected via a first direct bonding interface.

Example 17. The method of Example 16, wherein:
the second core insulating layer comprises a third flexible sublayer comprising the second conductive contact pad and a fourth flexible sublayer comprising a fourth conductive contact pad;
the fourth flexible sublayer is separated from the third flexible sublayer via a third intermediate dielectric layer; and
the second and fourth conductive contact pads are electrically connected via a second direct bonding interface.

### Example Embodiment VII

Example 1. A method of fabricating a substrate having a hybrid bonding surface, the method comprising:
providing a base substrate;
forming a conductive layer over the base substrate;
patterning the conductive layer to form openings in the conductive layer;
disposing a deformable material over the patterned conductive layer to overfill the opening and form a core insulating layer extending over the patterned conductive layer;
removing a top portion of the core insulating layer to cause a top portion of the patterned conductive layer opposite the base substrate to protrude;
providing a dielectric layer over the protruded top portion of the patterned conductive layer and the core insulating layer; and
planarizing the dielectric layer to expose a portion of the patterned conductive layer and to form the hybrid bonding surface comprising the protruded top portion of the patterned conductive layer.

Example 2. The method of Example 1, wherein forming the conductive layer comprises disposing an intermediate layer over the base substrate and disposing the conductive layer over the intermediate layer.

Example 3. The method of Example 1, wherein patterning the conductive layer comprises disposing a photoresists over the conductive layer, photolithographically patterning the photoresist layer, and the etching exposed regions of the conductive layer.

Example 4. The method of Example 1, further comprising, before disposing the deformable material over the patterned conductive layer, coating a barrier layer on the conductive layer, on the sidewalls of the openings, and on a bottom surface of the openings.

Example 5. The method of Example 2, wherein the deformable material comprises a polymer.

Example 6. The method of Example 1, wherein removing the top portion of the core insulating layer comprises polishing the core insulating layer to reduce thickness of the core insulating layer down a thickness of the patterned conductive layer and etching portions of the polished core insulating layer within the openings.

Example 7. The method of Example 1, wherein planarizing the dielectric layer comprises polishing the dielectric layer and activating resulting polished dielectric surface for direct bonding.

Example 8. The method of Example 1, wherein base substrate comprises a glass substrate.

Example 9. The method of Example 1, wherein base substrate comprises a multilayer substrate comprising a second core insulating layer disposed over a carrier substrate.

Example 10. The method of Example 9, wherein base substrate further comprises an intermediate layer between the second core insulating layer disposed and the carrier substrate.

Example 11. The method of Example 10, wherein providing a base substrate comprises:
providing the carrier substrate;
coating the intermediate layer or a top main surface of the carrier substrate; and
disposing the second core insulating layer over the intermediate layer.

Example 12. The method of Example 11, wherein the second core insulating layer comprises a second deformable material.

Example 13. The method of Example 12, wherein the second deformable material and the deformable material are substantially the same material.

Example 14. The method of Example 13, wherein the second deformable material is different from the deformable material.

Example 15. The substrate of Example 1, wherein the core insulating layer comprises a deformable region.

Example 16. The substrate of Example 15, wherein a thickness of the deformable region, along a direction normal to a main surface of the substrate, is larger than 5 microns.

Example 17. The substrate of Example 16, wherein a Young's modulus of the deformable region is less than 40 GPa.

Example 18. The substrate of Example 15, wherein a coefficient of thermal expansion (CTE) of the deformable region is larger than 2 ppm/° C.

Example 19. The substrate of Example 18 wherein a coefficient of thermal expansion (CTE) of the deformable region is larger than 4 ppm/° C.

### Example Embodiment VIII

Example 1. A method of fabricating a substrate having a hybrid bonding surface,

Example 2. the method comprising:
providing a base substrate;
forming a patterned photoresist layer over a top surface of the base substrate, the patterned photoresist layer having openings extended to the top surface of the base substrate;
filling the openings with a conductive material to form conductive contact pads;
removing the patterned photoresist layer;
disposing a first deformable material over the exposed regions of the top surface of the base substrate and the conductive contact pads to form a core insulating layer extending over the conductive contact pads;
removing a top portion of the core insulating layer to protrude top portions of the conductive contact pads;
providing a dielectric layer over the protruded top portion of the conductive contact pads; and
planarizing the dielectric layer to expose a to surface of the conductive contact pads and to form the hybrid bonding surface comprising the protruded top portion of the patterned conductive layer.

Example 3. The method of Example 1, further comprising prior to disposing the deformable material, coating a barrier layer over the conductive contact pads and the exposed regions of the top surface of the base substrate.

Example 4. The method of Example 1, wherein providing the base substrate comprises:
providing a carrier substrate;
coating a first intermediate layer on a top main surface of the carrier substrate;
disposing a base layer over the intermediate layer;
coating a second intermediate layer on the base layer; and
disposing a seed layer over the second intermediate layer,
wherein the top surface of the base substrate comprises a top surface of the seed layer.

Example 5. The method of Example 3, wherein the base layer comprises a second deformable material.

Example 6. The method of Example 4, wherein the first and second deformable materials are substantially the same material.

Example 7. The method of Example 4, wherein the second deformable material is different from the first deformable material.

Example 8. The method of Example 1, wherein forming the patterned photoresist layer comprises disposing a photoresist layer over the base substrate, and patterning the photoresist layer using photolithography.

Example 9. The method of Example 4, wherein a thickness of the deformable region, along a direction normal to a main surface of the substrate, is larger than 5 microns.

Example 10. The method of Example 8, wherein a Young's modulus of the deformable region is less than 40 GPa.

Example 11. The method of Example 1, wherein a coefficient of thermal expansion (CTE) of the deformable region is larger than 2 ppm/° C.

Example 12. The substrate of Example 10, wherein a coefficient of thermal expansion (CTE) of the deformable region is larger than 4 ppm/° C.

Example 13. The method of Example 1, wherein the first deformable material comprises a polymer.

Example 14. The method of Example 1, wherein the first deformable material is non-conductive.

Example 15. The method of Example 2, wherein the barrier layer comprises a conductive material.

### Example Embodiment IX

Example 1. A method of fabricating a substrate having a hybrid bonding surface,

Example 2. the method comprising:
providing a flexible hybrid bonding substrate comprising a first core insulating layer and a first conductive contact pad at least partially formed within the first core insulating layer;
forming a patterned photoresist layer over a top surface of the flexible hybrid bonding substrate, the patterned photoresist layer comprising an opening above the first conductive contact pad;
filling the opening with a conductive material to form a second conductive contact pad electrically connected to the first conductive contact pad;
removing the patterned photoresist layer;
disposing a dielectric layer over the second conductive contact pad and the top surface of first flexible hybrid bonding substrate; and
planarizing the dielectric layer to expose a top surface of the second conductive contact pad and to form the hybrid bonding surface comprising the top surface of the second conductive contact pad.

Example 3. The method of Example 1, wherein the top surface of the flexible hybrid bonding substrate comprises a primary hybrid bonding surface.

Example 4. The method of Example 1, wherein the core insulating layer comprises a deformable region.

Example 5. The method of Example 3, wherein the deformable region comprises a polymer.

Example 6. The method of Example 3, wherein a thickness of the deformable region, along a direction normal to a main surface of the substrate, is larger than 5 microns.

Example 7. The method of Example 5, wherein a Young's modulus of the deformable region is less than 40 GPa.

Example 8. The method of Example 6, wherein a coefficient of thermal expansion (CTE) of the deformable region is larger than 2 ppm/° C.

Example 9. The method of Example 7, wherein a coefficient of thermal expansion (CTE) of the deformable region is larger than 4 ppm/° C.

Example 10. The method of Example 1, wherein forming the patterned photoresist layer comprises:
disposing a seed layer over a top surface of the flexible hybrid bonding substrate;
disposing photoresists over the top surface of the flexible hybrid bonding substrate; and
patterning the photoresist layer using photolithography.

### Example Embodiment X

Example 1. A flexible hybrid bonding substrate comprising a hybrid bonding surface, the flexible hybrid bonding substrate comprising:
a core insulating layer having a deformable region;
a conductive region at least partially embedded in the core insulating layer;
a dielectric layer over the core insulating layer, the dielectric layer having a thickness greater than 3% of a thickness of the core insulating layer; and
a conductive contact pad extending from a top surface of the dielectric layer to a top surface of the conductive region, the conductive contact pad electrically connected to the conductive region;
wherein the hybrid bonding surface comprises the top surface of the dielectric layer and the top surface of the conductive region.

Example 2. The flexible hybrid bonding substrate of Example 1, wherein the core insulating layer comprises a first insulating sublayer and a second insulating sublayer below the first insulating sublayer, the second insulating sublayer separated from the first insulating sublayer by an intermediate layer.

Example 3. The flexible hybrid bonding substrate of Example 2, wherein the deformable region comprised portions of the first and second insulating sublayers.

Example 4. The flexible hybrid bonding substrate of Example 1, wherein a thickness of the deformable region, along a direction normal to a main surface of the flexible hybrid bonding substrate, is larger than 5 microns.

Example 5. The flexible hybrid bonding substrate of Example 4, wherein a Young's modulus of the deformable region is less than 40 GPa.

Example 6. The flexible hybrid bonding substrate of Example 1, wherein a coefficient of thermal expansion (CTE) of the deformable region is larger than 2 ppm/° C.

Example 7. The flexible hybrid bonding substrate of Example 6, wherein a coefficient of thermal expansion (CTE) of the deformable region is larger than 4 ppm/° C.

Example 8. The flexible hybrid bonding substrate of Example 2, wherein the second insulating sublayer comprises at least one reinforcement layer comprising a conductive material.

Example 9. The flexible hybrid bonding substrate of Example 1, wherein the conductive region is separated from the core insulating layer by a first barrier layer.

Example 10. The flexible hybrid bonding substrate of Example 1, wherein the conductive contact pad is separated from the dielectric layer a second barrier layer.

Example 11. The method of Example 9, wherein the first barrier layer comprises a conductive material.

Example 12. The method of Example 10, wherein the second barrier layer comprises a conductive material.

### Example Embodiment XI

Example 1. A method of fabricating a hybrid bonding substrate, the method comprising:
providing a base substrate;
disposing a precursor layer over a top surface of the base substrate;
patterning the precursor layer to form a pattered precursor layer having a first opening through which an underlying region of the top surface of the base substrate is exposed;
treating the patterned precursor layer to form a patterned core insulating layer over the base substrate, the patterned core insulating layer comprising a deformable region;
coating a barrier layer over the patterned core insulating layer on sidewalls of the first opening and the exposed underlying region of the top surface of the base substrate;
disposing a first conductive layer over the patterned core insulating layer to overfill the first opening and to form a first conductive contact pad; and
planarizing the first conductive layer to form an intermediate surface comprising a top surface of the first conductive contact pad and top surface regions of the patterned core insulating layer.

Example 2. The method of Example 1, further comprising:
disposing a dielectric layer over the intermediate surface;
patterning the dielectric layer to form a patterned dielectric layer having a second opening above the first conductive contact pad exposing at least a portion of the top surface of the first conductive contact pad;
disposing a second conductive layer over the patterned dielectric layer to overfill the second opening and to form a second conductive contact pad electrically connected to the first conductive contact pad; and
planarizing a top surface of the second conductive layer to form a hybrid bonding surface comprising a top surface of the second conductive contact pad.

Example 3. The method of Example 1, further comprising disposing an intermediate layer over the base substrate before disposing the precursor layer.

Example 4. The method of Example 1, wherein the base substrate comprises at least one core insulating layer and the hybrid bonding surface is formed over the core insulating layer.

Example 5. The method of Example 1, wherein providing the base substrate comprises:
providing a carrier substrate;
coating a first intermediate layer on a top main surface of the carrier substrate; and
disposing a base core insulating layer over the intermediate layer.

Example 6. The method of Example 1, wherein a thickness of the deformable region, along a direction normal to a main surface of the substrate, is larger than 5 microns.

Example 7. The method of Example 6, wherein a Young's modulus of the deformable region is less than 40 GPa.

Example 8. The method of Example 1, wherein a coefficient of thermal expansion (CTE) of the deformable region is larger than 2 ppm/° C.

Example 9. The method of Example 8, wherein a coefficient of thermal expansion (CTE) of the deformable region is larger than 4 ppm/° C.

Example 10. The method of Examples 1, wherein the deformable region comprises a polymer.

### Example Embodiment XII

Example 1. A flexible hybrid bonding substrate comprising a hybrid bonding surface, the flexible hybrid bonding substrate comprising:
an insulating substrate comprising a deformable region;
a first dielectric layer over a core insulating layer;
a second dielectric layer disposed on the first dielectric layer;
the first dielectric layer comprising a conductive region embedded in the first dielectric layer; and
the second dielectric layer comprising a conductive contact pad extending from a top major surface of the second dielectric layer to a boundary between the first and second dielectric layers;
wherein the conductive contact pad is electrically connected to the conductive region; and
wherein the hybrid bonding surface comprises a top surface of the second dielectric layer and a top surface of the second conductive contact pad.

Example 2. The flexible hybrid bonding substrate of Example 1,wherein a thickness of the deformable region, along a direction normal to a main surface of the flexible hybrid bonding substrate, is larger than 5 microns.

Example 3. The flexible hybrid bonding substrate of Example of Example 2, wherein a Young's modulus of the deformable region is less than 40 GPa.

Example 4. The flexible hybrid bonding substrate of Example 1, wherein a coefficient of thermal expansion (CTE) of the deformable region is larger than 2 ppm/° C.

Example 5. The flexible hybrid bonding substrate of Example 4, wherein a coefficient of thermal expansion (CTE) of the deformable region is larger than 4 ppm/° C.

Example 6. The flexible hybrid bonding substrate of Example 1, wherein the conductive region is separated from the first dielectric layer.

Example 7. The flexible hybrid bonding substrate of Example 1, wherein the conductive contact pad is separated from the second dielectric layer a second barrier layer.

Example 8. The method of Example 9, wherein the first barrier layer comprises a conductive material.

Example 9. The method of Example 10, wherein the second barrier layer comprises a conductive material.

Example 10. The flexible hybrid bonding substrate of Example 1, wherein the insulating substrate comprises at least one reinforcement layer comprising a conductive material.

Example 11. The flexible hybrid bonding substrate of Example 10, wherein the at least one reinforcement layer is electrically isolated from the first conductive contact pad region by at least a layer of the insulating substrate.

Example 12. The flexible hybrid bonding substrate of Example 11, wherein the at least one reinforcement layer is electrically isolated from the first conductive contact pad region by a sublayer of the first dielectric layer.

### Terminology

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A substrate for hybrid bonding to at least one component, the substrate comprising:
a core insulating layer comprising a deformable region;
an inorganic dielectric bonding layer over the core insulating layer;
an opening through the inorganic dielectric bonding layer extending below the inorganic dielectric bonding layer into the core insulating layer;
a barrier layer coated on sidewalls and a bottom surface of the opening; and
a first conductive contact pad formed within the opening, the first conductive contact pad separated from the core insulating layer and the inorganic dielectric bonding layer by the barrier layer;
wherein a surface of the inorganic dielectric bonding layer is prepared for direct hybrid bonding.

2. The substrate of claim 1, wherein the deformable region comprises an insulating organic material.

3. The substrate of claim 2, wherein the insulating organic material comprises a polymer.

4. The substrate of claim 1, wherein the deformable region comprises a flexible material.

5. The substrate of claim 1, wherein a thickness of the deformable region, along a direction normal to a main surface of the substrate, is larger than 5 microns.

6. The substrate of claim 5, wherein a Young's modulus of the deformable region is less than 40 GPa.

7. The substrate of claim 1, wherein a coefficient of thermal expansion (CTE) of the deformable region is larger than 2 ppm/° C.

8. The substrate of claim 7, wherein a coefficient of thermal expansion (CTE) of the deformable region is larger than 4 ppm/° C.

9. The substrate of claim 1, wherein the opening has a depth less than a thickness of the core insulating layer.

10. The substrate of claim 1, further comprising a second conductive contact pad spaced apart from the first conductive contact pad by a gap, wherein the deformable region at least partially bridges the gap.

11. The substrate of claim 10, wherein the first and second conductive contact pads are electrically connected by a conductive line at least partially embedded in the deformable region.

12. The substrate of claim 11, wherein the deformable region is bent without disrupting electrical connection via the conductive line and a radius of curvature of a bent flexible substrate is less than 100 times a thickness of the substrate along a direction normal to a main surface of the substrate.

13. The substrate of claim 1, wherein the surface of the inorganic dielectric bonding layer is activated and terminated with a species.

14. The substrate of claim 13, wherein the species comprises nitrogen.

15. The substrate of claim 1, wherein the first conductive contact pad comprises a conductive material disposed within the opening over the barrier layer.

16. The substrate of claim 15, wherein the conductive material comprises a metal.

17. The substrate of claim 1, wherein the barrier layer comprises a dielectric material.

18. The substrate of claim 17, wherein the barrier layer comprises silicon nitride, a combination of silicon nitride and silicon oxide, or silicon carbide.

19. The substrate of claim 18, wherein a composition of the barrier layer is identical to that of the inorganic dielectric bonding layer.

20. The substrate of claim 1, wherein the barrier layer comprises a conductive material.

21. The substrate of claim 20, wherein the conductive material comprises TaN or TiN.

22. The substrate of claim 1, wherein the inorganic dielectric bonding layer comprises SiOₓN_{y}, SiOₓ, or SiC.

23. The substrate of claim 1, wherein the deformable region is transparent in a visible wavelength range.

24. The substrate of claim 1, wherein a thickness of the barrier layer is from 5 to 100 nanometers.
